(19) United States
(12) Patent Application Publication
(10) Pub. No.: US 2022/0393637 A1
(43) Pub. Date: Dec. 8, 2022

(54) ROOFING MODULE SYSTEM

(71) Applicant: GAF Energy LLC, Parsippany, NJ (US)

(72) Inventors: Gabriela Bunea, San Jose, CA (US); Thierry Nguyen, San Francisco, CA (US); Richard Perkins, San Jose, CA (US); Michael Kuiper, Newark, CA (US); Gary Rossi, San Francisco, CA (US); Nicholas Boitnott, San Francisco, CA (US); David Kavulak, San Francisco, CA (US); Alex Sharenko, Berkley, CA (US); Anna Wojtowicz, San Francisco, CA (US)

(21) Appl. No.: 17/831,307

(22) Filed: Jun. 2, 2022

Related U.S. Application Data
(60) Provisional application No. 63/196,568, filed on Jun. 3, 2021.
(60) Provisional application No. 63/197,115, filed on Jun. 4, 2021.

(51) Int. Cl. H02S 20/25

(52) U.S. Cl. CPC H02S 20/25

(57) ABSTRACT

A system includes a plurality of roofing modules and a plurality of photovoltaic modules. The roofing modules include a first layer and a second layer. The first layer has a first surface that is textured. The roofing modules are configured to be installed on the roof deck of a structure proximate to the photovoltaic modules. An appearance of the roofing modules aesthetically matches an appearance of the photovoltaic modules when viewed from a vantage point located at a ground level of the structure.

### CROSS-REFERENCE TO RELATED APPLICATION

This application is a Section 111(a) application relating to and claiming the benefit of commonly-owned, co-pending U.S. Provisional Patent Application Ser. No. 63/196,568, filed Jun. 3, 2021, entitled “FLEXIBLE AND CUTTABLE ROOFING MODULES,” and commonly-owned, co-pending U.S. Provisional Patent Application Ser. No. 63/197,115, filed Jun. 4, 2021, entitled “PHOTOVOLTAIC MODULE WITH TEXTURED SUPERSTRATE PROVIDING SHINGLE-MIMICKING APPEARANCE,” the contents of each which are incorporated herein by reference in its entirety.

### FIELD OF THE INVENTION

The present invention relates to roofing modules, and, more particularly, flexible and cuttable roofing modules aesthetically matched with photovoltaic modules.

### BACKGROUND

Photovoltaic systems having solar panels are commonly installed on roofing of structures.

### SUMMARY

In some embodiments, a system includes a plurality of roofing modules, each of the roofing modules includes a first layer wherein the first layer includes a first surface, and a second surface opposite the first surface, wherein the first surface is textured, and a second layer, wherein the second layer is juxtaposed with the second surface of the first layer, wherein each of the roofing modules does not include a solar cell; and a plurality of photovoltaic modules, each of the plurality of photovoltaic modules includes at least one solar cell, an encapsulant encapsulating the at least one solar cell, wherein the encapsulant of the photovoltaic module includes a first surface and a second surface opposite the first surface of the encapsulant of the photovoltaic module, a frontsheet, wherein the frontsheet includes a first surface, and a second surface opposite the first surface of the frontsheet, wherein the second surface of the frontsheet is juxtaposed with the first surface of the encapsulant, wherein the first surface of the frontsheet is textured, and a backsheet juxtaposed with the second surface of the encapsulant of the photovoltaic module, wherein the photovoltaic modules are configured to be installed on a roof deck of a structure, wherein the roofing modules are configured to be installed on the roof deck proximate to the photovoltaic modules, and wherein an appearance of the roofing modules aesthetically matches an appearance of the photovoltaic modules when viewed from a vantage point located at a ground level of the structure.

In some embodiments, the first layer is composed of a polymer. In some embodiments, the first layer is composed of thermoplastic polyolefin (TPO). In some embodiments, the second layer is composed of a polymer. In some embodiments, the second layer is composed of thermoplastic polyolefin (TPO). In some embodiments, the second layer includes fiberglass. In some embodiments, the first layer has a thickness of 25 mils to 100 mils. In some embodiments, the second layer has a thickness of 25 mils to 200 mils. In some embodiments, the first layer includes a pattern printed on the first surface of the first layer. In some embodiments, the pattern is a depiction of solar cells. In some embodiments, the first layer is colored. In some embodiments, the first layer is black colored. In some embodiments, the second layer is colored. In some embodiments, the second layer is black colored.

In some embodiments, a method, comprising the steps of: obtaining a plurality of roofing modules, each of the roofing modules includes a first layer wherein the first layer includes a first surface, and a second surface opposite the first surface, wherein the first surface is textured, and a second layer, wherein the second layer is juxtaposed with the second surface of the first layer, wherein each of the roofing modules does not include a solar cell; obtaining a plurality of photovoltaic modules, each of the plurality of photovoltaic modules includes at least one solar cell, an encapsulant encapsulating the at least one solar cell, wherein the encapsulant of the photovoltaic module includes a first surface and a second surface opposite the first surface of the encapsulant of the photovoltaic module, a frontsheet, wherein the frontsheet includes a first surface, and a second surface opposite the first surface of the frontsheet, wherein the second surface of the frontsheet is juxtaposed with the first surface of the encapsulant, wherein the first surface of the frontsheet is textured, and a backsheet juxtaposed with the second surface of the encapsulant of the photovoltaic module; installing the plurality of photovoltaic modules on a roof deck of a structure; cutting at least one of the plurality of roofing modules to a size and shape; and installing the plurality of roofing modules on the roof deck proximate to the plurality of photovoltaic modules, wherein the at least one solar cell of at least one of the plurality of photovoltaic modules is electrically active, and wherein an appearance of the roofing modules aesthetically matches an appearance of the photovoltaic modules when viewed from a vantage point located at a ground level of the structure.

In some embodiments, each of the first layer and the second layer is composed of a polymer. In some embodiments, each of the first layer and the second layer is composed of thermoplastic polyolefin (TPO). In some embodiments, the first layer has a thickness of 25 mils to 100 mils, and wherein the second layer has a thickness of 25 mils to 200 mils. In some embodiments, the first layer includes a pattern printed on the first surface of the first layer. In some embodiments, the pattern is a depiction of solar cells.

### BRIEF DESCRIPTION OF THE DRAWINGS

FIG. 1 is a schematic view of an embodiment of a roofing module;

FIG. 2 shows an embodiment of a roofing module;

FIG. 3 is a schematic view of another embodiment of a roofing module;

FIG. 4 is a schematic view of another embodiment of a roofing module;

FIG. 5 shows an embodiment of a roofing module;

FIG. 6 shows embodiments of a roofing system;

FIG. 7 is a schematic view of another embodiment of a roofing module;

FIG. 8 is a schematic view of another embodiment of a roofing module;

FIG. 9 is a schematic view of another embodiment of a roofing module;

FIG. 10 is a schematic view of another embodiment of a roofing module;

FIG. 11 is a schematic view of another embodiment of a roofing module;

FIGS. 12A to 12D show embodiments of a roofing module;

FIG. 13 is a schematic view of another embodiment of a roofing module;

FIG. 14 is a schematic view of another embodiment of a roofing module;

FIG. 15 is a schematic view another embodiment of a photovoltaic module;

FIGS. 16 and 17 show an embodiment of a roofing module;

FIG. 18 shows a schematic view of an embodiment of a photovoltaic module;

FIGS. 19A through 19C show embodiments of a textured release liner employed by the photovoltaic module shown in FIG. 18;

FIG. 20 shows an embodiment of a solar cell employed by the photovoltaic module shown in FIG. 18;

FIGS. 21A through 21C show embodiments of a photovoltaic module including the textured release liner shown in FIG. 19A;

FIGS. 22A through 22C show embodiments of a photovoltaic module including the textured release liner shown in FIG. 19B;

FIGS. 23A through 23C show embodiments of a photovoltaic module including the textured release liner shown in FIG. 19C;

FIGS. 24 and 25 show embodiments of release liners;

FIG. 26 is a graph showing gloss versus embodiments of textured release liners; and

FIG. 27 illustrates an embodiment of a roofing system with roofing shingles.

### DETAILED DESCRIPTION

The present invention will be further explained with reference to the attached drawings, wherein like structures are referred to by like numerals throughout the several views. The drawings shown are not necessarily to scale, with emphasis instead generally being placed upon illustrating the principles of the present invention. Further, some features may be exaggerated to show details of particular components.

The figures constitute a part of this specification and include illustrative embodiments of the present invention and illustrate various objects and features thereof. Further, the figures are not necessarily to scale, some features may be exaggerated to show details of particular components. In addition, any measurements, specifications and the like shown in the figures are intended to be illustrative, and not restrictive. Therefore, specific structural and functional details disclosed herein are not to be interpreted as limiting, but merely as a representative basis for teaching one skilled in the art to variously employ the present invention.

Among those benefits and improvements that have been disclosed, other objects and advantages of this invention will become apparent from the following description taken in conjunction with the accompanying figures. Detailed embodiments of the present invention are disclosed herein; however, it is to be understood that the disclosed embodiments are merely illustrative of the invention that may be embodied in various forms. In addition, each of the examples given in connection with the various embodiments of the invention which are intended to be illustrative, and not restrictive.

Throughout the specification and claims, the following terms take the meanings explicitly associated herein, unless the context clearly dictates otherwise. The phrases “in one embodiment” and “in some embodiments” as used herein do not necessarily refer to the same embodiment(s), though they may. Furthermore, the phrases “in another embodiment” and “in some other embodiments” as used herein do not necessarily refer to a different embodiment, although they may. Thus, as described below, various embodiments of the invention may be readily combined, without departing from the scope or spirit of the invention.

The term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

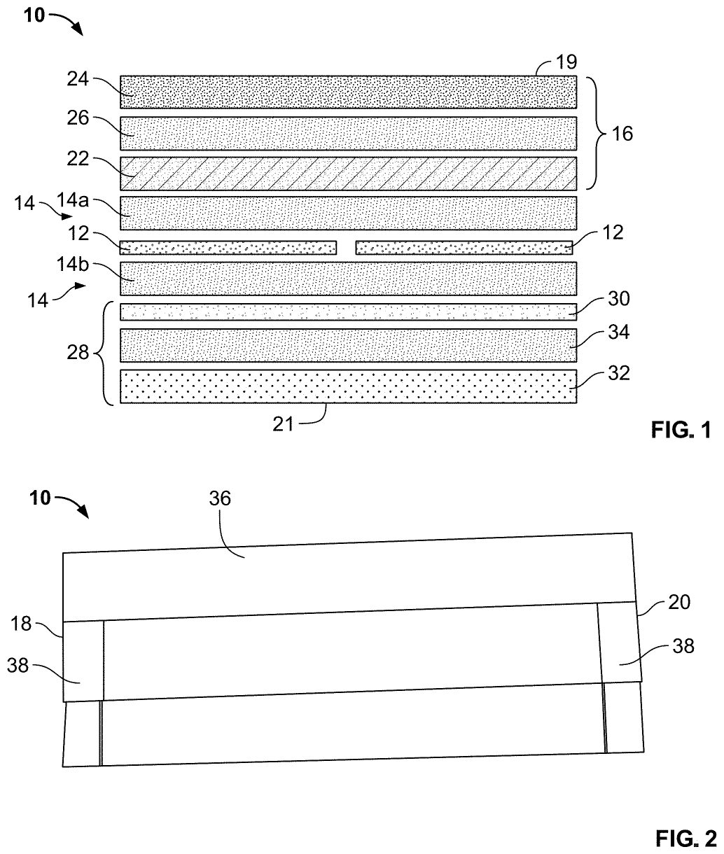

Referring to FIGS. 1 through 2, in some embodiments, a roofing module 10 includes at least one cell 12, an encapsulant 14 encapsulating the at least one cell 12, and a frontsheet 16 juxtaposed with the encapsulant 14. In some embodiments, the frontsheet 16 is juxtaposed with a first surface of the encapsulant 14. As used herein, the terms “encapsulating” and “encapsulates” mean to partially or fully envelope or enclose, and with respect to certain embodiments of the roofing module 10, the at least one cell 12 is fully enveloped by or enclosed within the encapsulant 14, or partially enveloped by or enclosed within the encapsulant 14. In some embodiments, the at least one cell 12 includes a plurality of cells 12. In some embodiments, the encapsulant 14 encapsulates 50% to 99.9% of an exterior surface area of the at least one cell 12. In another embodiment, the encapsulant 14 encapsulates 55% to 99.9% of an exterior surface area of the at least one cell 12. In another embodiment, the encapsulant 14 encapsulates 60% to 99.9% of an exterior surface area of the at least one cell 12. In another embodiment, the encapsulant 14 encapsulates 65% to 99.9% of an exterior surface area of the at least one cell 12. In another embodiment, the encapsulant 14 encapsulates 70% to 99.9% of an exterior surface area of the at least one cell 12. In another embodiment, the encapsulant 14 encapsulates 75% to 99.9% of an exterior surface area of the at least one cell 12. In another embodiment, the encapsulant 14 encapsulates 80% to 99.9% of an exterior surface area of the at least one cell 12. In another embodiment, the encapsulant 14 encapsulates 85% to 99.9% of an exterior surface area of the at least one cell 12. In another embodiment, the encapsulant 14 encapsulates 90% to 99.9% of an exterior surface area of the at least one cell 12. In another embodiment, the encapsulant 14 encapsulates 95% to 99.9% of an exterior surface area of the at least one cell 12.

In another embodiment, the encapsulant 14 encapsulates 50% to 95% of an exterior surface area of the at least one cell 12. In another embodiment, the encapsulant 14 encapsulates 55% to 95% of an exterior surface area of the at least one cell 12. In another embodiment, the encapsulant 14 encapsulates 60% to 95% of an exterior surface area of the at least one cell 12. In another embodiment, the encapsulant 14 encapsulates 65% to 95% of an exterior surface area of the at least one cell 12. In another embodiment, the encapsulant 14 encapsulates 70% to 95% of an exterior surface area of the at least one cell 12. In another embodiment, the encapsulant 14 encapsulates 75% to 95% of an exterior surface area of the at least one cell 12. In another embodiment, the encapsulant 14 encapsulates 80% to 95% of an exterior surface area of the at least one cell 12. In another embodiment, the encapsulant 14 encapsulates 85% to 95% of an exterior surface area of the at least one cell 12. In another embodiment, the encapsulant 14 encapsulates 90% to 95% of an exterior surface area of the at least one cell 12.

In another embodiment, the encapsulant 14 encapsulates 50% to 90% of an exterior surface area of the at least one cell 12. In another embodiment, the encapsulant 14 encapsulates 55% to 90% of an exterior surface area of the at least one cell 12. In another embodiment, the encapsulant 14 encapsulates 60% to 90% of an exterior surface area of the at least one cell 12. In another embodiment, the encapsulant 14 encapsulates 65% to 90% of an exterior surface area of the at least one cell 12. In another embodiment, the encapsulant 14 encapsulates 70% to 90% of an exterior surface area of the at least one cell 12. In another embodiment, the encapsulant 14 encapsulates 75% to 90% of an exterior surface area of the at least one cell 12. In another embodiment, the encapsulant 14 encapsulates 80% to 90% of an exterior surface area of the at least one cell 12. In another embodiment, the encapsulant 14 encapsulates 85% to 90% of an exterior surface area of the at least one cell 12.

In another embodiment, the encapsulant 14 encapsulates 50% to 85% of an exterior surface area of the at least one cell 12. In another embodiment, the encapsulant 14 encapsulates 55% to 85% of an exterior surface area of the at least one cell 12. In another embodiment, the encapsulant 14 encapsulates 60% to 85% of an exterior surface area of the at least one cell 12. In another embodiment, the encapsulant 14 encapsulates 65% to 85% of an exterior surface area of the at least one cell 12. In another embodiment, the encapsulant 14 encapsulates 70% to 85% of an exterior surface area of the at least one cell 12. In another embodiment, the encapsulant 14 encapsulates 75% to 85% of an exterior surface area of the at least one cell 12. In another embodiment, the encapsulant 14 encapsulates 80% to 85% of an exterior surface area of the at least one cell 12.

In another embodiment, the encapsulant 14 encapsulates 50% to 80% of an exterior surface area of the at least one cell 12. In another embodiment, the encapsulant 14 encapsulates 55% to 80% of an exterior surface area of the at least one cell 12. In another embodiment, the encapsulant 14 encapsulates 60% to 80% of an exterior surface area of the at least one cell 12. In another embodiment, the encapsulant 14 encapsulates 65% to 80% of an exterior surface area of the at least one cell 12. In another embodiment, the encapsulant 14 encapsulates 70% to 80% of an exterior surface area of the at least one cell 12. In another embodiment, the encapsulant 14 encapsulates 75% to 80% of an exterior surface area of the at least one cell 12.

In another embodiment, the encapsulant 14 encapsulates 50% to 75% of an exterior surface area of the at least one cell 12. In another embodiment, the encapsulant 14 encapsulates 55% to 75% of an exterior surface area of the at least one cell 12. In another embodiment, the encapsulant 14 encapsulates 60% to 75% of an exterior surface area of the at least one cell 12. In another embodiment, the encapsulant 14 encapsulates 65% to 75% of an exterior surface area of the at least one cell 12. In another embodiment, the encapsulant 14 encapsulates 70% to 75% of an exterior surface area of the at least one cell 12.

In another embodiment, the encapsulant 14 encapsulates 50% to 70% of an exterior surface area of the at least one cell 12. In another embodiment, the encapsulant 14 encapsulates 55% to 70% of an exterior surface area of the at least one cell 12. In another embodiment, the encapsulant 14 encapsulates 60% to 70% of an exterior surface area of the at least one cell 12. In another embodiment, the encapsulant 14 encapsulates 65% to 70% of an exterior surface area of the at least one cell 12.

In another embodiment, the encapsulant 14 encapsulates 50% to 65% of an exterior surface area of the at least one cell 12. In another embodiment, the encapsulant 14 encapsulates 55% to 65% of an exterior surface area of the at least one cell 12. In another embodiment, the encapsulant 14 encapsulates 60% to 65% of an exterior surface area of the at least one cell 12. In another embodiment, the encapsulant 14 encapsulates 50% to 60% of an exterior surface area of the at least one cell 12. In another embodiment, the encapsulant 14 encapsulates 55% to 60% of an exterior surface area of the at least one cell 12. In another embodiment, the encapsulant 14 encapsulates 55% to 60% of an exterior surface area of the at least one cell 12.

In some embodiments, the encapsulant 14 encapsulates 50% of an exterior surface area of the at least one cell 12. In another embodiment, the encapsulant 14 encapsulates 55% of the exterior surface area of the at least one cell 12. In another embodiment, the encapsulant 14 encapsulates 60% of the exterior surface area of the at least one cell 12. In another embodiment, the encapsulant 14 encapsulates 65% of the exterior surface area of the at least one cell 12. In another embodiment, the encapsulant 14 encapsulates 70% of the exterior surface area of the at least one cell 12. In another embodiment, the encapsulant 14 encapsulates 75% of the exterior surface area of the at least one cell 12. In another embodiment, the encapsulant 14 encapsulates 80% of the exterior surface area of the at least one cell 12. In another embodiment, the encapsulant 14 encapsulates 85% of the exterior surface area of the at least one cell 12. In another embodiment, the encapsulant 14 encapsulates 90% of the exterior surface area of the at least one cell 12. In another embodiment, the encapsulant 14 encapsulates 95% of the exterior surface area of the at least one cell 12. In another embodiment, the encapsulant 14 encapsulates 100% of the exterior surface area of the at least one cell 12.

In some embodiments, the encapsulant 14 has a thickness of 0.5 mm to 4 mm. In another embodiment, the encapsulant 14 has a thickness of 0.5 mm to 3.5 mm. In another embodiment, the encapsulant 14 has a thickness of 0.5 mm to 3 mm. In another embodiment, the encapsulant 14 has a thickness of 0.5 mm to 2.5 mm. In another embodiment, the encapsulant 14 has a thickness of 0.5 mm to 2 mm. In another embodiment, the encapsulant 14 has a thickness of 0.5 mm to 1.5 mm. In another embodiment, the encapsulant 14 has a thickness of 0.5 mm to 1 mm.

In some embodiments, the encapsulant 14 has a thickness of 1 mm to 4 mm. In another embodiment, the encapsulant 14 has a thickness of 1 mm to 3.5 mm. In another embodiment, the encapsulant 14 has a thickness of 1 mm to 3 mm. In another embodiment, the encapsulant 14 has a thickness of 1 mm to 2.5 mm. In another embodiment, the encapsulant 14 has a thickness of 1 mm to 2 mm. In another embodiment, the encapsulant 14 has a thickness of 1 mm to 1.5 mm. In some embodiments, the encapsulant 14 has a thickness of 1.5 mm to 4 mm. In another embodiment, the encapsulant 14 has a thickness of 1.5 mm to 3.5 mm. In another embodiment, the encapsulant 14 has a thickness of 1.5 mm to 3 mm. In another embodiment, the encapsulant 14 has a thickness of 1.5 mm to 2.5 mm. In another embodiment, the encapsulant 14 has a thickness of 1.5 mm to 2 mm.

In some embodiments, the encapsulant 14 has a thickness of 2 mm to 4 mm. In another embodiment, the encapsulant 14 has a thickness of 2 mm to 3.5 mm. In another embodiment, the encapsulant 14 has a thickness of 2 mm to 3 mm. In another embodiment, the encapsulant 14 has a thickness of 2 mm to 2.5 mm. In some embodiments, the encapsulant 14 has a thickness of 2.5 mm to 4 mm. In another embodiment, the encapsulant 14 has a thickness of 2.5 mm to 3.5 mm. In another embodiment, the encapsulant 14 has a thickness of 2.5 mm to 3 mm. In some embodiments, the encapsulant 14 has a thickness of 3 mm to 4 mm. In another embodiment, the encapsulant 14 has a thickness of 3 mm to 3.5 mm. In some embodiments, the encapsulant 14 has a thickness of 3.5 mm to 4 mm.

In some embodiments, the encapsulant 14 has a thickness of 0.5 mm. In some embodiments, the encapsulant 14 has a thickness of 0.6 mm. In some embodiments, the encapsulant 14 has a thickness of 0.7 mm. In some embodiments, the encapsulant 14 has a thickness of 0.8 mm. In some embodiments, the encapsulant 14 has a thickness of 0.9 mm. In some embodiments, the encapsulant 14 has a thickness of 1 mm. In some embodiments, the encapsulant 14 has a thickness of 1.5 mm. In some embodiments, the encapsulant 14 has a thickness of 2 mm. In some embodiments, the encapsulant 14 has a thickness of 2.5 mm. In some embodiments, the encapsulant 14 has a thickness of 3 mm. In some embodiments, the encapsulant 14 has a thickness of 3.5 mm. In some embodiments, the encapsulant 14 has a thickness of 4 mm.

In some embodiments, a first layer 14a of the encapsulant 14 has a thickness of 0.2 mm to 2 mm. In some embodiments, the first layer 14a of the encapsulant 14 has a thickness of 0.2 mm to 1.5 mm. In some embodiments, the first layer 14a of the encapsulant 14 has a thickness of 0.2 mm to 1 mm. In some embodiments, the first layer 14a of the encapsulant 14 has a thickness of 0.2 mm to 0.5 mm. In some embodiments, the first layer 14a of the encapsulant 14 has a thickness of 0.5 mm to 2 mm. In some embodiments, the first layer 14a of the encapsulant 14 has a thickness of 0.5 mm to 1.5 mm. In some embodiments, the first layer 14a of the encapsulant 14 has a thickness of 0.5 mm to 1 mm. In some embodiments, the first layer 14a of the encapsulant 14 has a thickness of 1 mm to 2 mm. In some embodiments, the first layer 14a of the encapsulant 14 has a thickness of 1 mm to 1.5 mm. In some embodiments, the first layer 14a of the encapsulant 14 has a thickness of 1.5 mm to 2 mm.

In some embodiments, the first layer 14a of the encapsulant 14 has a thickness of 0.2 mm. In some embodiments, the first layer 14a of the encapsulant 14 has a thickness of 0.3 mm. In some embodiments, the first layer 14a of the encapsulant 14 has a thickness of 0.4 mm. In some embodiments, the first layer 14a of the encapsulant 14 has a thickness of 0.45 mm. In some embodiments, the first layer 14a of the encapsulant 14 has a thickness of 0.5 mm. In some embodiments, the first layer 14a of the encapsulant 14 has a thickness of 1 mm. In some embodiments, the first layer 14a of the encapsulant 14 has a thickness of 1.5 mm. In some embodiments, the first layer 14a of the encapsulant 14 has a thickness of 2 mm. In some embodiments, the first layer 14a of the encapsulant 14 has a thickness of 2.5 mm. In some embodiments, the first layer 14a of the encapsulant 14 has a thickness of 3 mm. In some embodiments, the first layer 14a of the encapsulant 14 has a thickness of 3.5 mm. In some embodiments, the first layer 14a of the encapsulant 14 has a thickness of 4 mm.

In some embodiments, a second layer 14b of the encapsulant 14 has a thickness of 0.2 mm to 2 mm. In some embodiments, the second layer 14b of the encapsulant 14 has a thickness of 0.2 mm to 1.5 mm. In some embodiments, the second layer 14b of the encapsulant 14 has a thickness of 0.2 mm to 1 mm. In some embodiments, the second layer 14b of the encapsulant 14 has a thickness of 0.2 mm to 0.5 mm. In some embodiments, the second layer 14b of the encapsulant 14 has a thickness of 0.5 mm to 2 mm. In some embodiments, the second layer 14b of the encapsulant 14 has a thickness of 0.5 mm to 1.5 mm. In some embodiments, the second layer 14b of the encapsulant 14 has a thickness of 0.5 mm to 1 mm. In some embodiments, the second layer 14b of the encapsulant 14 has a thickness of 1 mm to 2 mm. In some embodiments, the second layer 14b of the encapsulant 14 has a thickness of 1 mm to 1.5 mm. In some embodiments, the second layer 14b of the encapsulant 14 has a thickness of 1.5 mm to 2 mm.

In some embodiments, the second layer 14b of the encapsulant 14 has a thickness of 0.2 mm. In some embodiments, the second layer 14b of the encapsulant 14 has a thickness of 0.3 mm. In some embodiments, the second layer 14b of the encapsulant 14 has a thickness of 0.4 mm. In some embodiments, the second layer 14b of the encapsulant 14 has a thickness of 0.45 mm. In some embodiments, the second layer 14b of the encapsulant 14 has a thickness of 0.5 mm. In some embodiments, the second layer 14b of the encapsulant 14 has a thickness of 1 mm. In some embodiments, the second layer 14b of the encapsulant 14 has a thickness of 1.5 mm. In some embodiments, the second layer 14b of the encapsulant 14 has a thickness of 2 mm. In some embodiments, the second layer 14b of the encapsulant 14 has a thickness of 2.5 mm. In some embodiments, the second layer 14b of the encapsulant 14 has a thickness of 3 mm. In some embodiments, the second layer 14b of the encapsulant 14 has a thickness of 3.5 mm. In some embodiments, the second layer 14b of the encapsulant 14 has a thickness of 4 mm.

In some embodiments, the thickness of the first layer 14a is equal to the thickness of the second layer 14b. In another embodiment, the thickness of the first layer 14a is different from the thickness of the second layer 14b.

In some embodiments, the encapsulant 14 may be made from polyolefins, ethyl vinyl acetates, ionomers, silicones, poly vinyl butyral, epoxies, polyurethanes, or combinations/hybrids thereof. In some embodiments, the encapsulant 14 is made from thermosetting polyolefin.

In some embodiments, the roofing module 10 includes a first end 18, a second end 20 opposite the first end 18, a first surface 19 extending from the first end 18 to the second end 20, and a second surface 21 opposite the first surface 19 and extending from the first end 18 to the second end 20. In some embodiments, the first surface 19 is an upper, sun facing-side surface of the roofing module 10, and the second surface 21 is a lower surface configured to face a roof deck on which the roofing module 10 is installed.

In some embodiments, the at least one cell 12 includes a plurality of the cells 12. In some embodiments, the at least one cell 12 is a solar cell. In some embodiments, the solar cell is electrically inactive (i.e., a “dummy” solar cell). In some embodiments, the plurality of cells 12 is arranged in one row (i.e., one reveal). In another embodiment, the plurality of cells 12 is arranged in two rows (i.e., two reveals). In another embodiment, the plurality of cells 12 is arranged in three rows (i.e., three reveals). In other embodiments, the plurality of cells 12 is arranged in more than three rows.

In some embodiments, the frontsheet 16 includes a glass layer 22 and a polymer layer 24 attached to a first surface of the glass layer 22. In some embodiments, the frontsheet 16 is juxtaposed with the first layer 14a of the encapsulant 14. In some embodiments, each of the encapsulant 14, the glass layer 22, and the polymer layer 24 is transparent. In some embodiments, the polymer layer 24 is attached to the glass layer 22 by an first adhesive layer 26. In some embodiments, the first adhesive layer 26 may include polyvinyl butyrate, acrylic, silicone, or polycarbonate. In another embodiment, the first adhesive layer 26 may include pressure sensitive adhesives. In another embodiment, the polymer layer 24 is attached to the glass layer 22 by thermal bonding. In another embodiment, the frontsheet 16 includes at least one of the glass layer 22 or the polymer layer 24. In some embodiments, the first adhesive layer 26 is transparent. As used herein, the term “transparent” means having a solar weighted transmittance of 80% or greater, and with respect to certain embodiments of the roofing module 10, a transparent layer of the roofing module has a solar weighted transmittance of 80% or greater. In another embodiment, the frontsheet 16 does not include the glass layer 22.

In some embodiments, the glass layer 22 has a thickness of 1 mm to 4 mm. In some embodiments, the glass layer 22 has a thickness of 1 mm to 3.5 mm. In some embodiments, the glass layer 22 has a thickness of 1 mm to 3 mm. In some embodiments, the glass layer 22 has a thickness of 1 mm to 2.5 mm. In some embodiments, the glass layer 22 has a thickness of 1 mm to 2 mm. In some embodiments, the glass layer 22 has a thickness of 1 mm to 1.5 mm. In some embodiments, the glass layer 22 has a thickness of 1.5 mm to 4 mm. In some embodiments, the glass layer 22 has a thickness of 1.5 mm to 3.5 mm. In some embodiments, the glass layer 22 has a thickness of 1.5 mm to 3 mm. In some embodiments, the glass layer 22 has a thickness of 1 mm to 2.5 mm. In some embodiments, the glass layer 22 has a thickness of 1.5 mm to 2 mm.

In some embodiments, the glass layer 22 has a thickness of 2 mm to 4 mm. In some embodiments, the glass layer 22 has a thickness of 2 mm to 3.5 mm. In some embodiments, the glass layer 22 has a thickness of 2 mm to 3 mm. In some embodiments, the glass layer 22 has a thickness of 2 mm to 2.5 mm. In some embodiments, the glass layer 22 has a thickness of 2.5 mm to 4 mm. In some embodiments, the glass layer 22 has a thickness of 2.5 mm to 3.5 mm. In some embodiments, the glass layer 22 has a thickness of 2.5 mm to 3 mm. In some embodiments, the glass layer 22 has a thickness of 3 mm to 4 mm. In some embodiments, the glass layer 22 has a thickness of 3 mm to 3.5 mm. In some embodiments, the glass layer 22 has a thickness of 3.5 mm to 4 mm.

In some embodiments, the glass layer 22 has a thickness of 1 mm. In some embodiments, the glass layer 22 has a thickness of 1.5 mm. In some embodiments, the glass layer 22 has a thickness of 2 mm. In some embodiments, the glass layer 22 has a thickness of 2.5 mm. In some embodiments, the glass layer 22 has a thickness of 3 mm. In some embodiments, the glass layer 22 has a thickness of 3.5 mm. In some embodiments, the glass layer 22 has a thickness of 4 mm.

In some embodiments, the first adhesive layer 26 includes thermosetting polyolefin, thermosetting polyolefin encapsulant material, ethylene-vinyl acetate (EVA), EVA encapsulants, thermoplastic olefin, thermoplastic polyolefin (TPO) or hybrids/combinations thereof.

In some embodiments, the first adhesive layer 26 has a thickness of 0.2 mm to 2 mm. In some embodiments, the first adhesive layer 26 has a thickness of 0.2 mm to 1.5 mm. In some embodiments, the first adhesive layer 26 has a thickness of 0.2 mm to 1 mm. In some embodiments, the first adhesive layer 26 has a thickness of 0.2 mm to 0.5 mm. In some embodiments, the first adhesive layer 26 has a thickness of 0.5 mm to 2 mm. In some embodiments, the first adhesive layer 26 has a thickness of 0.5 mm to 1.5 mm. In some embodiments, the first adhesive layer 26 has a thickness of 0.5 mm to 1 mm. In some embodiments, the first adhesive layer 26 has a thickness of 1 mm to 2 mm. In some embodiments, the first adhesive layer 26 has a thickness of 1 mm to 1.5 mm. In some embodiments, the first adhesive layer 26 has a thickness of 1.5 mm to 2 mm.

In some embodiments, the first adhesive layer 26 has a thickness of 0.2 mm. In some embodiments, the first adhesive layer 26 has a thickness of 0.3 mm. In some embodiments, the first adhesive layer 26 has a thickness of 0.4 mm. In some embodiments, the first adhesive layer 26 has a thickness of 0.45 mm. In some embodiments, the first adhesive layer 26 has a thickness of 0.5 mm. In some embodiments, the first adhesive layer 26 has a thickness of 1 mm. In some embodiments, the first adhesive layer 26 has a thickness of 1.5 mm. In some embodiments, the first adhesive layer 26 has a thickness of 2 mm. In some embodiments, the first adhesive layer 26 has a thickness of 2.5 mm. In some embodiments, the first adhesive layer 26 has a thickness of 3 mm. In some embodiments, the first adhesive layer 26 has a thickness of 3.5 mm. In some embodiments, the first adhesive layer 26 has a thickness of 4 mm.

In another embodiment, the first adhesive layer 26 has a thickness of 1 μm to 900 μm. In some embodiments, the first adhesive layer 26 has a thickness of 1 μm to 900 μm. In some embodiments, the first adhesive layer 26 has a thickness of 1 μm to 850 μm. In some embodiments, the first adhesive layer 26 has a thickness of 1 μm to 800 μm. In some embodiments, the first adhesive layer 26 has a thickness of 1 μm to 750 μm. In some embodiments, the first adhesive layer 26 has a thickness of 1 μm to 700 μm. In some embodiments, the first adhesive layer 26 has a thickness of 1 μm to 650 μm. In some embodiments, the first adhesive layer 26 has a thickness of 1 μm to 600 μm. In some embodiments, the first adhesive layer 26 has a thickness of 1 μm to 550 μm. In some embodiments, the first adhesive layer 26 has a thickness of 1 μm to 500 μm. In some embodiments, the first adhesive layer 26 has a thickness of 1 μm to 450 μm. In some embodiments, the first adhesive layer 26 has a thickness of 1 μm to 400 μm. In some embodiments, the first adhesive layer 26 has a thickness of 1 μm to 350 μm. In some embodiments, the first adhesive layer 26 has a thickness of 1 μm to 300 μm. In some embodiments, the first adhesive layer 26 has a thickness of 1 μm to 250 μm. In some embodiments, the first adhesive layer 26 has a thickness of 1 μm to 200 μm. In some embodiments, the first adhesive layer 26 has a thickness of 1 μm to 150 μm. In some embodiments, the first adhesive layer 26 has a thickness of 1 μm to 100 μm. In some embodiments, the first adhesive layer 26 has a thickness of 1 μm to 50 μm.

In some embodiments, the first adhesive layer 26 has a thickness of 50 μm to 900 μm. In some embodiments, the first adhesive layer 26 has a thickness of 50 μm to 850 μm. In some embodiments, the first adhesive layer 26 has a thickness of 50 μm to 800 μm. In some embodiments, the first adhesive layer 26 has a thickness of 50 μm to 750 μm. In some embodiments, the first adhesive layer 26 has a thickness of 50 μm to 700 μm. In some embodiments, the first adhesive layer 26 has a thickness of 50 μm to 650 μm. In some embodiments, the first adhesive layer 26 has a thickness of 50 μm to 600 μm. In some embodiments, the first adhesive layer 26 has a thickness of 50 μm to 550 μm. In some embodiments, the first adhesive layer 26 has a thickness of 50 μm to 500 μm. In some embodiments, the first adhesive layer 26 has a thickness of 50 μm to 450 μm. In some embodiments, the first adhesive layer 26 has a thickness of 50 μm to 400 μm. In some embodiments, the first adhesive layer 26 has a thickness of 50 μm to 350 μm. In some embodiments, the first adhesive layer 26 has a thickness of 50 μm to 300 μm. In some embodiments, the first adhesive layer 26 has a thickness of 50 μm to 250 μm. In some embodiments, the first adhesive layer 26 has a thickness of 50 μm to 200 μm. In some embodiments, the first adhesive layer 26 has a thickness of 50 μm to 150 μm. In some embodiments, the first adhesive layer 26 has a thickness of 50 μm to 100 μm.

In some embodiments, the first adhesive layer 26 has a thickness of 100 μm to 900 μm. In some embodiments, the first adhesive layer 26 has a thickness of 100 μm to 850 μm. In some embodiments, the first adhesive layer 26 has a thickness of 100 μm to 800 μm. In some embodiments, the first adhesive layer 26 has a thickness of 100 μm to 750 μm. In some embodiments, the first adhesive layer 26 has a thickness of 100 μm to 700 μm. In some embodiments, the first adhesive layer 26 has a thickness of 100 μm to 650 μm. In some embodiments, the first adhesive layer 26 has a thickness of 100 μm to 600 μm. In some embodiments, the first adhesive layer 26 has a thickness of 100 μm to 550 μm. In some embodiments, the first adhesive layer 26 has a thickness of 100 μm to 500 μm. In some embodiments, the first adhesive layer 26 has a thickness of 100 μm to 450 μm. In some embodiments, the first adhesive layer 26 has a thickness of 100 μm to 400 μm. In some embodiments, the first adhesive layer 26 has a thickness of 100 μm to 350 μm. In some embodiments, the first adhesive layer 26 has a thickness of 100 μm to 300 μm. In some embodiments, the first adhesive layer 26 has a thickness of 100 μm to 250 μm. In some embodiments, the first adhesive layer 26 has a thickness of 100 μm to 200 μm. In some embodiments, the first adhesive layer 26 has a thickness of 100 μm to 150 μm.

In some embodiments, the first adhesive layer 26 has a thickness of 150 μm to 900 μm. In some embodiments, the first adhesive layer 26 has a thickness of 150 μm to 850 μm. In some embodiments, the first adhesive layer 26 has a thickness of 150 μm to 800 μm. In some embodiments, the first adhesive layer 26 has a thickness of 150 μm to 750 μm. In some embodiments, the first adhesive layer 26 has a thickness of 150 μm to 700 μm. In some embodiments, the first adhesive layer 26 has a thickness of 150 μm to 650 μm. In some embodiments, the first adhesive layer 26 has a thickness of 150 μm to 600 μm. In some embodiments, the first adhesive layer 26 has a thickness of 150 μm to 550 μm. In some embodiments, the first adhesive layer 26 has a thickness of 150 μm to 500 μm. In some embodiments, the first adhesive layer 26 has a thickness of 150 μm to 450 μm. In some embodiments, the first adhesive layer 26 has a thickness of 150 μm to 400 μm. In some embodiments, the first adhesive layer 26 has a thickness of 150 μm to 350 μm. In some embodiments, the first adhesive layer 26 has a thickness of 150 μm to 300 μm. In some embodiments, the first adhesive layer 26 has a thickness of 150 μm to 250 μm. In some embodiments, the first adhesive layer 26 has a thickness of 150 μm to 200 μm.

In some embodiments, the first adhesive layer 26 has a thickness of 200 μm to 900 μm. In some embodiments, the first adhesive layer 26 has a thickness of 200 μm to 850 μm. In some embodiments, the first adhesive layer 26 has a thickness of 200 μm to 800 μm. In some embodiments, the first adhesive layer 26 has a thickness of 200 μm to 750 μm. In some embodiments, the first adhesive layer 26 has a thickness of 200 μm to 700 μm. In some embodiments, the first adhesive layer 26 has a thickness of 200 μm to 650 μm. In some embodiments, the first adhesive layer 26 has a thickness of 200 μm to 600 μm. In some embodiments, the first adhesive layer 26 has a thickness of 200 μm to 550 μm. In some embodiments, the first adhesive layer 26 has a thickness of 200 μm to 500 μm. In some embodiments, the first adhesive layer 26 has a thickness of 200 μm to 450 μm. In some embodiments, the first adhesive layer 26 has a thickness of 200 μm to 400 μm. In some embodiments, the first adhesive layer 26 has a thickness of 200 μm to 350 μm. In some embodiments, the first adhesive layer 26 has a thickness of 200 μm to 300 μm. In some embodiments, the first adhesive layer 26 has a thickness of 200 μm to 250 μm.

In some embodiments, the first adhesive layer 26 has a thickness of 250 μm to 900 μm. In some embodiments, the first adhesive layer 26 has a thickness of 250 μm to 850 μm. In some embodiments, the first adhesive layer 26 has a thickness of 250 μm to 800 μm. In some embodiments, the first adhesive layer 26 has a thickness of 250 μm to 750 μm. In some embodiments, the first adhesive layer 26 has a thickness of 250 μm to 700 μm. In some embodiments, the first adhesive layer 26 has a thickness of 250 μm to 650 μm. In some embodiments, the first adhesive layer 26 has a thickness of 250 μm to 600 μm. In some embodiments, the first adhesive layer 26 has a thickness of 250 μm to 550 μm. In some embodiments, the first adhesive layer 26 has a thickness of 250 μm to 500 μm. In some embodiments, the first adhesive layer 26 has a thickness of 250 μm to 450 μm. In some embodiments, the first adhesive layer 26 has a thickness of 250 μm to 400 μm. In some embodiments, the first adhesive layer 26 has a thickness of 250 μm to 350 μm. In some embodiments, the first adhesive layer 26 has a thickness of 250 μm to 300 μm.

In some embodiments, the first adhesive layer 26 has a thickness of 300 μm to 900 μm. In some embodiments, the first adhesive layer 26 has a thickness of 300 μm to 850 μm. In some embodiments, the first adhesive layer 26 has a thickness of 300 μm to 800 μm. In some embodiments, the first adhesive layer 26 has a thickness of 300 μm to 750 μm. In some embodiments, the first adhesive layer 26 has a thickness of 300 μm to 700 μm. In some embodiments, the first adhesive layer 26 has a thickness of 300 μm to 650 μm. In some embodiments, the first adhesive layer 26 has a thickness of 300 μm to 600 μm. In some embodiments, the first adhesive layer 26 has a thickness of 300 μm to 550 μm. In some embodiments, the first adhesive layer 26 has a thickness of 300 μm to 500 μm. In some embodiments, the first adhesive layer 26 has a thickness of 300 μm to 450 μm. In some embodiments, the first adhesive layer 26 has a thickness of 300 μm to 400 μm. In some embodiments, the first adhesive layer 26 has a thickness of 300 μm to 350 μm.

In some embodiments, the first adhesive layer 26 has a thickness of 350 μm to 900 μm. In some embodiments, the first adhesive layer 26 has a thickness of 350 μm to 850 μm. In some embodiments, the first adhesive layer 26 has a thickness of 350 μm to 800 μm. In some embodiments, the first adhesive layer 26 has a thickness of 350 μm to 750 μm. In some embodiments, the first adhesive layer 26 has a thickness of 350 μm to 700 μm. In some embodiments, the first adhesive layer 26 has a thickness of 350 μm to 650 μm. In some embodiments, the first adhesive layer 26 has a thickness of 350 μm to 600 μm. In some embodiments, the first adhesive layer 26 has a thickness of 350 μm to 550 μm. In some embodiments, the first adhesive layer 26 has a thickness of 350 μm to 500 μm. In some embodiments, the first adhesive layer 26 has a thickness of 350 μm to 450 μm. In some embodiments, the first adhesive layer 26 has a thickness of 350 μm to 400 μm.

In some embodiments, the first adhesive layer 26 has a thickness of 400 μm to 900 μm. In some embodiments, the first adhesive layer 26 has a thickness of 400 μm to 850 μm. In some embodiments, the first adhesive layer 26 has a thickness of 400 μm to 800 μm. In some embodiments, the first adhesive layer 26 has a thickness of 400 μm to 750 μm. In some embodiments, the first adhesive layer 26 has a thickness of 400 μm to 700 μm. In some embodiments, the first adhesive layer 26 has a thickness of 400 μm to 650 μm. In some embodiments, the first adhesive layer 26 has a thickness of 400 μm to 600 μm. In some embodiments, the first adhesive layer 26 has a thickness of 400 μm to 550 μm. In some embodiments, the first adhesive layer 26 has a thickness of 400 μm to 500 μm. In some embodiments, the first adhesive layer 26 has a thickness of 400 μm to 450 μm.

In some embodiments, the first adhesive layer 26 has a thickness of 450 μm to 900 μm. In some embodiments, the first adhesive layer 26 has a thickness of 450 μm to 850 μm. In some embodiments, the first adhesive layer 26 has a thickness of 450 μm to 800 μm. In some embodiments, the first adhesive layer 26 has a thickness of 450 μm to 750 μm. In some embodiments, the first adhesive layer 26 has a thickness of 450 μm to 700 μm. In some embodiments, the first adhesive layer 26 has a thickness of 450 μm to 650 μm. In some embodiments, the first adhesive layer 26 has a thickness of 450 μm to 600 μm. In some embodiments, the first adhesive layer 26 has a thickness of 450 μm to 550 μm. In some embodiments, the first adhesive layer 26 has a thickness of 450 μm to 500 μm.

In some embodiments, the first adhesive layer 26 has a thickness of 500 μm to 900 μm. In some embodiments, the first adhesive layer 26 has a thickness of 500 μm to 850 μm. In some embodiments, the first adhesive layer 26 has a thickness of 500 μm to 800 μm. In some embodiments, the first adhesive layer 26 has a thickness of 500 μm to 750 μm. In some embodiments, the first adhesive layer 26 has a thickness of 500 μm to 700 μm. In some embodiments, the first adhesive layer 26 has a thickness of 500 μm to 650 μm. In some embodiments, the first adhesive layer 26 has a thickness of 500 μm to 600 μm. In some embodiments, the first adhesive layer 26 has a thickness of 500 μm to 550 μm.

In some embodiments, the first adhesive layer 26 has a thickness of 550 μm to 900 μm. In some embodiments, the first adhesive layer 26 has a thickness of 550 μm to 850 μm. In some embodiments, the first adhesive layer 26 has a thickness of 550 μm to 800 μm. In some embodiments, the first adhesive layer 26 has a thickness of 550 μm to 750 μm. In some embodiments, the first adhesive layer 26 has a thickness of 550 μm to 700 μm. In some embodiments, the first adhesive layer 26 has a thickness of 550 μm to 650 μm. In some embodiments, the first adhesive layer 26 has a thickness of 550 μm to 600 μm.

In some embodiments, the first adhesive layer 26 has a thickness of 600 μm to 900 μm. In some embodiments, the first adhesive layer 26 has a thickness of 600 μm to 850 μm. In some embodiments, the first adhesive layer 26 has a thickness of 600 μm to 800 μm. In some embodiments, the first adhesive layer 26 has a thickness of 600 μm to 750 μm. In some embodiments, the first adhesive layer 26 has a thickness of 600 μm to 700 μm. In some embodiments, the first adhesive layer 26 has a thickness of 600 μm to 650 μm.

In some embodiments, the first adhesive layer 26 has a thickness of 650 μm to 900 μm. In some embodiments, the first adhesive layer 26 has a thickness of 650 μm to 850 μm. In some embodiments, the first adhesive layer 26 has a thickness of 650 μm to 800 μm. In some embodiments, the first adhesive layer 26 has a thickness of 650 μm to 750 μm. In some embodiments, the first adhesive layer 26 has a thickness of 650 μm to 700 μm. In some embodiments, the first adhesive layer 26 has a thickness of 700 μm to 900 μm. In some embodiments, the first adhesive layer 26 has a thickness of 700 μm to 850 μm. In some embodiments, the first adhesive layer 26 has a thickness of 700 μm to 800 μm. In some embodiments, the first adhesive layer 26 has a thickness of 700 μm to 750 μm. In some embodiments, the first adhesive layer 26 has a thickness of 750 μm to 900 μm. In some embodiments, the first adhesive layer 26 has a thickness of 750 μm to 850 μm. In some embodiments, the first adhesive layer 26 has a thickness of 750 μm to 800 μm. In some embodiments, the first adhesive layer 26 has a thickness of 800 μm to 900 μm. In some embodiments, the first adhesive layer 26 has a thickness of 800 μm to 850 μm. In some embodiments, the first adhesive layer 26 has a thickness of 850 μm to 900 μm.

In some embodiments, the first adhesive layer 26 has a thickness of 1 μm. In some embodiments, the first adhesive layer 26 has a thickness of 50 μm. In some embodiments, the first adhesive layer 26 has a thickness of 100 μm. In some embodiments, the first adhesive layer 26 has a thickness of 1 μm. In some embodiments, the first adhesive layer 26 has a thickness of 150 μm. In some embodiments, the first adhesive layer 26 has a thickness of 200 μm. In some embodiments, the first adhesive layer 26 has a thickness of 250 μm. In some embodiments, the first adhesive layer 26 has a thickness of 300 μm. In some embodiments, the first adhesive layer 26 has a thickness of 350 μm. In some embodiments, the first adhesive layer 26 has a thickness of 400 μm. In some embodiments, the first adhesive layer 26 has a thickness of 450 μm. In some embodiments, the first adhesive layer 26 has a thickness of 500 μm. In some embodiments, the first adhesive layer 26 has a thickness of 550 μm. In some embodiments, the first adhesive layer 26 has a thickness of 600 μm. In some embodiments, the first adhesive layer 26 has a thickness of 650 μm. In some embodiments, the first adhesive layer 26 has a thickness of 700 μm. In some embodiments, the first adhesive layer 26 has a thickness of 750 μm. In some embodiments, the first adhesive layer 26 has a thickness of 800 μm. In some embodiments, the first adhesive layer 26 has a thickness of 850 μm. In some embodiments, the first adhesive layer 26 has a thickness of 900 μm.

In some embodiments, the polymer layer 24 includes a fluoropolymer. In certain embodiments, the fluoropolymer may be ethylene tetrafluoroethylene (ETFE), fluoropolymer is polyvinylidene fluoride (PVDF), tetrafluoroethylene-hexafluoropropylene copolymers (FEP), and tetrafluoroethylene-hexafluoropropylene-vinylidene fluoride copolymers (THV), polyvinyl fluoride (PVF), or blends thereof. In some embodiments, the frontsheet includes fluoropolymers, acrylics, polyesters, silicones, polycarbonates, or combinations thereof. In other embodiments, the polymer layer 24 includes polyethylene terephthalate (PET), polyethylene naphthalate (PEN), polyetheretherketone (PEEK), polyaryletherketone (PAEK), polyarylate (PAR), polyetherimide (PEI), polyarylsulfone (PAS), polyethersulfone (PES), polyamideimide (PAI), polyphenylsulfone (PPSU), polyolefin, cyclic olefin copolymers (CPCs), or polyimide. In some embodiments, the polymer layer 24 includes a crosslinked polymeric material. In some embodiments, 50% to 99% of the polymer chains of the polymeric material are crosslinked.

In some embodiments, the polymer layer 24 has a thickness of 0.01 mm to 0.5 mm. In some embodiments, the polymer layer 24 has a thickness of 0.01 mm to 0.45 mm. In some embodiments, the polymer layer 24 has a thickness of 0.01 mm to 0.4 mm. In some embodiments, the polymer layer 24 has a thickness of 0.01 mm to 0.35 mm. In some embodiments, the polymer layer 24 has a thickness of 0.01 mm to 0.3 mm. In some embodiments, the polymer layer 24 has a thickness of 0.01 mm to 0.25 mm. In some embodiments, the polymer layer 24 has a thickness of 0.01 mm to 0.2 mm. In some embodiments, the polymer layer 24 has a thickness of 0.01 mm to 0.15 mm. In some embodiments, the polymer layer 24 has a thickness of 0.01 mm to 0.1 mm.

In some embodiments, the polymer layer 24 has a thickness of 0.01 mm to 0.05 mm. In some embodiments, the polymer layer 24 has a thickness of 0.05 mm to 0.5 mm. In some embodiments, the polymer layer 24 has a thickness of 0.05 mm to 0.45 mm. In some embodiments, the polymer layer 24 has a thickness of 0.05 mm to 0.4 mm. In some embodiments, the polymer layer 24 has a thickness of 0.05 mm to 0.35 mm. In some embodiments, the polymer layer 24 has a thickness of 0.05 mm to 0.3 mm. In some embodiments, the polymer layer 24 has a thickness of 0.05 mm to 0.25 mm. In some embodiments, the polymer layer 24 has a thickness of 0.05 mm to 0.2 mm. In some embodiments, the polymer layer 24 has a thickness of 0.05 mm to 0.15 mm. In some embodiments, the polymer layer 24 has a thickness of 0.05 mm to 0.1 mm.

In some embodiments, the polymer layer 24 has a thickness of 0.1 mm to 0.5 mm. In some embodiments, the polymer layer 24 has a thickness of 0.1 mm to 0.45 mm. In some embodiments, the polymer layer 24 has a thickness of 0.1 mm to 0.4 mm. In some embodiments, the polymer layer 24 has a thickness of 0.1 mm to 0.35 mm. In some embodiments, the polymer layer 24 has a thickness of 0.1 mm to 0.3 mm. In some embodiments, the polymer layer 24 has a thickness of 0.1 mm to 0.25 mm. In some embodiments, the polymer layer 24 has a thickness of 0.1 mm to 0.2 mm. In some embodiments, the polymer layer 24 has a thickness of 0.1 mm to 0.15 mm. In some embodiments, the polymer layer 24 has a thickness of 0.15 mm to 0.5 mm. In some embodiments, the polymer layer 24 has a thickness of 0.15 mm to 0.45 mm. In some embodiments, the polymer layer 24 has a thickness of 0.15 mm to 0.4 mm. In some embodiments, the polymer layer 24 has a thickness of 0.15 mm to 0.35 mm. In some embodiments, the polymer layer 24 has a thickness of 0.15 mm to 0.3 mm. In some embodiments, the polymer layer 24 has a thickness of 0.15 mm to 0.25 mm. In some embodiments, the polymer layer 24 has a thickness of 0.15 mm to 0.2 mm.

In some embodiments, the polymer layer 24 has a thickness of 0.2 mm to 0.5 mm. In some embodiments, the polymer layer 24 has a thickness of 0.2 mm to 0.45 mm. In some embodiments, the polymer layer 24 has a thickness of 0.2 mm to 0.4 mm. In some embodiments, the polymer layer 24 has a thickness of 0.2 mm to 0.35 mm. In some embodiments, the polymer layer 24 has a thickness of 0.2 mm to 0.3 mm. In some embodiments, the polymer layer 24 has a thickness of 0.2 mm to 0.25 mm. In some embodiments, the polymer layer 24 has a thickness of 0.25 mm to 0.5 mm. In some embodiments, the polymer layer 24 has a thickness of 0.25 mm to 0.45 mm. In some embodiments, the polymer layer 24 has a thickness of 0.25 mm to 0.4 mm. In some embodiments, the polymer layer 24 has a thickness of 0.25 mm to 0.35 mm. In some embodiments, the polymer layer 24 has a thickness of 0.25 mm to 0.3 mm.

In some embodiments, the polymer layer 24 has a thickness of 0.3 mm to 0.5 mm. In some embodiments, the polymer layer 24 has a thickness of 0.3 mm to 0.45 mm. In some embodiments, the polymer layer 24 has a thickness of 0.3 mm to 0.4 mm. In some embodiments, the polymer layer 24 has a thickness of 0.3 mm to 0.35 mm. In some embodiments, the polymer layer 24 has a thickness of 0.35 mm to 0.5 mm. In some embodiments, the polymer layer 24 has a thickness of 0.35 mm to 0.45 mm. In some embodiments, the polymer layer 24 has a thickness of 0.35 mm to 0.4 mm. In some embodiments, the polymer layer 24 has a thickness of 0.4 mm to 0.5 mm. In some embodiments, the polymer layer 24 has a thickness of 0.4 mm to 0.45 mm. In some embodiments, the polymer layer 24 has a thickness of 0.45 mm to 0.5 mm.

In some embodiments, the polymer layer 24 has a thickness of 0.01 mm. In some embodiments, the polymer layer 24 has a thickness of 0.05 mm. In some embodiments, the polymer layer 24 has a thickness of 0.1 mm. In some embodiments, the polymer layer 24 has a thickness of 0.15 mm. In some embodiments, the polymer layer 24 has a thickness of 0.2 mm. In some embodiments, the polymer layer 24 has a thickness of 0.25 mm. In some embodiments, the polymer layer 24 has a thickness of 0.3 mm. In some embodiments, the polymer layer 24 has a thickness of 0.35 mm. In some embodiments, the polymer layer 24 has a thickness of 0.4 mm. In some embodiments, the polymer layer 24 has a thickness of 0.45 mm. In some embodiments, the polymer layer 24 has a thickness of 0.5 mm.

In some embodiments, a backsheet 28 is juxtaposed with a second layer 14b of the encapsulant 14. In some embodiments, the backsheet 28 includes a first layer 30 and a second layer 32. In some embodiments, the first layer 30 is juxtaposed with the second layer 14b of the encapsulant 14. In some embodiments, the second layer 32 is juxtaposed with the first layer 30.

In some embodiments, the first layer 30 of the backsheet 28 includes a polymeric material. In some embodiments, the first layer 30 of the backsheet 28 includes polyethylene terephthalate (“PET”). In another embodiment, the first layer 30 of the backsheet 28 includes ethylene tetrafluoroethylene (“ETFE”). In some embodiments, the first layer 30 of the backsheet 28 includes an acrylic such as polymethyl methacrylate (“PMMA”). In some embodiments, the first layer 30 of the backsheet 28 includes thermoplastic polyolefin (TPO). In some embodiments, the first layer 30 of the backsheet 28 includes a single ply TPO roofing membrane. In other embodiments, non-limiting examples of TPO membranes are disclosed in U.S. Pat. No. 9,359,014 to Yang et al., which is incorporated by reference herein in its entirety. In another embodiment, the first layer 30 of the backsheet 28 includes polyvinyl chloride. In some embodiments, the first layer 30 of the backsheet 28 includes ethylene propylene diene monomer (EPDM) rubber. In some embodiments, the first layer 30 of the backsheet 28 includes a flame retardant additive. In some embodiments, the flame retardant additive may be clays, nanoclays, silicas, carbon black, metal hydroxides such as aluminum hydroxide, metal foils, graphite, and combinations thereof.

In some embodiments, the first layer 30 has a thickness of 0.2 mm to 0.5 mm. In another embodiment, the first layer 30 has a thickness of 0.2 mm to 0.4 mm. In another embodiment, the first layer 30 has a thickness of 0.2 mm to 0.3 mm. In some embodiments, the first layer 30 has a thickness of 0.3 mm to 0.5 mm. In another embodiment, the first layer 30 has a thickness of 0.3 mm to 0.4 mm. In some embodiments, the first layer 30 has a thickness of 0.4 mm to 0.5 mm. In some embodiments, the first layer 30 has a thickness of 0.2 mm. In some embodiments, the first layer 30 has a thickness of 0.3 mm. In some embodiments, the first layer 30 has a thickness of 0.4 mm. In some embodiments, the first layer 30 has a thickness of 0.5 mm.

In some embodiments, the second layer 32 of the backsheet 28 includes a polymeric material. In some embodiments, the second layer 32 of the backsheet 28 includes thermoplastic polyolefin (TPO). In some embodiments, the second layer 32 of the backsheet 28 includes a single ply TPO roofing membrane. In other embodiments, non-limiting examples of TPO membranes are disclosed in U.S. Pat. No. 9,359,014 to Yang et al., which is incorporated by reference herein in its entirety. In another embodiment, the second layer 32 of the backsheet 28 includes polyethylene terephthalate (“PET”). In another embodiment, the second layer 32 includes styrene acrylic copolymer. In another embodiment, the second layer 32 of the backsheet 28 includes ethylene tetrafluoroethylene (“ETFE”). In some embodiments, the second layer 32 of the backsheet 28 includes an acrylic such as polymethyl methacrylate (“PMMA”). In another embodiment, the second layer 32 of the backsheet 28 includes polyvinyl chloride. In some embodiments, the second layer 32 of the backsheet 28 includes ethylene propylene diene monomer (EPDM) rubber. In some embodiments, the second layer 32 of the backsheet 28 includes a flame retardant additive. In some embodiments, the flame retardant additive may be clays, nanoclays, silicas, carbon black, metal hydroxides such as aluminum hydroxide, metal foils, graphite, and combinations thereof.

In some embodiments, the second layer 32 has a thickness of 1 mm to 5 mm. In some embodiments, the second layer 32 has a thickness of 1 mm to 4 mm. In some embodiments, the second layer 32 has a thickness of 1 mm to 3 mm. In some embodiments, the second layer 32 has a thickness of 1 mm to 2 mm. In some embodiments, the second layer 32 has a thickness of 2 mm to 5 mm. In some embodiments, the second layer 32 has a thickness of 2 mm to 4 mm. In some embodiments, the second layer 32 has a thickness of 2 mm to 3 mm. In some embodiments, the second layer 32 has a thickness of 3 mm to 5 mm. In some embodiments, the second layer 32 has a thickness of 3 mm to 4 mm. In some embodiments, the second layer 32 has a thickness of 4 mm to 5 mm. In some embodiments, the second layer 32 has a thickness of 1 mm. In some embodiments, the second layer 32 has a thickness of 2 mm. In some embodiments, the second layer 32 has a thickness of 3 mm. In some embodiments, the second layer 32 has a thickness of 4 mm. In some embodiments, the second layer 32 has a thickness of 5 mm.

In some embodiments, the first layer 30 is attached to the second layer 32 by a second adhesive layer 34. In some embodiments, the second adhesive layer 34 may include polyvinyl butyrate, acrylic, silicone, or polycarbonate. In another embodiment, the first adhesive layer 34 may include pressure sensitive adhesives.

In some embodiments, the second adhesive layer 34 includes thermosetting polyolefin, thermosetting polyolefin encapsulant material, thermosetting ethylene-vinyl acetate (EVA), EVA encapsulants, thermoplastic olefin, thermoplastic polyolefin (TPO) or hybrids/combinations thereof.

In some embodiments, the second adhesive layer 34 has a thickness of 0.2 mm to 2 mm. In some embodiments, the second adhesive layer 34 has a thickness of 0.2 mm to 1.5 mm. In some embodiments, the second adhesive layer 34 has a thickness of 0.2 mm to 1 mm. In some embodiments, the second adhesive layer 34 has a thickness of 0.2 mm to 0.5 mm. In some embodiments, the second adhesive layer 34 has a thickness of 0.5 mm to 2 mm. In some embodiments, the second adhesive layer 34 has a thickness of 0.5 mm to 1.5 mm. In some embodiments, the second adhesive layer 34 has a thickness of 0.5 mm to 1 mm. In some embodiments, the second adhesive layer 34 has a thickness of 1 mm to 2 mm. In some embodiments, the second adhesive layer 34 has a thickness of 1 mm to 1.5 mm. In some embodiments, the second adhesive layer 34 has a thickness of 1.5 mm to 2 mm.

In some embodiments, the second adhesive layer 34 has a thickness of 0.2 mm. In some embodiments, the second adhesive layer 34 has a thickness of 0.3 mm. In some embodiments, the second adhesive layer 34 has a thickness of 0.4 mm. In some embodiments, the second adhesive layer 34 has a thickness of 0.45 mm. In some embodiments, the second adhesive layer 34 has a thickness of 0.5 mm. In some embodiments, the second adhesive layer 34 has a thickness of 1 mm. In some embodiments, the second adhesive layer 34 has a thickness of 1.5 mm. In some embodiments, the second adhesive layer 34 has a thickness of 2 mm. In some embodiments, the second adhesive layer 34 has a thickness of 2.5 mm. In some embodiments, the second adhesive layer 34 has a thickness of 3 mm. In some embodiments, the second adhesive layer 34 has a thickness of 3.5 mm. In some embodiments, the second adhesive layer 34 has a thickness of 4 mm.

In another embodiment, the second adhesive layer 34 has a thickness of 1 μm to 900 μm. In some embodiments, the second adhesive layer 34 has a thickness of 1 μm to 900 μm. In some embodiments, the second adhesive layer 34 has a thickness of 1 μm to 850 μm. In some embodiments, the second adhesive layer 34 has a thickness of 1 μm to 800 μm. In some embodiments, the second adhesive layer 34 has a thickness of 1 μm to 750 μm. In some embodiments, the second adhesive layer 34 has a thickness of 1 μm to 700 μm. In some embodiments, the second adhesive layer 34 has a thickness of 1 μm to 650 μm. In some embodiments, the second adhesive layer 34 has a thickness of 1 μm to 600 μm. In some embodiments, the second adhesive layer 34 has a thickness of 1 μm to 550 μm. In some embodiments, the second adhesive layer 34 has a thickness of 1 μm to 500 μm. In some embodiments, the second adhesive layer 34 has a thickness of 1 μm to 450 μm. In some embodiments, the second adhesive layer 34 has a thickness of 1 μm to 400 μm. In some embodiments, the second adhesive layer 34 has a thickness of 1 μm to 350 μm. In some embodiments, the second adhesive layer 34 has a thickness of 1 μm to 300 μm. In some embodiments, the second adhesive layer 34 has a thickness of 1 μm to 250 μm. In some embodiments, the second adhesive layer 34 has a thickness of 1 μm to 200 μm. In some embodiments, the second adhesive layer 34 has a thickness of 1 μm to 150 μm. In some embodiments, the second adhesive layer 34 has a thickness of 1 μm to 100 μm. In some embodiments, the second adhesive layer 34 has a thickness of 1 μm to 50 μm.

In some embodiments, the second adhesive layer 34 has a thickness of 50 μm to 900 μm. In some embodiments, the second adhesive layer 34 has a thickness of 50 μm to 850 μm. In some embodiments, the second adhesive layer 34 has a thickness of 50 μm to 800 μm. In some embodiments, the second adhesive layer 34 has a thickness of 50 μm to 750 μm. In some embodiments, the second adhesive layer 34 has a thickness of 50 μm to 700 μm. In some embodiments, the second adhesive layer 34 has a thickness of 50 μm to 650 μm. In some embodiments, the second adhesive layer 34 has a thickness of 50 μm to 600 μm. In some embodiments, the second adhesive layer 34 has a thickness of 50 μm to 550 μm. In some embodiments, the second adhesive layer 34 has a thickness of 50 μm to 500 μm. In some embodiments, the second adhesive layer 34 has a thickness of 50 μm to 450 μm. In some embodiments, the second adhesive layer 34 has a thickness of 50 μm to 400 μm. In some embodiments, the second adhesive layer 34 has a thickness of 50 μm to 350 μm. In some embodiments, the second adhesive layer 34 has a thickness of 50 μm to 300 μm. In some embodiments, the second adhesive layer 34 has a thickness of 50 μm to 250 μm. In some embodiments, the second adhesive layer 34 has a thickness of 50 μm to 200 μm. In some embodiments, the second adhesive layer 34 has a thickness of 50 μm to 150 μm. In some embodiments, the second adhesive layer 34 has a thickness of 50 μm to 100 μm.

In some embodiments, the second adhesive layer 34 has a thickness of 100 μm to 900 μm. In some embodiments, the second adhesive layer 34 has a thickness of 100 μm to 850 μm. In some embodiments, the second adhesive layer 34 has a thickness of 100 μm to 800 μm. In some embodiments, the second adhesive layer 34 has a thickness of 100 μm to 750 μm. In some embodiments, the second adhesive layer 34 has a thickness of 100 μm to 700 μm. In some embodiments, the second adhesive layer 34 has a thickness of 100 μm to 650 μm. In some embodiments, the second adhesive layer 34 has a thickness of 100 μm to 600 μm. In some embodiments, the second adhesive layer 34 has a thickness of 100 μm to 550 μm. In some embodiments, the second adhesive layer 34 has a thickness of 100 μm to 500 μm. In some embodiments, the second adhesive layer 34 has a thickness of 100 μm to 450 μm. In some embodiments, the second adhesive layer 34 has a thickness of 100 μm to 400 μm. In some embodiments, the second adhesive layer 34 has a thickness of 100 μm to 350 μm. In some embodiments, the second adhesive layer 34 has a thickness of 100 μm to 300 μm. In some embodiments, the second adhesive layer 34 has a thickness of 100 μm to 250 μm. In some embodiments, the second adhesive layer 34 has a thickness of 100 μm to 200 μm. In some embodiments, the second adhesive layer 34 has a thickness of 100 μm to 150 μm.

In some embodiments, the second adhesive layer 34 has a thickness of 150 μm to 900 μm. In some embodiments, the second adhesive layer 34 has a thickness of 150 μm to 850 μm. In some embodiments, the second adhesive layer 34 has a thickness of 150 μm to 800 μm. In some embodiments, the second adhesive layer 34 has a thickness of 150 μm to 750 μm. In some embodiments, the second adhesive layer 34 has a thickness of 150 μm to 700 μm. In some embodiments, the second adhesive layer 34 has a thickness of 150 μm to 650 μm. In some embodiments, the second adhesive layer 34 has a thickness of 150 μm to 600 μm. In some embodiments, the second adhesive layer 34 has a thickness of 150 μm to 550 μm. In some embodiments, the second adhesive layer 34 has a thickness of 150 μm to 500 μm. In some embodiments, the second adhesive layer 34 has a thickness of 150 μm to 450 μm. In some embodiments, the second adhesive layer 34 has a thickness of 150 μm to 400 μm. In some embodiments, the second adhesive layer 34 has a thickness of 150 μm to 350 μm. In some embodiments, the second adhesive layer 34 has a thickness of 150 μm to 300 μm. In some embodiments, the second adhesive layer 34 has a thickness of 150 μm to 250 μm. In some embodiments, the second adhesive layer 34 has a thickness of 150 μm to 200 μm.

In some embodiments, the second adhesive layer 34 has a thickness of 200 μm to 900 μm. In some embodiments, the second adhesive layer 34 has a thickness of 200 μm to 850 μm. In some embodiments, the second adhesive layer 34 has a thickness of 200 μm to 800 μm. In some embodiments, the second adhesive layer 34 has a thickness of 200 μm to 750 μm. In some embodiments, the second adhesive layer 34 has a thickness of 200 μm to 700 μm. In some embodiments, the second adhesive layer 34 has a thickness of 200 μm to 650 μm. In some embodiments, the second adhesive layer 34 has a thickness of 200 μm to 600 μm. In some embodiments, the second adhesive layer 34 has a thickness of 200 μm to 550 μm. In some embodiments, the second adhesive layer 34 has a thickness of 200 μm to 500 μm. In some embodiments, the second adhesive layer 34 has a thickness of 200 μm to 450 μm. In some embodiments, the second adhesive layer 34 has a thickness of 200 μm to 400 μm. In some embodiments, the second adhesive layer 34 has a thickness of 200 μm to 350 μm. In some embodiments, the second adhesive layer 34 has a thickness of 200 μm to 300 μm. In some embodiments, the second adhesive layer 34 has a thickness of 200 μm to 250 μm.

In some embodiments, the second adhesive layer 34 has a thickness of 250 μm to 900 μm. In some embodiments, the second adhesive layer 34 has a thickness of 250 μm to 850 μm. In some embodiments, the second adhesive layer 34 has a thickness of 250 μm to 800 μm. In some embodiments, the second adhesive layer 34 has a thickness of 250 μm to 750 μm. In some embodiments, the second adhesive layer 34 has a thickness of 250 μm to 700 μm. In some embodiments, the second adhesive layer 34 has a thickness of 250 μm to 650 μm. In some embodiments, the second adhesive layer 34 has a thickness of 250 μm to 600 μm. In some embodiments, the second adhesive layer 34 has a thickness of 250 μm to 550 μm. In some embodiments, the second adhesive layer 34 has a thickness of 250 μm to 500 μm. In some embodiments, the second adhesive layer 34 has a thickness of 250 μm to 450 μm. In some embodiments, the second adhesive layer 34 has a thickness of 250 μm to 400 μm. In some embodiments, the second adhesive layer 34 has a thickness of 250 μm to 350 μm. In some embodiments, the second adhesive layer 34 has a thickness of 250 μm to 300 μm.

In some embodiments, the second adhesive layer 34 has a thickness of 300 μm to 900 μm. In some embodiments, the second adhesive layer 34 has a thickness of 300 μm to 850 μm. In some embodiments, the second adhesive layer 34 has a thickness of 300 μm to 800 μm. In some embodiments, the second adhesive layer 34 has a thickness of 300 μm to 750 μm. In some embodiments, the second adhesive layer 34 has a thickness of 300 μm to 700 μm. In some embodiments, the second adhesive layer 34 has a thickness of 300 μm to 650 μm. In some embodiments, the second adhesive layer 34 has a thickness of 300 μm to 600 μm. In some embodiments, the second adhesive layer 34 has a thickness of 300 μm to 550 μm. In some embodiments, the second adhesive layer 34 has a thickness of 300 μm to 500 μm. In some embodiments, the second adhesive layer 34 has a thickness of 300 μm to 450 μm. In some embodiments, the second adhesive layer 34 has a thickness of 300 μm to 400 μm. In some embodiments, the second adhesive layer 34 has a thickness of 300 μm to 350 μm.

In some embodiments, the second adhesive layer 34 has a thickness of 350 μm to 900 μm. In some embodiments, the second adhesive layer 34 has a thickness of 350 μm to 850 μm. In some embodiments, the second adhesive layer 34 has a thickness of 350 μm to 800 μm. In some embodiments, the second adhesive layer 34 has a thickness of 350 μm to 750 μm. In some embodiments, the second adhesive layer 34 has a thickness of 350 μm to 700 μm. In some embodiments, the second adhesive layer 34 has a thickness of 350 μm to 650 μm. In some embodiments, the second adhesive layer 34 has a thickness of 350 μm to 600 μm. In some embodiments, the second adhesive layer 34 has a thickness of 350 μm to 550 μm. In some embodiments, the second adhesive layer 34 has a thickness of 350 μm to 500 μm. In some embodiments, the second adhesive layer 34 has a thickness of 350 μm to 450 μm. In some embodiments, the second adhesive layer 34 has a thickness of 350 μm to 400 μm.

In some embodiments, the second adhesive layer 34 has a thickness of 400 μm to 900 μm. In some embodiments, the second adhesive layer 34 has a thickness of 400 μm to 850 μm. In some embodiments, the second adhesive layer 34 has a thickness of 400 μm to 800 μm. In some embodiments, the second adhesive layer 34 has a thickness of 400 μm to 750 μm. In some embodiments, the second adhesive layer 34 has a thickness of 400 μm to 700 μm. In some embodiments, the second adhesive layer 34 has a thickness of 400 μm to 650 μm. In some embodiments, the second adhesive layer 34 has a thickness of 400 μm to 600 μm. In some embodiments, the second adhesive layer 34 has a thickness of 400 μm to 550 μm. In some embodiments, the second adhesive layer 34 has a thickness of 400 μm to 500 μm. In some embodiments, the second adhesive layer 34 has a thickness of 400 μm to 450 μm.

In some embodiments, the second adhesive layer 34 has a thickness of 450 μm to 900 μm. In some embodiments, the second adhesive layer 34 has a thickness of 450 μm to 850 μm. In some embodiments, the second adhesive layer 34 has a thickness of 450 μm to 800 μm. In some embodiments, the second adhesive layer 34 has a thickness of 450 μm to 750 μm. In some embodiments, the second adhesive layer 34 has a thickness of 450 μm to 700 μm. In some embodiments, the second adhesive layer 34 has a thickness of 450 μm to 650 μm. In some embodiments, the second adhesive layer 34 has a thickness of 450 μm to 600 μm. In some embodiments, the second adhesive layer 34 has a thickness of 450 μm to 550 μm. In some embodiments, the second adhesive layer 34 has a thickness of 450 μm to 500 μm.

In some embodiments, the second adhesive layer 34 has a thickness of 500 μm to 900 μm. In some embodiments, the second adhesive layer 34 has a thickness of 500 μm to 850 μm. In some embodiments, the second adhesive layer 34 has a thickness of 500 μm to 800 μm. In some embodiments, the second adhesive layer 34 has a thickness of 500 μm to 750 μm. In some embodiments, the second adhesive layer 34 has a thickness of 500 μm to 700 μm. In some embodiments, the second adhesive layer 34 has a thickness of 500 μm to 650 μm. In some embodiments, the second adhesive layer 34 has a thickness of 500 μm to 600 μm. In some embodiments, the second adhesive layer 34 has a thickness of 500 μm to 550 μm.

In some embodiments, the second adhesive layer 34 has a thickness of 550 μm to 900 μm. In some embodiments, the second adhesive layer 34 has a thickness of 550 μm to 850 μm. In some embodiments, the second adhesive layer 34 has a thickness of 550 μm to 800 μm. In some embodiments, the second adhesive layer 34 has a thickness of 550 μm to 750 μm. In some embodiments, the second adhesive layer 34 has a thickness of 550 μm to 700 μm. In some embodiments, the second adhesive layer 34 has a thickness of 550 μm to 650 μm. In some embodiments, the second adhesive layer 34 has a thickness of 550 μm to 600 μm.

In some embodiments, the second adhesive layer 34 has a thickness of 600 μm to 900 μm. In some embodiments, the second adhesive layer 34 has a thickness of 600 μm to 850 μm. In some embodiments, the second adhesive layer 34 has a thickness of 600 μm to 800 μm. In some embodiments, the second adhesive layer 34 has a thickness of 600 μm to 750 μm. In some embodiments, the second adhesive layer 34 has a thickness of 600 μm to 700 μm. In some embodiments, the second adhesive layer 34 has a thickness of 600 μm to 650 μm.

In some embodiments, the second adhesive layer 34 has a thickness of 650 μm to 900 μm. In some embodiments, the second adhesive layer 34 has a thickness of 650 μm to 850 μm. In some embodiments, the second adhesive layer 34 has a thickness of 650 μm to 800 μm. In some embodiments, the second adhesive layer 34 has a thickness of 650 μm to 750 μm. In some embodiments, the second adhesive layer 34 has a thickness of 650 μm to 700 μm. In some embodiments, the second adhesive layer 34 has a thickness of 700 μm to 900 μm. In some embodiments, the second adhesive layer 34 has a thickness of 700 μm to 850 μm. In some embodiments, the second adhesive layer 34 has a thickness of 700 μm to 800 μm. In some embodiments, the second adhesive layer 34 has a thickness of 700 μm to 750 μm. In some embodiments, the second adhesive layer 34 has a thickness of 750 μm to 900 μm. In some embodiments, the second adhesive layer 34 has a thickness of 750 μm to 850 μm. In some embodiments, the second adhesive layer 34 has a thickness of 750 μm to 800 μm. In some embodiments, the second adhesive layer 34 has a thickness of 800 μm to 900 μm. In some embodiments, the second adhesive layer 34 has a thickness of 800 μm to 850 μm. In some embodiments, the second adhesive layer 34 has a thickness of 850 μm to 900 μm.

In some embodiments, the second adhesive layer 34 has a thickness of 1 μm. In some embodiments, the second adhesive layer 34 has a thickness of 50 μm. In some embodiments, the second adhesive layer 34 has a thickness of 100 μm. In some embodiments, the second adhesive layer 34 has a thickness of 1 μm. In some embodiments, the second adhesive layer 34 has a thickness of 150 μm. In some embodiments, the second adhesive layer 34 has a thickness of 200 μm. In some embodiments, the second adhesive layer 34 has a thickness of 250 μm. In some embodiments, the second adhesive layer 34 has a thickness of 300 μm. In some embodiments, the second adhesive layer 34 has a thickness of 350 μm. In some embodiments, the second adhesive layer 34 has a thickness of 400 μm. In some embodiments, the second adhesive layer 34 has a thickness of 450 μm. In some embodiments, the second adhesive layer 34 has a thickness of 500 μm. In some embodiments, the second adhesive layer 34 has a thickness of 550 μm. In some embodiments, the second adhesive layer 34 has a thickness of 600 μm. In some embodiments, the second adhesive layer 34 has a thickness of 650 μm. In some embodiments, the second adhesive layer 34 has a thickness of 700 μm. In some embodiments, the second adhesive layer 34 has a thickness of 750 μm. In some embodiments, the second adhesive layer 34 has a thickness of 800 μm. In some embodiments, the second adhesive layer 34 has a thickness of 850 μm. In some embodiments, the second adhesive layer 34 has a thickness of 900 μm.

In another embodiment, the first layer 30 is attached to the second layer 32 by thermal bonding.

In some embodiments, a sealant is added to one or more edges of the roofing module 10 to prevent corrosion and delamination. In some embodiments, the sealant is a polymer sealant.

In some embodiments, the roofing module 10 is flexible. As used herein, the term “flexible” means capable of bending without breaking or plastic deformation, and with respect to certain embodiments of the roofing module 10, the roofing module 10 is capable of being bent without breakage or plastic deformation of any of the layers thereof, i.e., any of the layers of the frontsheet 16, the backsheet 28, and the encapsulant 14.

In some embodiments, a roofing system 45 includes at least one of the roofing module 10 and at least one photovoltaic module 50. In some embodiments, the at least one of the roofing module 10 includes a plurality of roofing modules 10. In some embodiments, the at least one photovoltaic module 50 includes a plurality of photovoltaic modules 50. In some embodiments, the at least one photovoltaic module 50 is electrically active. In some embodiments, the system includes at least one nonactive (i.e., not electrically active) roofing module 10 and at least one electrically active photovoltaic module 50. In some embodiments, the system includes at least one nonactive roofing module 10, at least one electrically active photovoltaic module 50, and at least one nonactive photovoltaic module 50. In some embodiments, the at least one roofing module 10 and the at least one photovoltaic module 50 are installed on a roof deck 80 of a structure. In some embodiments, the appearance of the at least one roofing module 10 aesthetically matches the appearance of the at least one photovoltaic module 50. As used herein, the term “aesthetically matches” means having a similar overall appearance, texture, gloss, and/or color, and with respect to an embodiment of the roofing module 10, the roofing module 10 includes an appearance, texture, gloss, and/or color that is similar to those of the photovoltaic module 50 when viewed from a vantage point located at a ground level of the structure. In some embodiments, the color is measured under a CIELAB color space system. In some embodiments, the gloss can be quantified in accordance with the ASTM E430 Standard Test Methods for Measurement of Gloss of High-Gloss Surfaces by Abridged Goniophotometry. In some embodiments, the difference in appearance between each of the roofing module 10 and the photovoltaic module 50 are visually perceptible by and subjective to a human.

In some embodiments, the roofing module 10 includes a first thickness and the photovoltaic module 50 includes a second thickness. In some embodiments, the percentage difference between the first thickness of the roofing module 10 and the second thickness of the photovoltaic module 50 is 0.1% to 30%. In some embodiments, the percentage difference between the first thickness of the roofing module 10 and the second thickness of the photovoltaic module 50 is 0.1% to 25%. In some embodiments, the percentage difference between the first thickness of the roofing module 10 and the second thickness of the photovoltaic module 50 is 0.1% to 20%. In some embodiments, the percentage difference between the first thickness of the roofing module 10 and the second thickness of the photovoltaic module 50 is 0.1% to 15%. In some embodiments, the percentage difference between the first thickness of the roofing module 10 and the second thickness of the photovoltaic module 50 is 0.1% to 10%. In some embodiments, the percentage difference between the first thickness of the roofing module 10 and the second thickness of the photovoltaic module 50 is 0.1% to 5%.

In some embodiments, the percentage difference between the first thickness of the roofing module 10 and the second thickness of the photovoltaic module 50 is 5% to 30%. In some embodiments, the percentage difference between the first thickness of the roofing module 10 and the second thickness of the photovoltaic module 50 is 5% to 25%. In some embodiments, the percentage difference between the first thickness of the roofing module 10 and the second thickness of the photovoltaic module 50 is 5% to 20%. In some embodiments, the percentage difference between the first thickness of the roofing module 10 and the second thickness of the photovoltaic module 50 is 5% to 15%. In some embodiments, the percentage difference between the first thickness of the roofing module 10 and the second thickness of the photovoltaic module 50 is 5% to 10%. In some embodiments, the percentage difference between the first thickness of the roofing module 10 and the second thickness of the photovoltaic module 50 is 10% to 30%. In some embodiments, the percentage difference between the first thickness of the roofing module 10 and the second thickness of the photovoltaic module 50 is 10% to 25%. In some embodiments, the percentage difference between the first thickness of the roofing module 10 and the second thickness of the photovoltaic module 50 is 10% to 20%. In some embodiments, the percentage difference between the first thickness of the roofing module 10 and the second thickness of the photovoltaic module 50 is 10% to 15%.

In some embodiments, the percentage difference between the first thickness of the roofing module 10 and the second thickness of the photovoltaic module 50 is 15% to 30%. In some embodiments, the percentage difference between the first thickness of the roofing module 10 and the second thickness of the photovoltaic module 50 is 15% to 25%. In some embodiments, the percentage difference between the first thickness of the roofing module 10 and the second thickness of the photovoltaic module 50 is 15% to 20%. In some embodiments, the percentage difference between the first thickness of the roofing module 10 and the second thickness of the photovoltaic module 50 is 20% to 30%. In some embodiments, the percentage difference between the first thickness of the roofing module 10 and the second thickness of the photovoltaic module 50 is 20% to 25%. In some embodiments, the percentage difference between the first thickness of the roofing module 10 and the second thickness of the photovoltaic module 50 is 25% to 30%.

In some embodiments, the first thickness of the roofing module 10 is 5 mm to 20 mm. In some embodiments, the first thickness of the roofing module 10 is 5 mm to 15 mm. In some embodiments, the first thickness of the roofing module 10 is 5 mm to 10 mm. In some embodiments, the first thickness of the roofing module 10 is 5 mm to 7 mm. In some embodiments, the first thickness of the roofing module 10 is 5 mm to 6 mm. In some embodiments, the first thickness of the roofing module 10 is 6 mm to 20 mm. In some embodiments, the first thickness of the roofing module 10 is 6 mm to 15 mm. In some embodiments, the first thickness of the roofing module 10 is 6 mm to 10 mm. In some embodiments, the first thickness of the roofing module 10 is 6 mm to 7 mm.

In some embodiments, the first thickness of the roofing module 10 is 7 mm to 20 mm. In some embodiments, the first thickness of the roofing module 10 is 7 mm to 15 mm. In some embodiments, the first thickness of the roofing module 10 is 7 mm to 10 mm. In some embodiments, the first thickness of the roofing module 10 is 10 mm to 20 mm. In some embodiments, the first thickness of the roofing module 10 is 10 mm to 15 mm. In some embodiments, the first thickness of the roofing module 10 is 15 mm to 20 mm.

In some embodiments, the first thickness of the roofing module 10 is 5 mm. In some embodiments, the first thickness of the roofing module 10 is 6 mm. In some embodiments, the first thickness of the roofing module 10 is 7 mm. In some embodiments, the first thickness of the roofing module 10 is 10 mm. In some embodiments, the first thickness of the roofing module 10 is 15 mm. In some embodiments, the first thickness of the roofing module 10 is 20 mm.

In some embodiments, the second thickness of the photovoltaic module 50 is 5 mm to 20 mm. In some embodiments, the second thickness of the photovoltaic module 50 is 5 mm to 15 mm. In some embodiments, the second thickness of the photovoltaic module 50 is 5 mm to 10 mm. In some embodiments, the second thickness of the photovoltaic module 50 is 5 mm to 7 mm. In some embodiments, the second thickness of the photovoltaic module 50 is 5 mm to 6 mm. In some embodiments, the second thickness of the photovoltaic module 50 is 6 mm to 20 mm. In some embodiments, the second thickness of the photovoltaic module 50 is 6 mm to 15 mm. In some embodiments, the second thickness of the photovoltaic module 50 is 6 mm to 10 mm. In some embodiments, the second thickness of the photovoltaic module 50 is 6 mm to 7 mm.

In some embodiments, the second thickness of the photovoltaic module 50 is 7 mm to 20 mm. In some embodiments, the second thickness of the photovoltaic module 50 is 7 mm to 15 mm. In some embodiments, the second thickness of the photovoltaic module 50 is 7 mm to 10 mm. In some embodiments, the second thickness of the photovoltaic module 50 is 10 mm to 20 mm. In some embodiments, the second thickness of the photovoltaic module 50 is 10 mm to 15 mm. In some embodiments, the second thickness of the photovoltaic module 50 is 15 mm to 20 mm.

In some embodiments, the second thickness of the photovoltaic module 50 is 5 mm. In some embodiments, the second thickness of the photovoltaic module 50 is 6 mm. In some embodiments, the second thickness of the photovoltaic module 50 is 7 mm. In some embodiments, the second thickness of the photovoltaic module 50 is 10 mm. In some embodiments, the second thickness of the photovoltaic module 50 is 15 mm. In some embodiments, the second thickness of the photovoltaic module 50 is 20 mm.

In some embodiments, the roofing module 10 includes a length L1 extending from the first end 18 to the second end 20. In some embodiments, the length L1 is 30 inches to 80 inches. In some embodiments, the length L1 is 30 inches to 75 inches. In some embodiments, the length L1 is 30 inches to 70 inches. In some embodiments, the length L1 is 30 inches to 65 inches. In some embodiments, the length L1 is 30 inches to 60 inches. In some embodiments, the length L1 is 30 inches to 55 inches. In some embodiments, the length L1 is 30 inches to 50 inches. In some embodiments, the length L1 is 30 inches to 45 inches. In some embodiments, the length L1 is 30 inches to 40 inches. In some embodiments, the length L1 is 30 inches to 35 inches.

In some embodiments, the length L1 is 35 inches to 80 inches. In some embodiments, the length L1 is 35 inches to 75 inches. In some embodiments, the length L1 is 35 inches to 70 inches. In some embodiments, the length L1 is 35 inches to 65 inches. In some embodiments, the length L1 is 35 inches to 60 inches. In some embodiments, the length L1 is 35 inches to 55 inches. In some embodiments, the length L1 is 35 inches to 50 inches. In some embodiments, the length L1 is 35 inches to 45 inches. In some embodiments, the length L1 is 35 inches to 40 inches. In some embodiments, the length L1 is 40 inches to 80 inches. In some embodiments, the length L1 is 40 inches to 75 inches. In some embodiments, the length L1 is 40 inches to 70 inches. In some embodiments, the length L1 is 40 inches to 65 inches. In some embodiments, the length L1 is 40 inches to 60 inches. In some embodiments, the length L1 is 40 inches to 55 inches. In some embodiments, the length L1 is 40 inches to 50 inches. In some embodiments, the length L1 is 40 inches to 45 inches.

In some embodiments, the length L1 is 45 inches to 80 inches. In some embodiments, the length L1 is 45 inches to 75 inches. In some embodiments, the length L1 is 45 inches to 70 inches. In some embodiments, the length L1 is 45 inches to 65 inches. In some embodiments, the length L1 is 45 inches to 60 inches. In some embodiments, the length L1 is 45 inches to 55 inches. In some embodiments, the length L1 is 45 inches to 50 inches. In some embodiments, the length L1 is 50 inches to 80 inches. In some embodiments, the length L1 is 50 inches to 75 inches. In some embodiments, the length L1 is 50 inches to 70 inches. In some embodiments, the length L1 is 50 inches to 65 inches. In some embodiments, the length L1 is 50 inches to 60 inches. In some embodiments, the length L1 is 50 inches to 55 inches.

In some embodiments, the length L1 is 55 inches to 80 inches. In some embodiments, the length L1 is 55 inches to 75 inches. In some embodiments, the length L1 is 55 inches to 70 inches. In some embodiments, the length L1 is 55 inches to 65 inches. In some embodiments, the length L1 is 55 inches to 60 inches. In some embodiments, the length L1 is 60 inches to 80 inches. In some embodiments, the length L1 is 60 inches to 75 inches. In some embodiments, the length L1 is 60 inches to 70 inches. In some embodiments, the length L1 is 60 inches to 65 inches. In some embodiments, the length L1 is 65 inches to 80 inches. In some embodiments, the length L1 is 65 inches to 75 inches. In some embodiments, the length L1 is 65 inches to 70 inches. In some embodiments, the length L1 is 70 inches to 80 inches. In some embodiments, the length L1 is 70 inches to 75 inches. In some embodiments, the length L1 is 75 inches to 80 inches.

In some embodiments, the length L1 is 30 inches. In some embodiments, the length L1 is 35 inches. In some embodiments, the length L1 is 40 inches. In some embodiments, the length L1 is 45 inches. In some embodiments, the length L1 is 50 inches. In some embodiments, the length L1 is 55 inches. In some embodiments, the length L1 is 60 inches. In some embodiments, the length L1 is 65 inches. In some embodiments, the length L1 is 70 inches. In some embodiments, the length L1 is 75 inches. In some embodiments, the length L1 is 80 inches.

In some embodiments, the roofing module 10 is cuttable. In some embodiments, the roofing module 10 is cuttable to a desired size and shape. As used herein, the term “cuttable” means capable of being cut or penetrated with or as if with by an edged instrument, and with respect to certain embodiments of the roofing module 10, the roofing module 10 is capable of being cut or penetrated by an edged instrument such as a cutting knife, scissors, razor, or other suitable roofing module cutting instruments and tools. In some embodiments, the roofing module 10 is configured to be installed on the roof deck 80. In some embodiments, the roofing module 10 is configured to be installed on non-solar roof planes of the roof deck 80. In some embodiments, the roofing module 10 is configured to be installed either partially or fully around an array of the photovoltaic modules 50. In some embodiments, the roofing module 10 is cuttable to a size and shape for positioning around obstacles, such as vents, chimneys, antennas, and other roofing structures. In some embodiments, the roofing module 10 cuttable to a size and shape to extend to roofing eaves and ridges.

In some embodiments, the frontsheet 16 of the roofing module 10 is textured to impart an appearance of a traditional asphalt roofing module. In some embodiments, the frontsheet 16 of the roofing module 10 is textured to impart an appearance of and aesthetically match the photovoltaic modules 50. In some embodiments, the frontsheet 16 includes an embossed surface. In some embodiments, the frontsheet 16 includes a plurality of indentations. In some embodiments, the indentations are created by embossing a portion of the frontsheet 16. In another embodiment, the indentations are created by embossing the polymer layer 24 of the frontsheet 16.

In an embodiment, the frontsheet 16 includes a matte surface texture. In some embodiments, the frontsheet 16 includes a matte film. In some embodiments, the matte film includes matte ETFE. In another embodiment, the matte film includes a coated film. In some embodiments, the frontsheet 16 includes a smooth surface. In some embodiments, the frontsheet 16 includes a glossy material, such as a shiny film, gloss patterned glass, or a gloss non-patterned glass. In some embodiments, the roofing module 10 having a textured frontsheet 16 is an element of the system 45 including a plurality of the roofing modules 10, in which adjacent roofing modules have textured frontsheets 16 that are patterned differently from one another, thereby imparting a random-seeming appearance to the system 45.

In some embodiments, the first layer 14a of the encapsulant 14 is a light scattering encapsulant layer. In some embodiments, the first layer 14a of the encapsulant 14 has a light scattering value as measured in accordance with an ASTM E430 standard. In some embodiments, the light scattering value is 0.1 HU to 12 HU. In some embodiments, the first layer 14a of the encapsulant 14 includes a pattern. In certain embodiments, the pattern includes at least one of squares, rectangles, lozenges, diamonds, rhombuses, parallelograms, circles, hexagons, triangles, or a combination thereof. In another embodiment, a first portion of the first layer 14a of the encapsulant 14 has a first light scattering value as measured in accordance with an ASTM E430 standard, and a second portion of the first layer 14a of the encapsulant 14 has a second light scattering value as measured in accordance with the ASTM E430 standard. In some embodiments, the second light scattering value is greater than the first light scattering value. In some embodiments, the first light scattering value is 0.1 HU to 12 HU. In some embodiments, the second light scattering value is 0.1 HU to 12 HU.

In another embodiment, the roofing module 10 includes a material similar to a standard asphalt roofing module (e.g., polymer material on asphalt). In another embodiment, the roofing module 10 includes a material similar to a non-asphalt (NAS) roofing module (e.g., polymer coated fiberglass mat). In another embodiment, the roofing module 10 includes a non-asphalt (NAS) material. In some embodiments, the NAS material includes a thermoplastic polymer. In some embodiments, the thermoplastic polymer includes at least one of a polyolefin, a vinyl polymer, and combinations thereof. In some embodiments, the polyolefin comprises one of (i) a polypropylene, (ii) a polyethylene, or (iii) a copolymer of propylene and ethylene. In some embodiments, the vinyl polymer is polyvinyl butyral (PVB). In some embodiments, the NAS material includes a filler. In some embodiments, the filler includes at least one of an organic filler, an inorganic mineral filler, or combinations thereof. In some embodiments, the filler is at least one of calcium carbonate, barium sulfate, calcium sulfate, talc, limestone, perlite, silica, fumed silica, precipitated silica, quartz, aluminum trihydrate, magnesium hydroxide, colemanite, titanium dioxide, snow white, fly ash, graphene nanoparticles, carbon black, recycled rubber tires, recycled shingles, recycled thermoplastic resins, basalt, roofing granules, clay, and combinations thereof. In other embodiments, non-limiting examples of NAS materials are disclosed in U.S. Patent Application Publication No. 2020/0224419 to Boss et al., which is incorporated by reference herein in its entirety. In another embodiment, the roofing module 10 is made from a combination of any or all of the foregoing.

In some embodiments, the roofing module 10 is adapted to be a component of a photovoltaic system that includes a fire resistance that conforms to standards under UL 790/ASTM E 108 test standards. In some embodiments, the roofing module 10 includes a Class A rating when tested in accordance with UL 790/ASTM E 108.

In some embodiments, the roofing module 10 includes a headlap portion 36. In some embodiments, the headlap portion 36 extends from the first end 18 to the second end 20. In some embodiments, at least a portion of a reveal portion of one of the roofing modules 10 overlays at least a portion of the headlap portion 36 of another of the roofing modules 10. In some embodiments, at least a portion of a reveal portion of one of the photovoltaic modules 50 overlays at least a portion of the headlap portion of one of the roofing modules 10. In some embodiments, the roofing module 10 includes at least one side lap 38. In some embodiments, the at least one side lap 38 is located at the first end 18. In some embodiments, the at least one side lap 38 is located at the second end 20. In some embodiments, the at least one side lap 38 includes a side lap 38 located at the first end 18 and a side lap 38 located at the second end 20. In some embodiments, the side lap 38 of one of the roofing modules 10 overlays the side lap 38 of another of the roofing modules 10. In some embodiments, a side lap of one of the photovoltaic modules 50 overlays the side lap 38 of one of the roofing modules 10. In some embodiments, the roofing module 10 is a watershedding layer when installed on the roof deck 80. In some embodiments, the watershedding of the roofing module 10 is substantially similar to the watershedding of the photovoltaic module 50.

In some embodiments, the system 45 includes at least one wireway 40 installed proximate to the first end 18 of the roofing module 10. In some embodiments, the at least one wireway 40 is installed proximate to the second end 20 of the roofing module 10. In some embodiments, the at least one wireway 40 is installed intermediate the first end 18 of one of the roofing modules 10 and a second end 20 of another one of the roofing modules 10. In some embodiments, the at least one wireway 40 includes a lid. In some embodiments, the lid is removably attached to the at least one wireway 40. In some embodiments, the at least one wireway 40 includes a plurality of the wireways 40. In some embodiments, one of the lids of one of the plurality of wireways 40 overlaps another of the lids of another of the plurality of wireways 40. In some embodiments, the at least one wireway 40 overlays a corresponding one of the side laps 38. In some embodiments, the at least one wireway 40 includes a height of 1 mm to 20 mm. In some embodiments, the at least one wireway 40 includes a single wireway installed proximate to the first end of each of the roofing modules 10. In some embodiments, the at least one wireway 40 does not include any electrical components or electrical wires or cables therein.

In some embodiments, a method includes the steps of:
obtaining a plurality of the roofing modules 10
obtaining a plurality of the photovoltaic modules 50
installing the plurality of photovoltaic modules 50 on the roof deck 80;
cutting at least one of the plurality of roofing modules 10 to a size and shape; and
installing the plurality of roofing modules 10 on the roof deck 80 proximate to the plurality of photovoltaic modules 50, the at least one cell 12 of each of the plurality of roofing modules 10 is electrically inactive, and the at least one solar cell of at least one of the plurality of photovoltaic modules 50 is electrically active.

In some embodiments, the plurality of roofing modules 10 and the plurality of photovoltaic modules 50 are installed on the roof deck 80 a single roof face. In another embodiment, the plurality of roofing modules 10 and the plurality of photovoltaic modules 50 are installed on the roof deck 80 in multiple roof faces. In another embodiment, the plurality of roofing modules 10 and the plurality of photovoltaic modules 50 are installed on all faces of the roof deck 80. In some embodiments, the system includes a plurality of roofing shingles. In some embodiments, the plurality of roofing shingles includes asphalt shingles.

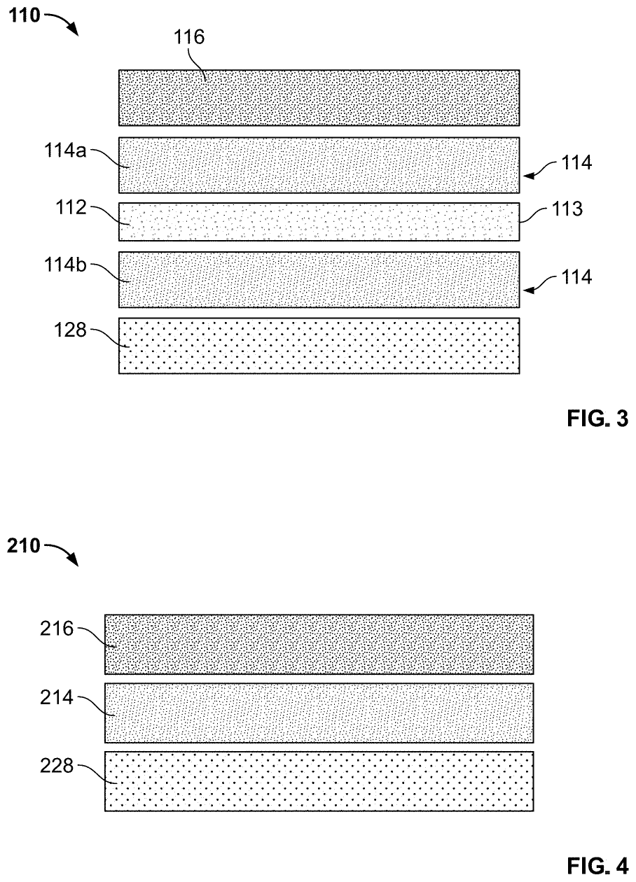

FIG. 3 shows an embodiment of a roofing module 110. The roofing module 110 includes a structure and function similar to the roofing module 10, except for certain differences described hereinafter. In some embodiments, the roofing module 110 includes a first layer 112, an encapsulant 114 encapsulating the first layer 112, a frontsheet 116 juxtaposed with a first layer 114a of the encapsulant 114, and a backsheet 128 juxtaposed with a second layer 114b of the encapsulant 114. In some embodiments, the first layer 114a of the encapsulant 114 is a UV blocking encapsulant layer. In some embodiments, the first layer 114a of the encapsulant 114 is a non-UV blocking encapsulant layer.

In some embodiments, the frontsheet 116 includes a fluoropolymer. In certain embodiments, the fluoropolymer may be ethylene tetrafluoroethylene (ETFE), fluoropolymer is polyvinylidene fluoride (PVDF), tetrafluoroethylene-hexafluoropropylene copolymers (FEP), and tetrafluoroethylene-hexafluoropropylene-vinylidene fluoride copolymers (THV), polyvinyl fluoride (PVF), or blends thereof. In some embodiments, the frontsheet includes fluoropolymers, acrylics, polyesters, silicones, polycarbonates, or combinations thereof. In other embodiments, the frontsheet 116 includes polyethylene terephthalate (PET), polyethylene naphthalate (PEN), polyetheretherketone (PEEK), polyaryletherketone (PAEK), polyarylate (PAR), polyetherimide (PEI), polyarylsulfone (PAS), polyethersulfone (PES), polyamideimide (PAI), polyphenylsulfone (PPSU), polyolefin, cyclic olefin copolymers (CPCs), or polyimide. In some embodiments, the frontsheet 116 includes an ultraviolet (UV) light blocking film. In some embodiments, the frontsheet 116 includes a crosslinked polymeric material. In some embodiments, 50% to 99% of the polymer chains of the polymeric material are crosslinked. In some embodiments, the frontsheet 116 includes a single layer.

In some embodiments, the first layer 112 includes polyethylene terephthalate (PET). In another embodiment, the first layer 112 includes thermoplastic polyolefin (TPO). In some embodiments, the first layer 112 includes a single ply TPO roofing membrane. In some embodiments, the first layer 112 is plasma-treated. In some embodiments, the plasma-treated first layer 112 includes thermoplastic polyolefins (TPO), polyvinyl chlorides (PVC), cyclopiazonic acid (CPA), chlorinated polyethylene resins (CPE), ethylene interpolymers (EIP), nitrile butadiene polymers (NBP), polyisobutylenes (PIB), atactic-polypropylene (APP), APP-modified bitumen, poly(styrene-butadiene-styrene) (SBS), styrene ethylene butylene styrene (SEBS), ethylene propylene diene monomers (EDPM), chlorosulfonated polyethylene rubbers (CSPE), polychloroprene (CR), extracellular region membranes (ECR), polycarbonate, nylon, polyvinyl acetate, polystyrene, polytetrafluoroethylene, polyvinylidene fluoride (PVDF), polyurethane, epoxy and the like. In some embodiments, the first layer 112 includes a non-asphalt (NAS) roofing material. In some embodiments, the NAS material includes a thermoplastic polymer. In some embodiments, the thermoplastic polymer includes at least one of a polyolefin, a vinyl polymer, and combinations thereof. In some embodiments, the polyolefin comprises one of (i) a polypropylene, (ii) a polyethylene, or (iii) a copolymer of propylene and ethylene. In some embodiments, the vinyl polymer is polyvinyl butyral (PVB). In some embodiments, the NAS material includes a filler. In some embodiments, the filler includes at least one of an organic filler, an inorganic mineral filler, or combinations thereof. In some embodiments, the filler is at least one of calcium carbonate, barium sulfate, calcium sulfate, talc, limestone, perlite, silica, fumed silica, precipitated silica, quartz, aluminum trihydrate, magnesium hydroxide, colemanite, titanium dioxide, snow white, fly ash, graphene nanoparticles, carbon black, recycled rubber tires, recycled shingles, recycled thermoplastic resins, basalt, roofing granules, clay, and combinations thereof. In other embodiments, non-limiting examples of NAS materials are disclosed in U.S. Patent Application Publication No. 2020/0224419 to Boss et al., which is incorporated by reference herein in its entirety.

In some embodiments, the first layer 112 includes polyvinyl chloride (PVC). In some embodiments, the first layer 112 includes ethylene propylene diene monomer (EPDM) rubber. In some embodiments, a pattern is printed on a first surface 113 of the first layer 112. In some embodiments, a pattern or depiction of solar cells is printed on the first surface 113 of the first layer 112. In some embodiments, the pattern or depiction of solar cells includes a depiction of a plurality of cell fingers. In some embodiments, the depiction of the plurality of cell fingers is similar in size, shape and grain pattern of cell fingers 1340 described below. In some embodiments, the pattern is printed on the first surface 113 of the first layer 112 by ink jet printing. In some embodiments, the pattern is printed on the first surface 113 of the first layer 112 by laser printing. In some embodiments, the pattern is printed on the first surface 113 of the first layer 112 by lithography. In some embodiments, the pattern is printed on the first surface 113 of the first layer 112 by flexography. In another embodiment, the first layer 112 is painted. In another embodiment, the first layer 112 is a colored layer. In another embodiment, the first layer 112 includes a black color. In some embodiments, the color of the first layer 112 includes a mixture of colors. In some embodiments, the first layer 112 includes an infrared reflective pigment. In some embodiments, the infrared reflective pigment includes graphene. In some embodiments, the roofing module 110 meets standards of California Building Energy Efficiency Standards of Residential and Nonresidential Buildings, Title 24, Part 6.

In some embodiments, the first layer 112 includes magnesium oxide (MgO). In some embodiments, the first layer 112 includes 35% to 50% by weight of MgO. In some embodiments, the first layer 112 includes 35% to 45% by weight of MgO. In some embodiments, the first layer 112 includes 35% to 40% by weight of MgO. In some embodiments, the first layer 112 includes 40% to 50% by weight of MgO. In some embodiments, the first layer 112 includes 40% to 45% by weight of MgO. In some embodiments, the first layer 112 includes 45% to 50% by weight of MgO. In some embodiments, the first layer 112 includes 35% by weight of MgO. In some embodiments, the first layer 112 includes 40% by weight of MgO. In some embodiments, the first layer 112 includes 45% by weight of MgO. In some embodiments, the first layer 112 includes 50% by weight of MgO.

In some embodiments, the first layer 112 includes magnesium hydroxide (Mg(OH)₂). In some embodiments, the first layer 112 includes 35% to 50% by weight of Mg(OH)₂. In some embodiments, the first layer 112 includes 35% to 45% by weight of Mg(OH)₂. In some embodiments, the first layer 112 includes 35% to 40% by weight of Mg(OH)₂. In some embodiments, the first layer 112 includes 40% to 50% by weight of Mg(OH)₂. In some embodiments, the first layer 112 includes 40% to 45% by weight of Mg(OH)₂. In some embodiments, the first layer 112 includes 45% to 50% by weight of Mg(OH)₂. In some embodiments, the first layer 112 includes 35% by weight of Mg(OH)₂. In some embodiments, the first layer 112 includes 40% by weight of Mg(OH)₂. In some embodiments, the first layer 112 includes 45% by weight of Mg(OH)₂. In some embodiments, the first layer 112 includes 50% by weight of Mg(OH)₂.

In some embodiments, the first layer 112 includes ketone ethylene ester (KEE). In some embodiments, the first layer 112 includes a PVC-KEE hybrid membrane. In some embodiments, the roofing module 110 is adapted to be a component of a photovoltaic system that includes a fire resistance that conforms to standards under UL 790/ASTM E 108 test standards. In some embodiments, the roofing module 110 includes a Class A rating when tested in accordance with UL 790/ASTM E 108.

In some embodiments, the first layer 112 has a thickness of 0.1 mm to 1 mm. In some embodiments, the first layer 112 has a thickness of 0.1 mm to 0.9 mm. In some embodiments, the first layer 112 has a thickness of 0.1 mm to 0.8 mm. In some embodiments, the first layer 112 has a thickness of 0.1 mm to 0.7 mm. In some embodiments, the first layer 112 has a thickness of 0.1 mm to 0.6 mm. In some embodiments, the first layer 112 has a thickness of 0.1 mm to 0.5 mm. In some embodiments, the first layer 112 has a thickness of 0.1 mm to 0.4 mm. In some embodiments, the first layer 112 has a thickness of 0.1 mm to 0.3 mm. In some embodiments, the first layer 112 has a thickness of 0.1 mm to 0.2 mm.

In some embodiments, the first layer 112 has a thickness of 0.2 mm to 1 mm. In some embodiments, the first layer 112 has a thickness of 0.2 mm to 0.9 mm. In some embodiments, the first layer 112 has a thickness of 0.2 mm to 0.8 mm. In some embodiments, the first layer 112 has a thickness of 0.2 mm to 0.7 mm. In some embodiments, the first layer 112 has a thickness of 0.2 mm to 0.6 mm. In some embodiments, the first layer 112 has a thickness of 0.2 mm to 0.5 mm. In some embodiments, the first layer 112 has a thickness of 0.2 mm to 0.4 mm. In some embodiments, the first layer 112 has a thickness of 0.2 mm to 0.3 mm.

In some embodiments, the first layer 112 has a thickness of 0.3 mm to 1 mm. In some embodiments, the first layer 112 has a thickness of 0.3 mm to 0.9 mm. In some embodiments, the first layer 112 has a thickness of 0.3 mm to 0.8 mm. In some embodiments, the first layer 112 has a thickness of 0.3 mm to 0.7 mm. In some embodiments, the first layer 112 has a thickness of 0.3 mm to 0.6 mm. In some embodiments, the first layer 112 has a thickness of 0.3 mm to 0.5 mm. In some embodiments, the first layer 112 has a thickness of 0.3 mm to 0.4 mm. In some embodiments, the first layer 112 has a thickness of 0.4 mm to 1 mm. In some embodiments, the first layer 112 has a thickness of 0.4 mm to 0.9 mm. In some embodiments, the first layer 112 has a thickness of 0.4 mm to 0.8 mm. In some embodiments, the first layer 112 has a thickness of 0.4 mm to 0.7 mm. In some embodiments, the first layer 112 has a thickness of 0.4 mm to 0.6 mm. In some embodiments, the first layer 112 has a thickness of 0.4 mm to 0.5 mm.

In some embodiments, the first layer 112 has a thickness of 0.5 mm to 1 mm. In some embodiments, the first layer 112 has a thickness of 0.5 mm to 0.9 mm. In some embodiments, the first layer 112 has a thickness of 0.5 mm to 0.8 mm. In some embodiments, the first layer 112 has a thickness of 0.5 mm to 0.7 mm. In some embodiments, the first layer 112 has a thickness of 0.5 mm to 0.6 mm. In some embodiments, the first layer 112 has a thickness of 0.6 mm to 1 mm. In some embodiments, the first layer 112 has a thickness of 0.6 mm to 0.9 mm. In some embodiments, the first layer 112 has a thickness of 0.6 mm to 0.8 mm. In some embodiments, the first layer 112 has a thickness of 0.6 mm to 0.7 mm. In some embodiments, the first layer 112 has a thickness of 0.7 mm to 1 mm. In some embodiments, the first layer 112 has a thickness of 0.7 mm to 0.9 mm. In some embodiments, the first layer 112 has a thickness of 0.7 mm to 0.8 mm. In some embodiments, the first layer 112 has a thickness of 0.8 mm to 1 mm. In some embodiments, the first layer 112 has a thickness of 0.8 mm to 0.9 mm. In some embodiments, the first layer 112 has a thickness of 0.9 mm to 1 mm.

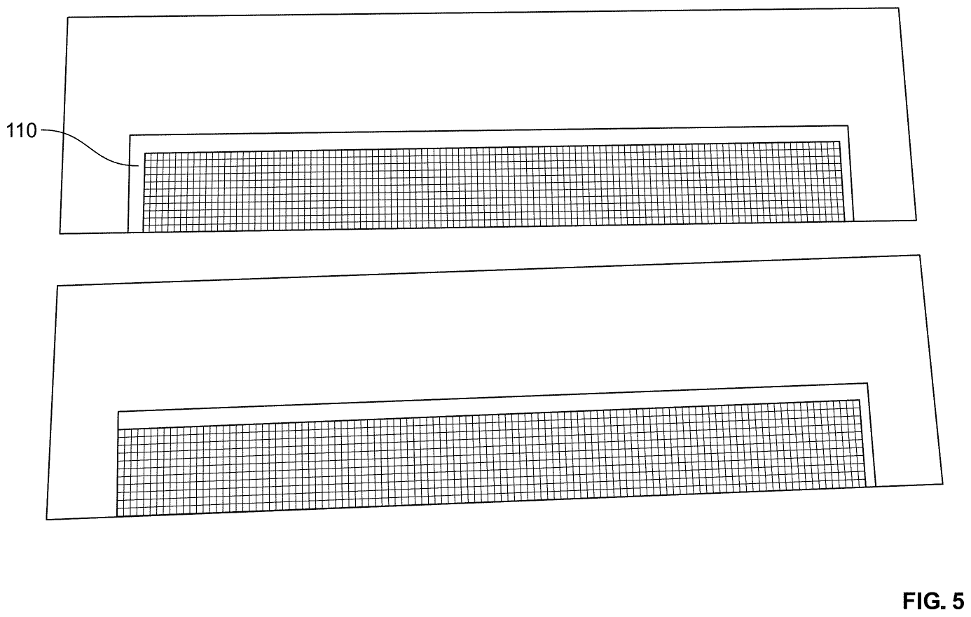

In some embodiments, the backsheet 128 includes a polymeric material. In some embodiments, the backsheet 128 includes thermoplastic polyolefin (TPO). In some embodiments, the backsheet 128 includes a single ply TPO roofing membrane. In other embodiments, non-limiting examples of TPO membranes are disclosed in U.S. Pat. No. 9,359,014 to Yang et al., which is incorporated by reference herein in its entirety. In another embodiment, the backsheet includes polyethylene terephthalate (“PET”). In another embodiment, the backsheet 128 includes ethylene tetrafluoroethylene (“ETFE”). In some embodiments, the backsheet 128 includes an acrylic such as polymethyl methacrylate (“PMMA”). In another embodiment, the backsheet 128 includes polyvinyl chloride. In some embodiments, the backsheet 128 includes ethylene propylene diene monomer (EPDM) rubber. In some embodiments, the backsheet 128 includes a flame retardant additive. In some embodiments, the flame retardant additive may be clays, nanoclays, silicas, carbon black, metal hydroxides such as aluminum hydroxide, metal foils, graphite, and combinations thereof. In some embodiments, the backsheet 128 is a single layer. FIG. 5 shows a prototype of an embodiment of the roofing module 110 pre-lamination and post-lamination thereof.

In some embodiments, the roofing module 110 is cuttable. In some embodiments, the roofing module 110 is cuttable to a desired size and shape.

In some embodiments, a method includes the steps of:
obtaining a plurality of the roofing modules 110;
obtaining a plurality of the photovoltaic modules 50;
installing the plurality of the photovoltaic modules 50 on the roof deck 80;
cutting at least one of the plurality of roofing modules 110 to a size and shape; and
installing the plurality of roofing modules 110 on the roof deck 80 proximate to the plurality of photovoltaic modules 50, wherein the at least one solar cell of at least one of the plurality of the photovoltaic modules 50 is electrically active.

FIG. 4 shows an embodiment of a roofing module 210. The roofing module 210 includes a structure and function similar to the roofing module 110, except for certain differences described hereinafter. In some embodiments, the roofing module 210 includes an encapsulant 214, a frontsheet 216 juxtaposed with a first surface of the encapsulant 214, and a backsheet 228 juxtaposed with a second surface of the encapsulant 214. In some embodiments, the encapsulant 214 is a UV blocking encapsulant. In some embodiments, the encapsulant 214 is a non-UV blocking encapsulant.

In some embodiments, the frontsheet 216 includes a fluoropolymer. In certain embodiments, the fluoropolymer may be ethylene tetrafluoroethylene (ETFE), fluoropolymer is polyvinylidene fluoride (PVDF), tetrafluoroethylene-hexafluoropropylene copolymers (FEP), and tetrafluoroethylene-hexafluoropropylene-vinylidene fluoride copolymers (THV), polyvinyl fluoride (PVF), or blends thereof. In some embodiments, the frontsheet includes fluoropolymers, acrylics, polyesters, silicones, polycarbonates, or combinations thereof. In other embodiments, the frontsheet 216 includes polyethylene terephthalate (PET), polyethylene naphthalate (PEN), polyetheretherketone (PEEK), polyaryletherketone (PAEK), polyarylate (PAR), polyetherimide (PEI), polyarylsulfone (PAS), polyethersulfone (PES), polyamideimide (PAI), polyphenylsulfone (PPSU), polyolefin, cyclic olefin copolymers (CPCs), or polyimide. In some embodiments, the frontsheet 216 includes an ultraviolet (UV) light blocking film. In some embodiments, the frontsheet 216 includes a crosslinked polymeric material. In some embodiments, 50% to 99% of the polymer chains of the polymeric material are crosslinked. In some embodiments, the frontsheet 216 includes a single layer.

In some embodiments, the backsheet 228 includes a polymeric material. In some embodiments, the backsheet 228 includes thermoplastic polyolefin (TPO). In some embodiments, the backsheet 228 is plasma-treated. In some embodiments, the plasma-treated backsheet 228 includes thermoplastic polyolefins (TPO), polyvinyl chlorides (PVC), cyclopiazonic acid (CPA), chlorinated polyethylene resins (CPE), ethylene interpolymers (EIP), nitrile butadiene polymers (NBP), polyisobutylenes (PIB), atactic-polypropylene (APP), APP-modified bitumen, poly(styrene-butadiene-styrene) (SBS), styrene ethylene butylene styrene (SEBS), ethylene propylene diene monomers (EDPM), chlorosulfonated polyethylene rubbers (CSPE), polychloroprene (CR), extracellular region membranes (ECR), polycarbonate, nylon, polyvinyl acetate, polystyrene, polytetrafluoroethylene, polyvinylidene fluoride (PVDF), polyurethane, epoxy and the like. In some embodiments, the backsheet 228 includes a non-asphalt (NAS) roofing material.

In some embodiments, the NAS material includes a thermoplastic polymer. In some embodiments, the thermoplastic polymer includes at least one of a polyolefin, a vinyl polymer, and combinations thereof. In some embodiments, the polyolefin comprises one of (i) a polypropylene, (ii) a polyethylene, or (iii) a copolymer of propylene and ethylene. In some embodiments, the vinyl polymer is polyvinyl butyral (PVB). In some embodiments, the NAS material includes a filler. In some embodiments, the filler includes at least one of an organic filler, an inorganic mineral filler, or combinations thereof. In some embodiments, the filler is at least one of calcium carbonate, barium sulfate, calcium sulfate, talc, limestone, perlite, silica, fumed silica, precipitated silica, quartz, aluminum trihydrate, magnesium hydroxide, colemanite, titanium dioxide, snow white, fly ash, graphene nanoparticles, carbon black, recycled rubber tires, recycled shingles, recycled thermoplastic resins, basalt, roofing granules, clay, and combinations thereof. In other embodiments, non-limiting examples of NAS materials are disclosed in U.S. Patent Application Publication No. 2020/0224419 to Boss et al., which is incorporated by reference herein in its entirety.

In some embodiments, the backsheet 228 includes polyvinyl chloride (PVC). In some embodiments, the backsheet 228 includes a single ply TPO roofing membrane. In other embodiments, non-limiting examples of TPO membranes are disclosed in U.S. Pat. No. 9,359,014 to Yang et al., which is incorporated by reference herein in its entirety. In another embodiment, the backsheet includes polyethylene terephthalate (“PET”). In another embodiment, the backsheet 228 includes ethylene tetrafluoroethylene (“ETFE”). In some embodiments, the backsheet 228 includes an acrylic such as polymethyl methacrylate (“PMMA”). In another embodiment, the backsheet 228 includes polyvinyl chloride. In some embodiments, the backsheet 228 includes ethylene propylene diene monomer (EPDM) rubber. In some embodiments, the backsheet 228 includes a flame retardant additive. In some embodiments, the flame retardant additive may be clays, nanoclays, silicas, carbon black, metal hydroxides such as aluminum hydroxide, metal foils, graphite, and combinations thereof. In some embodiments, the backsheet 228 is a single layer. In some embodiments, a pattern or depiction of solar cells is printed on a first surface of the backsheet 228. In some embodiments, the pattern or depiction of solar cells includes a depiction of a plurality of cell fingers. In some embodiments, the depiction of the plurality of cell fingers is similar in size, shape and grain pattern of the cell fingers 1340 described below. In another embodiment, the backsheet 228 is painted. In another embodiment, the backsheet 228 includes a black color. In some embodiments, the backsheet 228 includes an infrared reflective pigment. In some embodiments, the infrared reflective pigment includes graphene. In some embodiments, the roofing module 210 meets standards of California Building Energy Efficiency Standards of Residential and Nonresidential Buildings, Title 24, Part 6.

In some embodiments, the backsheet 228 includes magnesium oxide (MgO). In some embodiments, the backsheet 228 includes 35% to 50% by weight of MgO. In some embodiments, the backsheet 228 includes 35% to 45% by weight of MgO. In some embodiments, the backsheet 228 includes 35% to 40% by weight of MgO. In some embodiments, the backsheet 228 includes 40% to 50% by weight of MgO. In some embodiments, the backsheet 228 includes 40% to 45% by weight of MgO. In some embodiments, the backsheet 228 includes 45% to 50% by weight of MgO. In some embodiments, the backsheet 228 includes 35% by weight of MgO. In some embodiments, the backsheet 228 includes 40% by weight of MgO. In some embodiments, the backsheet 228 includes 45% by weight of MgO. In some embodiments, the backsheet 228 includes 50% by weight of MgO.

In some embodiments, the backsheet 228 includes ketone ethylene ester (KEE). In some embodiments, the backsheet 228 includes a PVC-KEE hybrid membrane. In some embodiments, the roofing module 210 is adapted to be a component of a photovoltaic system that includes a fire resistance that conforms to standards under UL 790/ASTM E 108 test standards. In some embodiments, the roofing module 210 includes a Class A rating when tested in accordance with UL 790/ASTM E 108.

In some embodiments, a method includes the steps of:
obtaining a plurality of the roofing modules 210;
obtaining a plurality of the photovoltaic modules 50;
installing the plurality of the photovoltaic modules 50 on the roof deck 80;
cutting at least one of the plurality of roofing modules 210 to a size and shape; and
installing the plurality of roofing modules 210 on the roof deck 80 proximate to the plurality of photovoltaic modules 50, wherein the at least one solar cell of at least one of the plurality of the photovoltaic modules 50 is electrically active.

In some embodiments, the roofing module 210 is cuttable. In some embodiments, the roofing module 210 is cuttable to a desired size and shape.

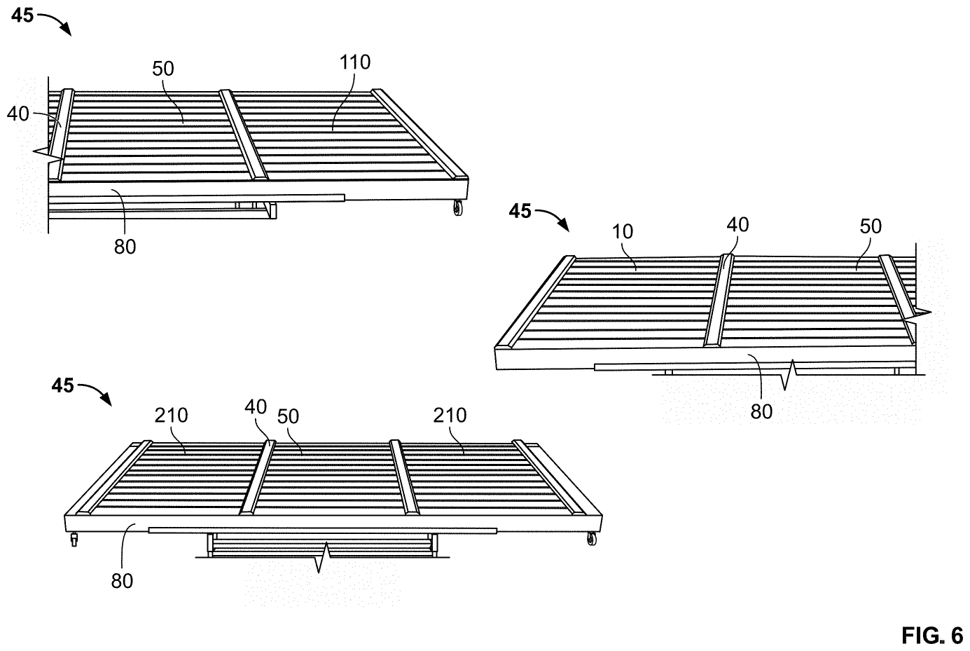

FIG. 6 shows an embodiments of the roofing modules 10, 110, 210 on a roof deck. Option 1 shows the non-active roofing modules 110 and the active photovoltaic modules 50 on the roof deck 80. Option 2 shows the nonactive roofing modules 10 and the active photovoltaic modules 50 on the roof deck 80. Option 3 shows the nonactive roofing modules 210 and the active photovoltaic modules 50 on the roof deck 80.

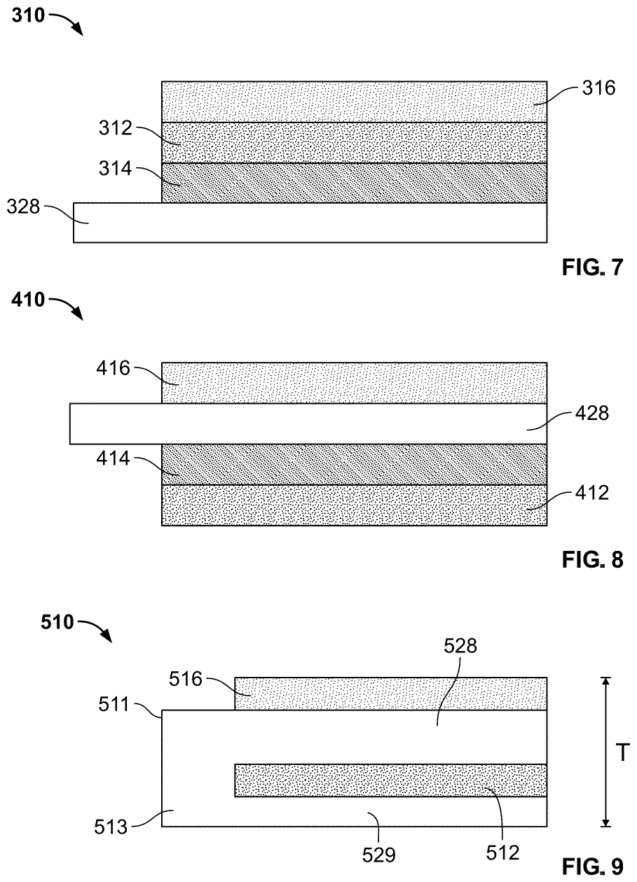

FIG. 7 shows another embodiment of a roofing module 310. The roofing module 310 includes a structure and function similar to the roofing module 210, except for certain differences described hereinafter. In some embodiments, the roofing module 310 includes a layer 312 having a first surface and a second surface opposite the first surface, a frontsheet 316 juxtaposed with a first surface of the layer 312, and an encapsulant 314 having a first surface and a second surface opposite the first surface, and juxtaposed with a second surface of the layer 312. In some embodiments, a pattern is printed on a first surface of the layer 312. In some embodiments, a pattern or depiction of solar cells is printed on the first surface of the layer 312. In some embodiments, the pattern or depiction of solar cells includes a depiction of a plurality of cell fingers. In some embodiments, the depiction of the plurality of cell fingers is similar in size, shape and grain pattern of the cell fingers 1340 described below. In some embodiments, the layer 312 is rigid. As used herein, the term “rigid” means substantially stiff. In some embodiments, the layer 312 is made from metal. In some embodiments, the layer 312 is made from aluminum. In some embodiments, the layer 312 is made from galvanized aluminum. In another embodiment, the layer 312 is made from an FR-4 glass-reinforced epoxy laminate material.

In some embodiments, the layer 312 includes a thickness of 0.01 inch to 0.1 inch. In another embodiment, the layer 312 includes a thickness of 0.01 inch to 0.09 inch. In another embodiment, the layer 312 includes a thickness of 0.01 inch to 0.08 inch. In another embodiment, the layer 312 includes a thickness of 0.01 inch to 0.07 inch. In another embodiment, the layer 312 includes a thickness of 0.01 inch to 0.06 inch. In another embodiment, the layer 312 includes a thickness of 0.01 inch to 0.05 inch. In another embodiment, the layer 312 includes a thickness of 0.01 inch to 0.04 inch. In another embodiment, the layer 312 includes a thickness of 0.01 inch to 0.03 inch. In another embodiment, the layer 312 includes a thickness of 0.01 inch to 0.02 inch.

In some embodiments, the layer 312 includes a thickness of 0.02 inch to 0.1 inch. In another embodiment, the layer 312 includes a thickness of 0.02 inch to 0.09 inch. In another embodiment, the layer 312 includes a thickness of 0.02 inch to 0.08 inch. In another embodiment, the layer 312 includes a thickness of 0.02 inch to 0.07 inch. In another embodiment, the layer 312 includes a thickness of 0.02 inch to 0.06 inch. In another embodiment, the layer 312 includes a thickness of 0.02 inch to 0.05 inch. In another embodiment, the layer 312 includes a thickness of 0.02 inch to 0.04 inch. In another embodiment, the layer 312 includes a thickness of 0.02 inch to 0.03 inch.

In some embodiments, the layer 312 includes a thickness of 0.03 inch to 0.1 inch. In another embodiment, the layer 312 includes a thickness of 0.03 inch to 0.09 inch. In another embodiment, the layer 312 includes a thickness of 0.03 inch to 0.08 inch. In another embodiment, the layer 312 includes a thickness of 0.03 inch to 0.07 inch. In another embodiment, the layer 312 includes a thickness of 0.03 inch to 0.06 inch. In another embodiment, the layer 312 includes a thickness of 0.03 inch to 0.05 inch. In another embodiment, the layer 312 includes a thickness of 0.03 inch to 0.04 inch.

In some embodiments, the layer 312 includes a thickness of 0.04 inch to 0.1 inch. In another embodiment, the layer 312 includes a thickness of 0.04 inch to 0.09 inch. In another embodiment, the layer 312 includes a thickness of 0.04 inch to 0.08 inch. In another embodiment, the layer 312 includes a thickness of 0.04 inch to 0.07 inch. In another embodiment, the layer 312 includes a thickness of 0.04 inch to 0.06 inch. In another embodiment, the layer 312 includes a thickness of 0.04 inch to 0.05 inch. In some embodiments, the layer 312 includes a thickness of 0.05 inch to 0.1 inch. In another embodiment, the layer 312 includes a thickness of 0.05 inch to 0.09 inch. In another embodiment, the layer 312 includes a thickness of 0.05 inch to 0.08 inch. In another embodiment, the layer 312 includes a thickness of 0.05 inch to 0.07 inch. In another embodiment, the layer 312 includes a thickness of 0.05 inch to 0.06 inch.

In some embodiments, the layer 312 includes a thickness of 0.06 inch to 0.1 inch. In another embodiment, the layer 312 includes a thickness of 0.06 inch to 0.09 inch. In another embodiment, the layer 312 includes a thickness of 0.06 inch to 0.08 inch. In another embodiment, the layer 312 includes a thickness of 0.06 inch to 0.07 inch. In some embodiments, the layer 312 includes a thickness of 0.07 inch to 0.1 inch. In another embodiment, the layer 312 includes a thickness of 0.07 inch to 0.09 inch. In another embodiment, the layer 312 includes a thickness of 0.07 inch to 0.08 inch. In some embodiments, the layer 312 includes a thickness of 0.08 inch to 0.1 inch. In another embodiment, the layer 312 includes a thickness of 0.08 inch to 0.09 inch. In some embodiments, the layer 312 includes a thickness of 0.09 inch to 0.1 inch.

In some embodiments, the layer 312 includes a thickness of 0.01 inch. In some embodiments, the layer 312 includes a thickness of 0.02 inch. In some embodiments, the layer 312 includes a thickness of 0.03 inch. In some embodiments, the layer 312 includes a thickness of 0.04 inch. In some embodiments, the layer 312 includes a thickness of 0.05 inch. In some embodiments, the layer 312 includes a thickness of 0.06 inch. In some embodiments, the layer 312 includes a thickness of 1/16 inch. In some embodiments, the layer 312 includes a thickness of 0.07 inch. In some embodiments, the layer 312 includes a thickness of 0.08 inch. In some embodiments, the layer 312 includes a thickness of 0.09 inch. In some embodiments, the layer 312 includes a thickness of 0.1 inch.

In some embodiments, the frontsheet 316 is a UV blocking frontsheet. In some embodiments, the frontsheet 316 is a non-UV blocking frontsheet. In some embodiments, the frontsheet 316 is a UV blocking coating. In some embodiments, a backsheet 328 is juxtaposed with the second surface of the encapsulant 314. In other embodiments, the backsheet 328 includes a structure and materials similar to the backsheet 228. In some embodiments, the backsheet 328 includes thermoplastic polyolefin (TPO).

In some embodiments, the roofing module 310 is cuttable. In some embodiments, the roofing module 310 is cuttable to a desired size and shape.

FIG. 8 shows another embodiment of a roofing module 410. The roofing module 410 includes a structure and function similar to the roofing module 310, except for certain differences described hereinafter. In some embodiments, the roofing module 410 includes a layer 412 having a first surface and a second surface opposite the first surface, an encapsulant 414 having a first surface and a second surface opposite the first surface and juxtaposed with a first surface of the layer 412, a layer 428 having a first surface and a second surface opposite the first surface and juxtaposed with the first surface of the encapsulant 414, and a frontsheet 416 juxtaposed with the first surface of the layer 428. In some embodiments, a pattern is printed on a first surface of the layer 428. In some embodiments, a pattern or depiction of solar cells is printed on the first surface of the layer 428. In some embodiments, the pattern or depiction of solar cells includes a depiction of a plurality of cell fingers. In some embodiments, the depiction of the plurality of cell fingers is similar in size, shape and grain pattern of the cell fingers 1340 described below. In some embodiments, the layer 428 includes a structure and materials similar to the backsheet 228. In some embodiments, the layer 428 includes thermoplastic polyolefin (TPO).

In some embodiments, the layer 412 is rigid. In some embodiments, the layer 412 is made from metal. In some embodiments, the layer 412 is made from aluminum. In some embodiments, the layer 412 is made from galvanized aluminum. In another embodiment, the layer 412 is made from an FR-4 glass-reinforced epoxy laminate material. In some embodiments, the frontsheet 416 is a UV blocking frontsheet. In some embodiments, the frontsheet 416 is a non-UV blocking frontsheet. In some embodiments, the frontsheet 416 is a UV blocking coating.

In some embodiments, the roofing module 410 is cuttable. In some embodiments, the roofing module 410 is cuttable to a desired size and shape.

FIG. 9 shows another embodiment of a roofing module 510. In some embodiments, the roofing module 510 includes a first layer 528 having a first surface, a second layer 529 having a second surface, and a third layer 512 intermediate the first layer 528 and the second layer 529. In some embodiments, the first layer 528 includes a first end 511 and the second layer 529 includes a first end 513. In some embodiments, each of the first layer 528 and the second layer 529 is made from materials similar to those of the backsheet 228. In some embodiments, each of the first layer 528 and the second layer 529 is made from thermoplastic polyolefin (TPO). In some embodiments, the first end 511 of the first layer 528 and the first end 513 of the second layer 529 are unitary. In some embodiments, a pattern is printed on a first surface of the first layer 528. In some embodiments, a pattern or depiction of solar cells is printed on the first surface of the first layer 528. In some embodiments, the pattern or depiction of solar cells includes a depiction of a plurality of cell fingers. In some embodiments, the depiction of the plurality of cell fingers is similar in size, shape and grain pattern of the cell fingers 1340 described below.

In some embodiments, the first layer 528 and the second layer 529 include a total thickness T of 1 mm to 10 mm. In another embodiment, the first layer 528 and the second layer 529 include a total thickness T of 1 mm to 9 mm. In another embodiment, the first layer 528 and the second layer 529 include a total thickness T of 1 mm to 8 mm. In another embodiment, the first layer 528 and the second layer 529 include a total thickness T of 1 mm to 7 mm. In another embodiment, the first layer 528 and the second layer 529 include a total thickness T of 1 mm to 6 mm. In another embodiment, the first layer 528 and the second layer 529 include a total thickness T of 1 mm to 5 mm. In another embodiment, the first layer 528 and the second layer 529 include a total thickness T of 1 mm to 4 mm. In another embodiment, the first layer 528 and the second layer 529 include a total thickness T of 1 mm to 3 mm. In another embodiment, the first layer 528 and the second layer 529 include a total thickness T of 1 mm to 2 mm.

In some embodiments, the first layer 528 and the second layer 529 include a total thickness T of 2 mm to 10 mm. In another embodiment, the first layer 528 and the second layer 529 include a total thickness T of 2 mm to 9 mm. In another embodiment, the first layer 528 and the second layer 529 include a total thickness T of 2 mm to 8 mm. In another embodiment, the first layer 528 and the second layer 529 include a total thickness T of 2 mm to 7 mm. In another embodiment, the first layer 528 and the second layer 529 include a total thickness T of 2 mm to 6 mm. In another embodiment, the first layer 528 and the second layer 529 include a total thickness T of 2 mm to 5 mm. In another embodiment, the first layer 528 and the second layer 529 include a total thickness T of 2 mm to 4 mm. In another embodiment, the first layer 528 and the second layer 529 include a total thickness T of 2 mm to 3 mm.

In some embodiments, the first layer 528 and the second layer 529 include a total thickness T of 3 mm to 10 mm. In another embodiment, the first layer 528 and the second layer 529 include a total thickness T of 3 mm to 9 mm. In another embodiment, the first layer 528 and the second layer 529 include a total thickness T of 3 mm to 8 mm. In another embodiment, the first layer 528 and the second layer 529 include a total thickness T of 3 mm to 7 mm. In another embodiment, the first layer 528 and the second layer 529 include a total thickness T of 3 mm to 6 mm. In another embodiment, the first layer 528 and the second layer 529 include a total thickness T of 3 mm to 5 mm. In another embodiment, the first layer 528 and the second layer 529 include a total thickness T of 3 mm to 4 mm.

In some embodiments, the first layer 528 and the second layer 529 include a total thickness T of 4 mm to 10 mm. In another embodiment, the first layer 528 and the second layer 529 include a total thickness T of 4 mm to 9 mm. In another embodiment, the first layer 528 and the second layer 529 include a total thickness T of 4 mm to 8 mm. In another embodiment, the first layer 528 and the second layer 529 include a total thickness T of 4 mm to 7 mm. In another embodiment, the first layer 528 and the second layer 529 include a total thickness T of 4 mm to 6 mm. In another embodiment, the first layer 528 and the second layer 529 include a total thickness T of 4 mm to 5 mm.

In some embodiments, the first layer 528 and the second layer 529 include a total thickness T of 5 mm to 10 mm. In another embodiment, the first layer 528 and the second layer 529 include a total thickness T of 5 mm to 9 mm. In another embodiment, the first layer 528 and the second layer 529 include a total thickness T of 5 mm to 8 mm. In another embodiment, the first layer 528 and the second layer 529 include a total thickness T of 5 mm to 7 mm. In another embodiment, the first layer 528 and the second layer 529 include a total thickness T of 5 mm to 6 mm. In some embodiments, the first layer 528 and the second layer 529 include a total thickness T of 6 mm to 10 mm. In another embodiment, the first layer 528 and the second layer 529 include a total thickness T of 6 mm to 9 mm. In another embodiment, the first layer 528 and the second layer 529 include a total thickness T of 6 mm to 8 mm. In another embodiment, the first layer 528 and the second layer 529 include a total thickness T of 6 mm to 7 mm.

In some embodiments, the first layer 528 and the second layer 529 include a total thickness T of 7 mm to 10 mm. In another embodiment, the first layer 528 and the second layer 529 include a total thickness T of 7 mm to 9 mm. In another embodiment, the first layer 528 and the second layer 529 include a total thickness T of 7 mm to 8 mm. In some embodiments, the first layer 528 and the second layer 529 include a total thickness T of 8 mm to 10 mm. In another embodiment, the first layer 528 and the second layer 529 include a total thickness T of 8 mm to 9 mm. In some embodiments, the first layer 528 and the second layer 529 include a total thickness T of 9 mm to 10 mm.

In some embodiments, the first layer 528 and the second layer 529 include a total thickness T of 1 mm. In some embodiments, the first layer 528 and the second layer 529 include a total thickness T of 2 mm. In some embodiments, the first layer 528 and the second layer 529 include a total thickness T of 3 mm. In some embodiments, the first layer 528 and the second layer 529 include a total thickness T of 4 mm. In some embodiments, the first layer 528 and the second layer 529 include a total thickness T of 5 mm. In some embodiments, the first layer 528 and the second layer 529 include a total thickness T of 6 mm. In some embodiments, the first layer 528 and the second layer 529 include a total thickness T of 7 mm. In some embodiments, the first layer 528 and the second layer 529 include a total thickness T of 8 mm. In some embodiments, the first layer 528 and the second layer 529 include a total thickness T of 9 mm. In some embodiments, the first layer 528 and the second layer 529 include a total thickness T of 10 mm.

In some embodiments, the third layer 512 is rigid. In some embodiments, the third layer 512 is made of metal. In some embodiments, the third layer 512 is made of aluminum. In some embodiments, the third layer 512 includes galvanized aluminum. In another embodiment, the third layer 512 is made from an FR-4 glass-reinforced epoxy laminate material. In some embodiments, the third layer 512 includes a scrim. In some embodiments, the scrim may be made from polyesters, polyethylene, carbon fiber, fiberglass, aramids, and combinations thereof. In some embodiments, the third layer 512 is a flame retardant layer. In some embodiments, the third layer 512 includes a flame retardant additive. In some embodiments, the flame retardant additive may be clays, nanoclays, silicas, carbon black, metal hydroxides such as aluminum hydroxide, metal foils, graphite, and combinations thereof.

In some embodiments, the roofing module 510 includes a frontsheet 516 juxtaposed with the first surface of the first layer 528. In some embodiments, the frontsheet 516 is a UV blocking frontsheet. In some embodiments, the frontsheet 516 is a non-UV blocking frontsheet. In some embodiments, the frontsheet 516 is a UV blocking coating. In some embodiments, the frontsheet 516 is a UV blocking film.

In some embodiments, the roofing module 510 is cuttable. In some embodiments, the roofing module 510 is cuttable to a desired size and shape.

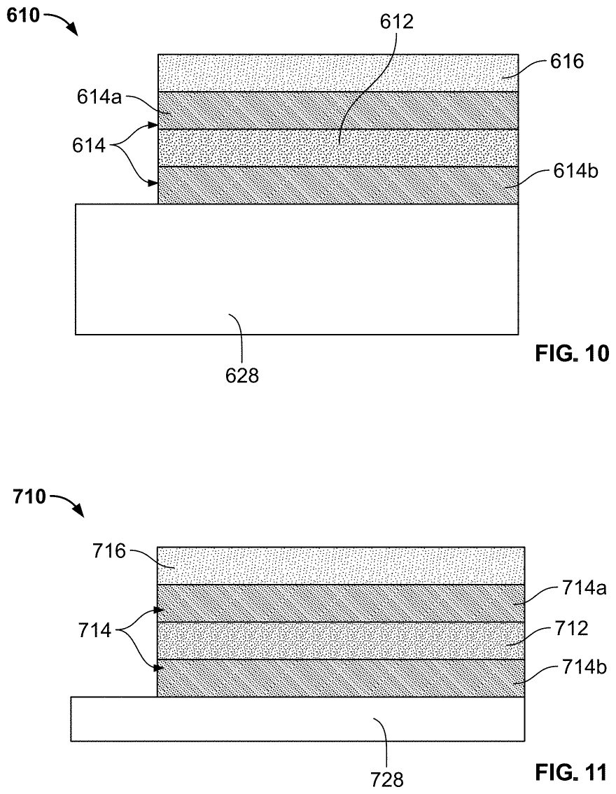

FIG. 10 shows another embodiment of a roofing module 610. In some embodiments, the roofing module 610 includes a layer 612 and an encapsulant 614 encapsulating the layer 612. In some embodiments, the encapsulant 614 includes a first layer 614a and a second layer 614b, In some embodiments, the first layer 614a is a UV blocking encapsulant. layer In some embodiments, the first layer 614a of the encapsulant 614 is a non-UV blocking encapsulant layer.

In some embodiments, the layer 612 includes a structure and/or is made from materials similar to those of the first layer 112. In some embodiments, the layer 612 includes polyethylene terephthalate (PET). In another embodiment, the layer 612 includes thermoplastic polyolefin (TPO). In some embodiments, a pattern is printed on a first surface of the layer 612. In some embodiments, a pattern or depiction of solar cells is printed on the first surface of the layer 612. In some embodiments, the pattern or depiction of solar cells includes a depiction of a plurality of cell fingers. In some embodiments, the depiction of the plurality of cell fingers is similar in size, shape and grain pattern of the cell fingers 1340 described below. In some embodiments, the layer 612 does not include any printing. In some embodiments, the roofing module 610 includes a frontsheet 616. In some embodiments, the frontsheet 616 is a non-UV blocking frontsheet. In some embodiments, the frontsheet 616 is a UV blocking coating. In some embodiments, the frontsheet 616 is a UV blocking film.

In some embodiments, the roofing module 610 includes a backsheet 628. In some embodiments, the backsheet 628 is made from materials similar to those of the backsheet 28. In some embodiments, the backsheet 628 is made from thermoplastic polyolefin (TPO). In some embodiments, the backsheet 628 includes a thickness T of 1 mm to 10 mm.

In some embodiments, the roofing module 610 is cuttable. In some embodiments, the roofing module 610 is cuttable to a desired size and shape.

FIG. 11 shows another embodiment of a roofing module 710. In some embodiments, the roofing module 710 includes a layer 712 and an encapsulant 714 encapsulating the layer 712. In some embodiments, the encapsulant 714 includes a first layer 714a and a second layer 714b, In some embodiments, the first layer 714a is a UV blocking encapsulant. layer In some embodiments, the first layer 714a of the encapsulant 714 is a non-UV blocking encapsulant layer.

In some embodiments, the layer 712 is rigid. In some embodiments, the layer 712 is made of metal. In some embodiments, the layer 712 is made of aluminum. In some embodiments, the layer 712 includes galvanized aluminum. In another embodiment, the layer 712 is made from an FR-4 glass-reinforced epoxy laminate material. In some embodiments, the roofing module 710 includes a frontsheet 716. In some embodiments, the frontsheet 716 is a non-UV blocking frontsheet. In some embodiments, the frontsheet 716 is a UV blocking coating. In some embodiments, the frontsheet 716 is a UV blocking film. In some embodiments, the roofing module 710 includes a backsheet 728. In some embodiments, the backsheet 728 is made from materials similar to those of the backsheet 28. In some embodiments, the backsheet 728 is made from thermoplastic polyolefin (TPO).

In some embodiments, the roofing module 710 is cuttable. In some embodiments, the roofing module 710 is cuttable to a desired size and shape.

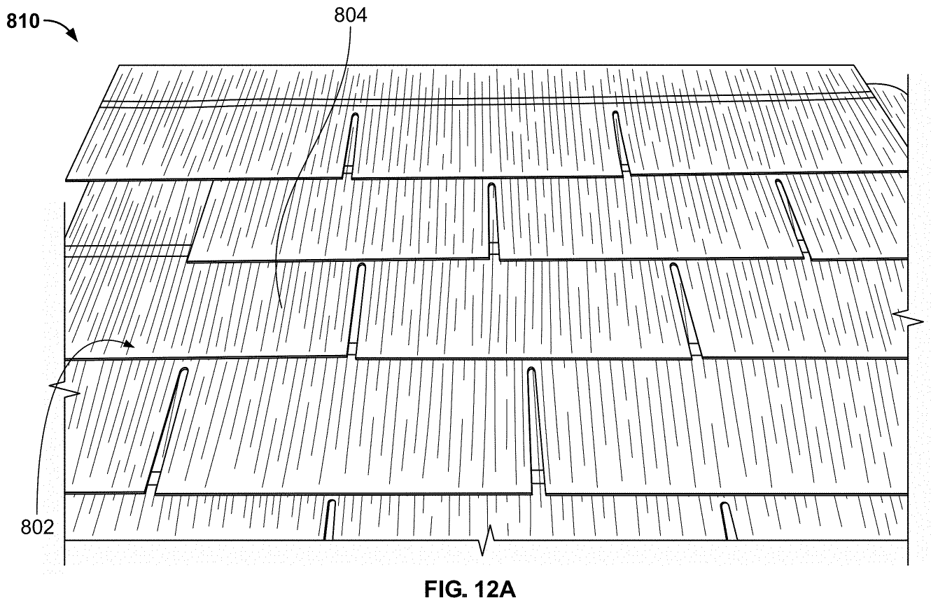

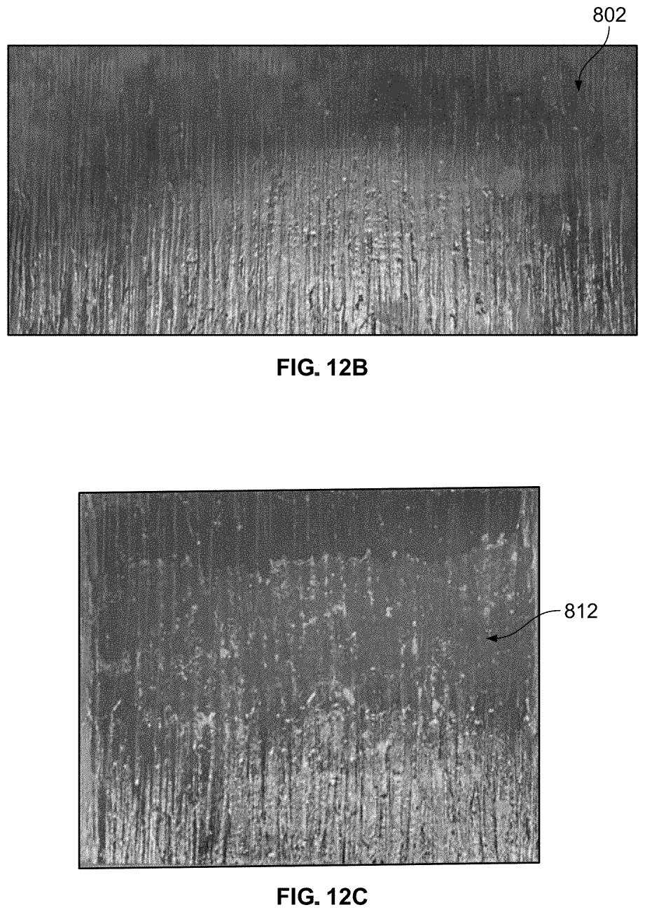

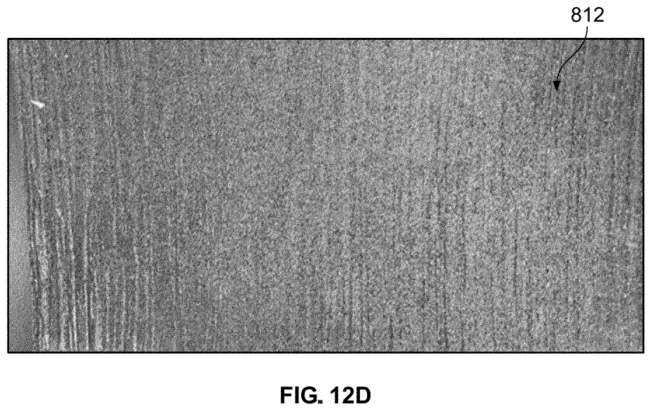

FIG. 12A shows an embodiment of a plurality of roofing modules 810. In some embodiments, each of the roofing modules 810 is textured to impart an appearance of a traditional asphalt roofing module. In some embodiments, each of the roofing modules 810 is textured to impart an appearance of a photovoltaic module. In some embodiments, the roofing module 810 includes a coated surface 802. In some embodiments, the roofing module 810 includes an embossed surface 802. In some embodiments, the embossed surface 802 is embossed in register. In some embodiments, the embossed surface 802 is a mechanical embossed surface, a laser embossed surface, a thermo-mechanical embossed surface, or any combination thereof. In some embodiments, the roofing module 810 includes an etched surface 802. In some embodiments, the surface 802 includes a plurality of indentations 804. In some embodiments, the indentations 804 includes a plurality of channels. In some embodiments, the plurality of channels is formed in a pattern. In some embodiments, each of the plurality of channels is random in size, shape and location. In some embodiments, the surface 802 includes a matte surface texture. In some embodiments, the surface 802 includes a glossy surface, such as a shiny film, gloss patterned glass, or a gloss non-patterned glass. In some embodiments, the surface 802 includes ink. In some embodiments, the ink is printed, on the surface 802, in a pattern. In some embodiments, the ink is printed in the pattern by an inkjet printer. In some embodiments, the ink is printed in the pattern by an offset printer. In some embodiments, the ink is printed in the pattern by a rotogravure printer. In some embodiments, the ink is printed in the pattern by a flexographic printer. In some embodiments, the ink is printed in the pattern by a screen printer.

In some embodiments, the surface 802 has a surface roughness, Ra. In some embodiments, the surface 802 has a surface roughness of 0.01 μm to 100 μm. In some embodiments, the surface 802 has a surface roughness of 0.01 μm to 90 μm. In some embodiments, the surface 802 has a surface roughness of 0.01 μm to 80 μm. In some embodiments, the surface 802 has a surface roughness of 0.01 μm to 70 μm. In some embodiments, the surface 802 has a surface roughness of 0.01 μm to 60 μm. In some embodiments, the surface 802 has a surface roughness of 0.01 m to 50 μm. In some embodiments, the surface 802 has a surface roughness of 0.01 μm to 40 μm. In some embodiments, the surface 802 has a surface roughness of 0.01 μm to 30 μm. In some embodiments, the surface 802 has a surface roughness of 0.01 μm to 20 μm. In some embodiments, the surface 802 has a surface roughness of 0.01 μm to 10 μm. In some embodiments, the surface 802 has a surface roughness of 0.01 μm to 5 μm. In some embodiments, the surface 802 has a surface roughness of 0.01 μm to 1 μm. In some embodiments, the surface 802 has a surface roughness of 0.01 μm to 0.1 μm.

In some embodiments, the surface 802 has a surface roughness of 0.1 μm to 100 μm. In some embodiments, the surface 802 has a surface roughness of 1 μm to 100 μm. In some embodiments, the surface 802 has a surface roughness of 5 μm to 100 μm. In some embodiments, the surface 802 has a surface roughness of 10 μm to 100 μm. In some embodiments, the surface 802 has a surface roughness of 20 μm to 100 μm. In some embodiments, the surface 802 has a surface roughness of 30 μm to 100 μm. In some embodiments, the surface 802 has a surface roughness of 40 μm to 100 μm. In some embodiments, the surface 802 has a surface roughness of 50 μm to 100 μm. In some embodiments, the surface 802 has a surface roughness of 60 μm to 100 μm. In some embodiments, the surface 802 has a surface roughness of 70 μm to 100 μm. In some embodiments, the surface 802 has a surface roughness of 80 μm to 100 μm. In some embodiments, the surface 802 has a surface roughness of 90 μm to 100 μm.

FIG. 12B shows an embodiment of a coated surface 802 which is textured to impart an appearance of a photovoltaic module. In some embodiments, the coated surface 802 includes a coating. In some embodiments, the coating is a heat-cured coating. In some embodiments, the coating is an ionizing radiation-cured coating. In some embodiments, the coating is an ultraviolet light (UV)-cured coating. In some embodiments, the coating is a photothermally-cured coating. In some embodiments, the coating is at least two of a heat-cured coating, an ionizing radiation-cured coating, a UV-cured coating, or a photothermally-cured coating. In some embodiments, the coating does not comprise asphalt.

In some embodiments, the coating includes at least one polymer. In some embodiments, the at least one polymer includes at least one of a thermoplastic polymer, a fluoropolymer, or any combination thereof. In some embodiments, the thermoplastic polymer comprises a thermoplastic polyolefin. In some embodiments, the thermoplastic polyolefin comprises at least one of polyethylene, polypropylene, any copolymer thereof, any homopolymer thereof, any polymer blend thereof, or any combination thereof. In some embodiments, the thermoplastic polyolefin comprises at least one of a copolymer of propylene and ethylene, a blend of propylene and ethylene, a copolymer of ethylene alpha-olefin, a propylene homopolymer, an ethylene homopolymer, a propylene block copolymer, an ethylene block copolymer, a propylene elastomer, an ethylene elastomer, or any combination thereof. In some embodiments, the thermoplastic polymer comprises at least one of a copolymer comprising ethylene and octene, a copolymer comprising ethylene and hexane, a copolymer comprising ethylene and butene, polyethylene (including raw and/or recycled low density polyethylene (LDPE)), linear low density polyethylene (LLDPE), high density polyethylene (HDPE)), polypropylenes (e.g., isotactic polypropylene (IPP) and/or atactic polypropylene (APP/IPP)), amorphous polyalpha olefins (APAO), amorphous polyolefins (APO), or any combination thereof. In some embodiments, the fluoropolymer includes at least one of ethylene tetrafluoroethylene (ETFE), polyvinylidene fluoride (PVDF), tetrafluoroethylene-hexafluoropropylene copolymers (FEP), tetrafluoroethylene-hexafluoropropylene-vinylidene fluoride copolymers (THV), polyvinyl fluoride (PVF), or any combination thereof.

In some embodiments, the coating includes at least one of a colorant, a pigment, a dye, a gloss control additive, or any combination thereof. In some embodiments, the pigment includes a reflective pigment. In some embodiments, the pigment includes an infrared reflective pigment, a near infrared reflective pigment, or any combination thereof. In some embodiments, the coating includes a metal oxide. In some embodiments, the metal oxide includes at least one of a transition metal oxide, an alkali metal oxide, an alkali metal silicate, or any combination thereof. In some embodiments, the coating includes at least one of titanium dioxide white, carbon black, lampblack, black iron oxide, red iron oxide, yellow iron oxide, brown iron oxide (a blend of red and yellow oxide with black), phthalocyanine green, Colonial red, phthalocyanine blue, naphthol red, quinacridone red, toulidine red, quinacridone magenta, quinacridone violet, DNA orange, Hansa yellow, and the like.

In some embodiments, the coating includes a surfacing media. In some embodiments, the surfacing media includes mineral particles. In some embodiments, the surfacing media includes a plurality of fines. In some embodiments, the surfacing media includes at least one of slag fines, granule fines, sands, limestone fines, calcium carbonate, slate fines, or any combination thereof. In some embodiments, the surfacing media includes at least one of granite, basalt, clay, coal, gypsum limestone, marble, quartz, rhyolite, sandstone, or any combination thereof.

FIG. 12C shows an embodiment of a PVDF coating 812 textured to impart an appearance of a photovoltaic module. FIG. 12D shows an embodiment of a surface media-containing coating 812 textured to impart an appearance of a photovoltaic module.

In some embodiments, the roofing module 810 is cuttable. In some embodiments, the roofing module 810 is cuttable to a desired size and shape.

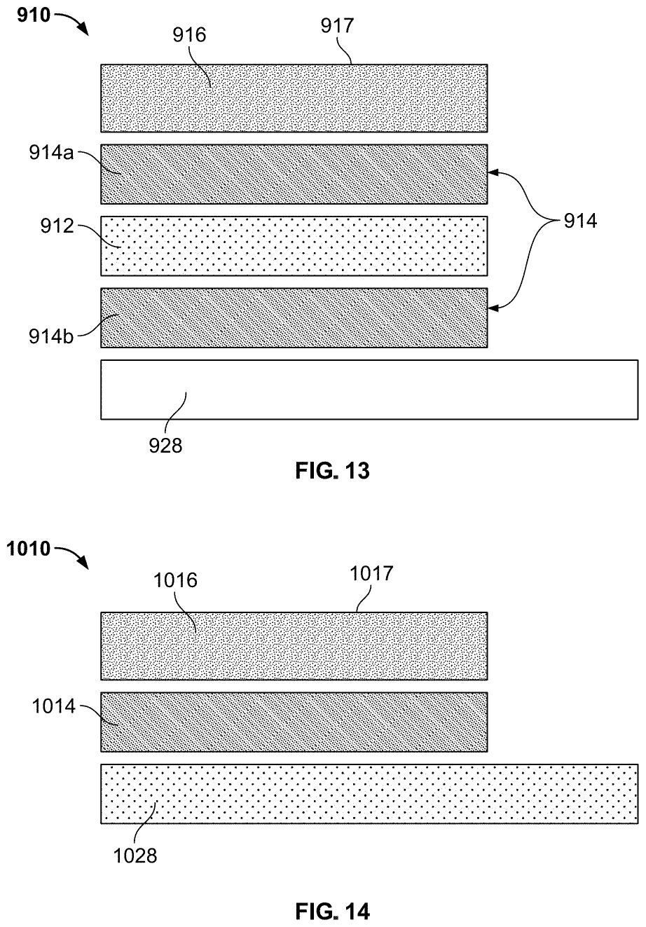

FIG. 13 shows an embodiment of a roofing module 910. In some embodiments, the roofing module 910 includes a layer 912 and an encapsulant 914 encapsulating the layer 912. In some embodiments, the encapsulant 914 includes a first layer 914a and a second layer 914b, In some embodiments, the first layer 914a is a UV blocking encapsulant. layer In some embodiments, the first layer 914a is a non-UV blocking encapsulant layer. In some embodiments, the layer 912 includes a structure and/or is made from materials similar to those of the first layer 112. In some embodiments, the layer 912 includes polyethylene terephthalate (PET). In another embodiment, the layer 912 includes thermoplastic polyolefin (TPO). In some embodiments, a pattern is printed on a first surface of the layer 912. In some embodiments, a pattern or depiction of solar cells is printed on the first surface of the layer 912. In some embodiments, the pattern or depiction of solar cells includes a depiction of a plurality of cell fingers. In some embodiments, the depiction of the plurality of cell fingers is similar in size, shape and grain pattern of the cell fingers 1340 described below.

In some embodiments, the roofing module 910 includes a frontsheet 916. In some embodiments, the frontsheet 916 includes glass. In some embodiments, the frontsheet 916 includes textured glass. In some embodiments, the frontsheet 916 is textured to impart an appearance of a traditional asphalt roofing module. In some embodiments, the frontsheet 916 includes a surface 917. In some embodiments, the surface 917 is an embossed surface. In some embodiments, the surface 917 includes a plurality of indentations. In some embodiments, the indentations includes a plurality of channels. In some embodiments, the plurality of channels is formed in a pattern. In some embodiments, each of the plurality of channels is random in size, shape and location. In some embodiments, the surface 917 includes a matte surface texture. In some embodiments, the surface 917 includes a glossy surface, such as a shiny film, gloss patterned glass, or a gloss non-patterned glass.

In some embodiments, the roofing module 910 includes a backsheet 928. In some embodiments, the backsheet 928 is made from materials similar to those of the backsheet 28. In some embodiments, the backsheet 928 is made from thermoplastic polyolefin (TPO).

In some embodiments, the roofing module 910 is cuttable. In some embodiments, the roofing module 910 is cuttable to a desired size and shape.

FIG. 14 shows an embodiment of a roofing module 1010. The roofing module 1010 includes a structure and function similar to the roofing module 210, except for certain differences described hereinafter. In some embodiments, the frontsheet 1016 includes glass. In some embodiments, the frontsheet 1016 includes textured glass. In some embodiments, the frontsheet 1016 is textured to impart an appearance of a traditional asphalt roofing module. In some embodiments, the frontsheet 1016 includes a surface 1017. In some embodiments, the surface 1017 is an embossed surface. In some embodiments, the surface 1017 includes a plurality of indentations. In some embodiments, the indentations includes a plurality of channels. In some embodiments, the plurality of channels is formed in a pattern. In some embodiments, each of the plurality of channels is random in size, shape and location. In some embodiments, the surface 1017 includes a matte surface texture. In some embodiments, the surface 1017 includes a glossy surface, such as a shiny film, gloss patterned glass, or a gloss non-patterned glass.

In some embodiments, the roofing module 1010 includes an encapsulant layer 1014 and a backsheet 1028. In some embodiments, the backsheet 1028 is made from materials similar to those of the backsheet 228. In some embodiments, the backsheet 1028 is made from thermoplastic polyolefin (TPO). In some embodiments, a pattern is printed on a first surface of the backsheet 1028. In some embodiments, a pattern or depiction of solar cells is printed on the first surface of the backsheet 1028. In some embodiments, the pattern or depiction of solar cells includes a depiction of a plurality of cell fingers. In some embodiments, the depiction of the plurality of cell fingers is similar in size, shape and grain pattern of the cell fingers 1340 described below. In another embodiment, the backsheet 1028 is painted. In another embodiment, the backsheet 1028 is black in color.

In some embodiments, the roofing module 1010 is cuttable. In some embodiments, the roofing module 1010 is cuttable to a desired size and shape.

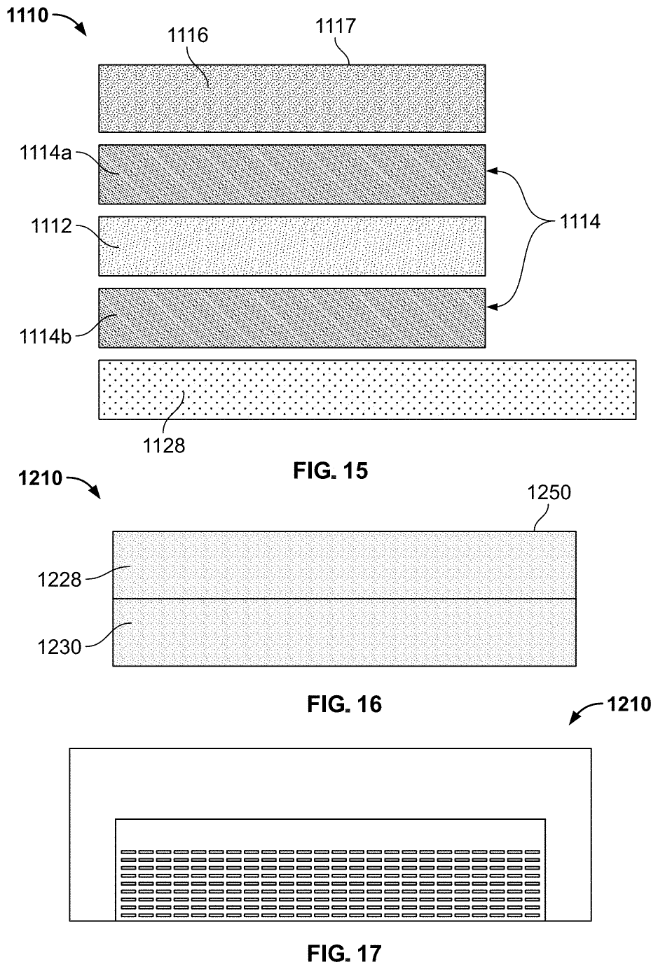

FIG. 15 shows an embodiment of a photovoltaic module 1110. In some embodiments, the photovoltaic module 1110 includes at least one solar cell 1112, an encapsulant 1114 encapsulating the at least one solar cell 1112, a frontsheet 1116 juxtaposed with a first layer 1114a of the encapsulant 1114, and a backsheet 1128 juxtaposed with a second layer 1114b of the encapsulant 1114. In some embodiments, the frontsheet 1116 includes glass. In some embodiments, the at least one solar cell 1112 includes a plurality of solar cells. In some embodiments, the frontsheet 1116 includes textured glass. In some embodiments, the frontsheet 1116 is textured to impart an appearance of a traditional asphalt roofing module. In some embodiments, the frontsheet 1116 includes a surface 1117. In some embodiments, the surface 1117 is an embossed surface. In some embodiments, the surface 1117 includes a plurality of indentations. In some embodiments, the indentations includes a plurality of channels. In some embodiments, the plurality of channels is formed in a pattern. In some embodiments, each of the plurality of channels is random in size, shape and location. In some embodiments, the surface 1117 includes a matte surface texture. In some embodiments, the surface 1117 includes a glossy surface, such as a shiny film, gloss patterned glass, or a gloss non-patterned glass.

In some embodiments, the backsheet 1128 is made from materials similar to those of the backsheet 228. In some embodiments, the backsheet 1128 is made from thermoplastic polyolefin (TPO). In another embodiment, the backsheet 1128 is painted. In another embodiment, the backsheet 1128 is black in color.

FIGS. 16 and 17 show an embodiment of a roofing module 1210. In some embodiments, the roofing module 1210 includes a first layer 1228 and a second layer 1230. In some embodiments, the first layer 1228 overlays the second layer 1230. In some embodiments, the first layer 1228 is juxtaposed with the second layer 1230. In some embodiments, the first layer 1228 and the second layer 1230 are thermally bonded to one another. In some embodiments, the first layer 1228 and the second layer 1230 are laminated. In some embodiments, the first layer 1228 is attached to the second layer 1230 by and adhesive. In some embodiments, the first layer 1228 and the second layer 1230 are mechanically attached to one another. In some embodiments, the roofing module 1210 does not include a solar cell, a photovoltaic cell, or any electrical device that converts the energy of light into electricity. In some embodiments, the roofing module 1210 does not include any electrically active components.

In some embodiments, the first layer 1228 is composed of a polymeric material. In some embodiments, the first layer 1228 is composed of polyethylene terephthalate (“PET”). In another embodiment, the first layer 1228 is composed of ethylene tetrafluoroethylene (“ETFE”). In some embodiments, the first layer 1228 is composed of an acrylic such as polymethyl methacrylate (“PMMA”). In some embodiments, the first layer 1228 is composed of thermoplastic polyolefin (TPO). In some embodiments, the first layer 1228 is composed of a single ply TPO roofing membrane. In other embodiments, non-limiting examples of TPO membranes are disclosed in U.S. Pat. No. 9,359,014 to Yang et al., which is incorporated by reference herein in its entirety. In another embodiment, the first layer 1228 is composed of includes polyvinyl chloride. In some embodiments, the first layer 1228 is composed of ethylene propylene diene monomer (EPDM) rubber. In some embodiments, the first layer 1228 is includes a flame retardant additive. In some embodiments, the flame retardant additive may be clays, nanoclays, silicas, carbon black, metal hydroxides such as aluminum hydroxide, metal foils, graphite, and combinations thereof. In some embodiments, the first layer 1228 is composed of a UV resistant material. In some embodiments, the first layer 1228 includes a UV resistant coating. In some embodiments, the first layer 1228 is composed of a water resistant material.

In some embodiments, the second layer 1230 is composed of a polymeric material. In some embodiments, the second layer 1230 is composed of polyethylene terephthalate (“PET”). In another embodiment, the second layer 1230 is composed of ethylene tetrafluoroethylene (“ETFE”). In some embodiments, the second layer 1230 is composed of an acrylic such as polymethyl methacrylate (“PMMA”). In some embodiments, the second layer 1230 is composed of thermoplastic polyolefin (TPO). In some embodiments, the second layer 1230 is composed of a single ply TPO roofing membrane. In other embodiments, non-limiting examples of TPO membranes are disclosed in U.S. Pat. No. 9,359,014 to Yang et al., which is incorporated by reference herein in its entirety. In another embodiment, the second layer 1230 is composed of includes polyvinyl chloride. In some embodiments, the second layer 1230 of ethylene propylene diene monomer (EPDM) rubber. In some embodiments, the second layer 1230 includes a flame retardant additive. In some embodiments, the flame retardant additive may be clays, nanoclays, silicas, carbon black, metal hydroxides such as aluminum hydroxide, metal foils, graphite, and combinations thereof. In some embodiments, the second layer 1230 is composed of a UV resistant material. In some embodiments, the second layer 1230 is composed of a water resistant material. In some embodiments, the second layer 1230 is composed of a polymer with fiberglass.

In some embodiments, the first layer 1228 has a thickness of 25 mils to 100 mils. In some embodiments, the first layer 1228 has a thickness of 25 mils to 90 mils. In some embodiments, the first layer 1228 has a thickness of 25 mils to 80 mils. In some embodiments, the first layer 1228 has a thickness of 25 mils to 70 mils. In some embodiments, the first layer 1228 has a thickness of 25 mils to 60 mils. In some embodiments, the first layer 1228 has a thickness of 25 mils to 50 mils. In some embodiments, the first layer 1228 has a thickness of 25 mils to 40 mils. In some embodiments, the first layer 1228 has a thickness of 25 mils to 30 mils. In some embodiments, the first layer 1228 has a thickness of 30 mils to 100 mils. In some embodiments, the first layer 1228 has a thickness of 30 mils to 90 mils. In some embodiments, the first layer 1228 has a thickness of 30 mils to 80 mils. In some embodiments, the first layer 1228 has a thickness of 30 mils to 70 mils. In some embodiments, the first layer 1228 has a thickness of 30 mils to 60 mils. In some embodiments, the first layer 1228 has a thickness of 30 mils to 50 mils. In some embodiments, the first layer 1228 has a thickness of 30 mils to 40 mils.

In some embodiments, the first layer 1228 has a thickness of 40 mils to 100 mils. In some embodiments, the first layer 1228 has a thickness of 40 mils to 90 mils. In some embodiments, the first layer 1228 has a thickness of 40 mils to 80 mils. In some embodiments, the first layer 1228 has a thickness of 40 mils to 70 mils. In some embodiments, the first layer 1228 has a thickness of 40 mils to 60 mils. In some embodiments, the first layer 1228 has a thickness of 40 mils to 50 mils. In some embodiments, the first layer 1228 has a thickness of 50 mils to 100 mils. In some embodiments, the first layer 1228 has a thickness of 50 mils to 90 mils. In some embodiments, the first layer 1228 has a thickness of 50 mils to 80 mils. In some embodiments, the first layer 1228 has a thickness of 50 mils to 70 mils. In some embodiments, the first layer 1228 has a thickness of 50 mils to 60 mils.

In some embodiments, the first layer 1228 has a thickness of 60 mils to 100 mils. In some embodiments, the first layer 1228 has a thickness of 60 mils to 90 mils. In some embodiments, the first layer 1228 has a thickness of 60 mils to 80 mils. In some embodiments, the first layer 1228 has a thickness of 60 mils to 70 mils. In some embodiments, the first layer 1228 has a thickness of 70 mils to 100 mils. In some embodiments, the first layer 1228 has a thickness of 70 mils to 90 mils. In some embodiments, the first layer 1228 has a thickness of 70 mils to 80 mils. In some embodiments, the first layer 1228 has a thickness of 80 mils to 100 mils. In some embodiments, the first layer 1228 has a thickness of 80 mils to 90 mils. In some embodiments, the first layer 1228 has a thickness of 90 mils to 100 mils.

In some embodiments, the first layer 1228 has a thickness of 25 mils. In some embodiments, the first layer 1228 has a thickness of 30 mils. In some embodiments, the first layer 1228 has a thickness of 40 mils. In some embodiments, the first layer 1228 has a thickness of 50 mils. In some embodiments, the first layer 1228 has a thickness of 60 mils. In some embodiments, the first layer 1228 has a thickness of 70 mils. In some embodiments, the first layer 1228 has a thickness of 80 mils. In some embodiments, the first layer 1228 has a thickness of 90 mils. In some embodiments, the first layer 1228 has a thickness of 100 mils.

In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 25 mils to 200 mils. In some embodiments, the second layer 1230 has a thickness of 40 mils to 200 mils. In some embodiments, the second layer 1230 has a thickness of 40 mils to 190 mils. In some embodiments, the second layer 1230 has a thickness of 40 mils to 180 mils. In some embodiments, the second layer 1230 has a thickness of 40 mils to 170 mils. In some embodiments, the second layer 1230 has a thickness of 40 mils to 160 mils. In some embodiments, the second layer 1230 has a thickness of 40 mils to 150 mils. In some embodiments, the second layer 1230 has a thickness of 40 mils to 140 mils. In some embodiments, the second layer 1230 has a thickness of 40 mils to 130 mils. In some embodiments, the second layer 1230 has a thickness of 40 mils to 120 mils. In some embodiments, the second layer 1230 has a thickness of 40 mils to 110 mils. In some embodiments, the second layer 1230 has a thickness of 40 mils to 100 mils. In some embodiments, the second layer 1230 has a thickness of 40 mils to 90 mils. In some embodiments, the second layer 1230 has a thickness of 40 mils to 80 mils. In some embodiments, the second layer 1230 has a thickness of 40 mils to 70 mils. In some embodiments, the second layer 1230 has a thickness of 40 mils to 60 mils.

In some embodiments, the second layer 1230 has a thickness of 60 mils to 200 mils. In some embodiments, the second layer 1230 has a thickness of 60 mils to 190 mils. In some embodiments, the second layer 1230 has a thickness of 60 mils to 180 mils. In some embodiments, the second layer 1230 has a thickness of 60 mils to 170 mils. In some embodiments, the second layer 1230 has a thickness of 60 mils to 160 mils. In some embodiments, the second layer 1230 has a thickness of 60 mils to 150 mils. In some embodiments, the second layer 1230 has a thickness of 60 mils to 140 mils. In some embodiments, the second layer 1230 has a thickness of 60 mils to 130 mils. In some embodiments, the second layer 1230 has a thickness of 60 mils to 120 mils. In some embodiments, the second layer 1230 has a thickness of 60 mils to 110 mils. In some embodiments, the second layer 1230 has a thickness of 60 mils to 100 mils. In some embodiments, the second layer 1230 has a thickness of 60 mils to 90 mils. In some embodiments, the second layer 1230 has a thickness of 60 mils to 80 mils. In some embodiments, the second layer 1230 has a thickness of 60 mils to 70 mils. In some embodiments, the second layer 1230 has a thickness of 80 mils to 200 mils. In some embodiments, the second layer 1230 has a thickness of 80 mils to 190 mils. In some embodiments, the second layer 1230 has a thickness of 80 mils to 180 mils. In some embodiments, the second layer 1230 has a thickness of 80 mils to 170 mils. In some embodiments, the second layer 1230 has a thickness of 80 mils to 160 mils. In some embodiments, the second layer 1230 has a thickness of 80 mils to 150 mils. In some embodiments, the second layer 1230 has a thickness of 80 mils to 140 mils. In some embodiments, the second layer 1230 has a thickness of 80 mils to 130 mils. In some embodiments, the second layer 1230 has a thickness of 80 mils to 120 mils. In some embodiments, the second layer 1230 has a thickness of 80 mils to 110 mils. In some embodiments, the second layer 1230 has a thickness of 80 mils to 100 mils. In some embodiments, the second layer 1230 has a thickness of 80 mils to 90 mils.

In some embodiments, the second layer 1230 has a thickness of 100 mils to 200 mils. In some embodiments, the second layer 1230 has a thickness of 100 mils to 190 mils. In some embodiments, the second layer 1230 has a thickness of 100 mils to 180 mils. In some embodiments, the second layer 1230 has a thickness of 100 mils to 170 mils. In some embodiments, the second layer 1230 has a thickness of 100 mils to 160 mils. In some embodiments, the second layer 1230 has a thickness of 100 mils to 150 mils. In some embodiments, the second layer 1230 has a thickness of 100 mils to 140 mils. In some embodiments, the second layer 1230 has a thickness of 100 mils to 130 mils. In some embodiments, the second layer 1230 has a thickness of 100 mils to 120 mils. In some embodiments, the second layer 1230 has a thickness of 100 mils to 110 mils. In some embodiments, the second layer 1230 has a thickness of 120 mils to 200 mils. In some embodiments, the second layer 1230 has a thickness of 120 mils to 190 mils. In some embodiments, the second layer 1230 has a thickness of 120 mils to 180 mils. In some embodiments, the second layer 1230 has a thickness of 120 mils to 170 mils. In some embodiments, the second layer 1230 has a thickness of 120 mils to 160 mils. In some embodiments, the second layer 1230 has a thickness of 120 mils to 150 mils. In some embodiments, the second layer 1230 has a thickness of 120 mils to 140 mils. In some embodiments, the second layer 1230 has a thickness of 120 mils to 130 mils.

In some embodiments, the second layer 1230 has a thickness of 140 mils to 200 mils. In some embodiments, the second layer 1230 has a thickness of 140 mils to 190 mils. In some embodiments, the second layer 1230 has a thickness of 140 mils to 180 mils. In some embodiments, the second layer 1230 has a thickness of 140 mils to 170 mils. In some embodiments, the second layer 1230 has a thickness of 140 mils to 160 mils. In some embodiments, the second layer 1230 has a thickness of 140 mils to 150 mils. In some embodiments, the second layer 1230 has a thickness of 160 mils to 200 mils. In some embodiments, the second layer 1230 has a thickness of 160 mils to 190 mils. In some embodiments, the second layer 1230 has a thickness of 160 mils to 180 mils. In some embodiments, the second layer 1230 has a thickness of 160 mils to 170 mils. In some embodiments, the second layer 1230 has a thickness of 180 mils to 200 mils. In some embodiments, the second layer 1230 has a thickness of 180 mils to 190 mils.

In some embodiments, the second layer 1230 has a thickness of 25 mils. In some embodiments, the second layer 1230 has a thickness of 30 mils. In some embodiments, the second layer 1230 has a thickness of 40 mils. In some embodiments, the second layer 1230 has a thickness of 50 mils. In some embodiments, the second layer 1230 has a thickness of 60 mils. In some embodiments, the second layer 1230 has a thickness of 70 mils. In some embodiments, the second layer 1230 has a thickness of 80 mils. In some embodiments, the second layer 1230 has a thickness of 90 mils. In some embodiments, the second layer 1230 has a thickness of 100 mils. In some embodiments, the second layer 1230 has a thickness of 110 mils. In some embodiments, the second layer 1230 has a thickness of 120 mils. In some embodiments, the second layer 1230 has a thickness of 130 mils. In some embodiments, the second layer 1230 has a thickness of 140 mils. In some embodiments, the second layer 1230 has a thickness of 150 mils. In some embodiments, the second layer 1230 has a thickness of 160 mils. In some embodiments, the second layer 1230 has a thickness of 170 mils. In some embodiments, the second layer 1230 has a thickness of 180 mils. In some embodiments, the second layer 1230 has a thickness of 190 mils. In some embodiments, the second layer 1230 has a thickness of 200 mils.

In some embodiments, the roofing module 1210 is textured. In some embodiments, the roofing module 1210 is textured to impart an appearance of a traditional asphalt roofing shingle. In some embodiments, the first layer 1228 includes a first surface 1250. In some embodiments, first surface 1250 is embossed. In some embodiments, the first surface 1250 includes a plurality of indentations. In some embodiments, the plurality of indentations includes a plurality of channels. In some embodiments, the plurality of channels is formed in a pattern. In some embodiments, each of the plurality of channels is random in size, shape and location. In some embodiments, the first surface 1250 includes a matte surface texture. In some embodiments, the first surface 1250 includes a glossy surface.

In some embodiments, the first surface 1250 of the first layer 1228 is textured. In some embodiments, the first surface 1250 of the first layer 1228 is textured by embossing. In some embodiments, the first surface 1250 of the first layer 1228 is textured. In some embodiments, the first surface 1250 of the first layer 1228 is textured by molding. In some embodiments, the first surface 1250 of the first layer 1228 is textured. In some embodiments, the first surface 1250 of the first layer 1228 is textured by etching. In some embodiments, the first surface 1250 of the first layer 1228 is textured. In some embodiments, the first surface 1250 of the first layer 1228 is textured by laser surface texturing.

In some embodiments, a pattern is printed on a first surface 1250 of the first layer 1228. In some embodiments, a pattern or depiction of solar cells is printed on the first surface 1250 of the first layer 1228. In some embodiments, the pattern or depiction of solar cells includes a depiction of a plurality of cell fingers. In some embodiments, the depiction of the plurality of cell fingers is similar in size, shape and grain pattern of the cell fingers 1340 described below. In some embodiments, the pattern is printed on the first surface 1250 of the first layer 1228 by ink jet printing. In some embodiments, the pattern is printed on the first surface 1250 of the first layer 1228 by laser printing. In some embodiments, the pattern is printed on the first surface 1250 of the first layer 1228 by lithography. In some embodiments, the pattern is printed on the first surface 1250 of the first layer 1228 by lithography. In some embodiments, the pattern is printed on the first surface 1250 of the first layer 1228 by offset printing. In some embodiments, the pattern is printed on the first surface 1250 of the first layer 1228 by screen printing. In some embodiments, the pattern is printed on the first surface 1250 of the first layer 1228 by digital printing. In another embodiment, the first layer 1228 is painted. In another embodiment, the first layer 1228 is a colored layer. In another embodiment, the first layer 1228 includes a black color. In some embodiments, the color of the first layer 1228 includes a mixture of colors. In some embodiments, the first layer 1228 includes an infrared reflective pigment. In some embodiments, the infrared reflective pigment includes graphene. In some embodiments, the roofing module 1210 meets standards of California Building Energy Efficiency Standards of Residential and Nonresidential Buildings, Title 24, Part 6. In some embodiments, the first surface 1250 of the first layer 1228 is textured and includes a pattern printed thereon.

In some embodiments, the roofing module 1210 is configured to be a component of a photovoltaic system that includes a fire resistance that conforms to standards under UL 790/ASTM E 108 test standards. In some embodiments, the roofing module 1210 includes a Class A rating when tested in accordance with UL 790/ASTM E 108.

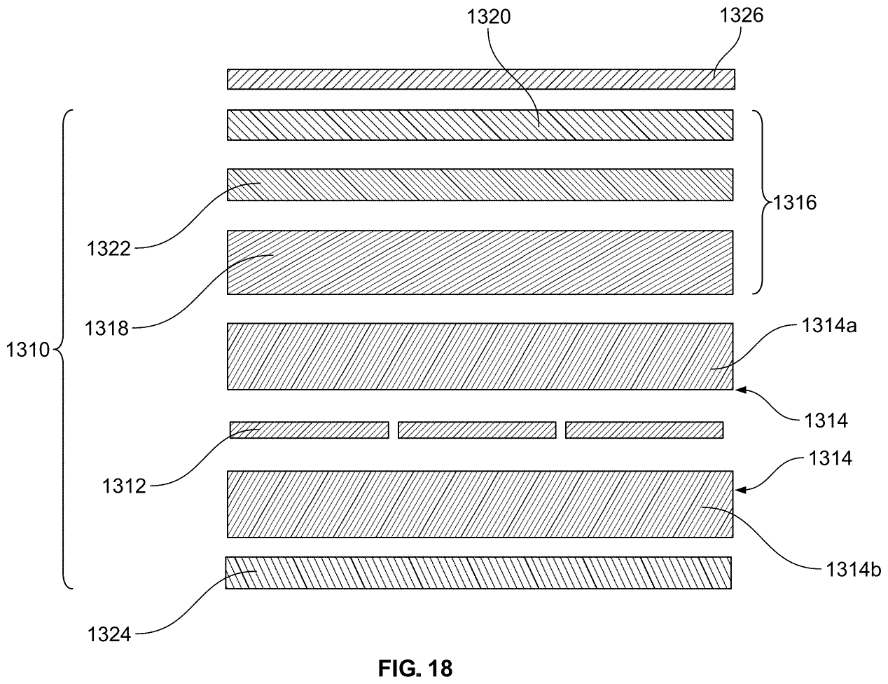

Referring to FIG. 18, in some embodiments, a photovoltaic module 1310 includes at least one solar cell 1312, an encapsulant 1314 encapsulating the at least one solar cell 1312, and a frontsheet 1316 juxtaposed with the encapsulant 1314. As used herein, the terms “encapsulating” and “encapsulates” mean to partially or fully envelope or enclose, and with respect to certain embodiments of the photovoltaic module 1310, the at least one solar cell 1312 is fully enveloped by or enclosed within the encapsulant 1314, or partially enveloped by or enclosed within the encapsulant 1314. In some embodiments, the encapsulant 1314 includes a first layer 1314a and a second layer 1314b.

In some embodiments, the at least one solar cell 1312 includes a plurality of the solar cells 1312. In some embodiments, the encapsulant 1314 encapsulates the plurality of solar cells 1312. In some embodiments, the at least one solar cell 1312 is electrically inactive (i.e., a “dummy” solar cell). In some embodiments, the plurality of solar cells 1312 is arranged in one row (i.e., one reveal). In another embodiment, the plurality of solar cells 1312 is arranged in two rows (i.e., two reveals). In another embodiment, the plurality of solar cells 1312 is arranged in three rows (i.e., three reveals). In other embodiments, the plurality of solar cells 1312 is arranged in more than three rows.

In some embodiments, the encapsulant 1314 may be made from polyolefins, ethyl vinyl acetates, ionomers, silicones, poly vinyl butyral, epoxies, polyurethanes, or combinations/hybrids thereof. In some embodiments, the encapsulant 1314 is made from thermosetting polyolefin. In some embodiments, the encapsulant 1314 includes a thickness of 0.4 mm to 1.8 mm. In some embodiments, the first layer 1314a of the encapsulant 1314 includes a thickness of 0.2 mm to 0.9 mm. In some embodiments, the second layer 1314b of the encapsulant 1314 includes a thickness of 0.2 mm to 0.9 mm.

In some embodiments, the thickness of the first layer 1314a is equal to the thickness of the second layer 1314b. In another embodiment, the thickness of the first layer 1314a is different from the thickness of the second layer 1314b. In some embodiments, the frontsheet 1316 includes a glass layer 1318 and a polymer layer 1320 attached to the glass layer 1318. In some embodiments, the frontsheet 1316 is juxtaposed with the first layer 1314a of the encapsulant 1314. In some embodiments, each of the glass layer 1318 and the polymer layer 1320 is transparent. In some embodiments, the glass layer 1318 includes a thickness of 2.5 mm to 4 mm.

In some embodiments, the polymer layer 1320 is attached to the glass layer 1318 by an adhesive layer 1322. In some embodiments, the adhesive layer 1322 may include polyvinyl butyrate, acrylic, silicone, or polycarbonate. In another embodiment, the adhesive layer 1322 may include pressure sensitive adhesives. In another embodiment, the polymer layer 1320 is attached to the glass layer 1318 by thermal bonding. In another embodiment, the frontsheet 1316 includes at least one of the glass layer 1318 or the polymer layer 1320.

In some embodiments, the adhesive layer 1322 includes thermosetting polyolefin, thermosetting polyolefin encapsulant material, thermosetting ethylene-vinyl acetate (EVA), EVA encapsulants, thermoplastic olefin, thermoplastic polyolefin (TPO) or hybrids/combinations thereof. In some embodiments, the adhesive layer 1322 includes a thickness of 1 μm to 900 μm.

In some embodiments, the polymer layer 1320 includes a fluoropolymer. In certain embodiments, the fluoropolymer may be ethylene tetrafluoroethylene (ETFE), fluoropolymer is polyvinylidene fluoride (PVDF), tetrafluoroethylene-hexafluoropropylene copolymers (FEP), and tetrafluoroethylene-hexafluoropropylene-vinylidene fluoride copolymers (THV), polyvinyl fluoride (PVF), or blends thereof. In some embodiments, the frontsheet includes fluoropolymers, acrylics, polyesters, silicones, polycarbonates, or combinations thereof. In other embodiments, the polymer layer 1320 includes polyethylene terephthalate (PET), polyethylene naphthalate (PEN), polyetheretherketone (PEEK), polyaryletherketone (PAEK), polyarylate (PAR), polyetherimide (PEI), polyarylsulfone (PAS), polyethersulfone (PES), polyamideimide (PAI), polyphenylsulfone (PPSU), polyolefin, cyclic olefin copolymers (CPCs), or polyimide. In some embodiments, the polymer layer 1320 includes a crosslinked polymeric material. In some embodiments, 50% to 99% of the polymer chains of the polymeric material are crosslinked. In some embodiments, the polymer layer 1320 includes a thickness of 0.01 mm to 0.5 mm.

In some embodiments, a backsheet 1324 is juxtaposed with the second layer 1314b of the encapsulant 1314. In some embodiments, the backsheet 1324 includes thermoplastic polyolefin (TPO). In some embodiments, the backsheet 1324 includes a single ply TPO roofing membrane. In other embodiments, non-limiting examples of TPO membranes are disclosed in U.S. Pat. No. 9,359,014 to Yang et al., which is incorporated by reference herein in its entirety. In another embodiment, the backsheet 1324 includes polyvinyl chloride. In some embodiments, the backsheet 1324 includes ethylene propylene diene monomer (EPDM) rubber. In some embodiments, the backsheet 1324 includes a flame retardant additive. In some embodiments, the flame retardant additive may be clays, nanoclays, silicas, carbon black, metal hydroxides such as aluminum hydroxide, metal foils, graphite, and combinations thereof.

In some embodiments, the photovoltaic module 1310 is flexible. As used herein, the term “flexible” means capable of bending without breaking or elastic deformation, and with respect to certain embodiments of the photovoltaic module 1310, the photovoltaic module 1310 is capable of being bent without breakage or elastic deformation of any of the layers thereof, i.e., any of the layers of the frontsheet 1316, the backsheet 1324, and the encapsulant 1314.

In some embodiments, the frontsheet 1316 is unpainted. In some embodiments, the backsheet 1324 is unpainted. In some embodiments, none of the layers of the photovoltaic module 1310 is painted. In some embodiments, the frontsheet 1316 and the backsheet 1324 are unpainted.

In some embodiments, a liner 1326 is configured to form a plurality of indentations within the frontsheet 1316. In some embodiments, the plurality of indentations is formed within the polymer layer 1320 and the adhesive layer 1322. In some embodiments, the liner 1326 is a textured release liner including a plurality of dimples configured to form the plurality of indentations in the frontsheet 1316. In some embodiments, the photovoltaic module 1310 is laminated. In some embodiments, the liner 1326 is configured to form the plurality of indentations within the frontsheet 1316 during lamination of the photovoltaic module 1310. In some embodiments, the liner 1326 is removed after formation of the plurality of indentations.

In some embodiments, the liner 1326 includes a thickness of 0.025 mm to 5 mm. In another embodiment, the liner 1326 includes a thickness of 0.025 mm to 4 mm. In another embodiment, the liner 1326 includes a thickness of 0.025 mm to 3 mm. In another embodiment, the liner 1326 includes a thickness of 0.025 mm to 2 mm. In another embodiment, the liner 1326 includes a thickness of 0.025 mm to 1 mm. In another embodiment, the liner 1326 includes a thickness of 0.025 mm to 0.5 mm. In some embodiments, the liner 1326 includes a thickness of 0.5 mm to 5 mm. In another embodiment, the liner 1326 includes a thickness of 0.5 mm to 4 mm. In another embodiment, the liner 1326 includes a thickness of 0.5 mm to 3 mm. In another embodiment, the liner 1326 includes a thickness of 0.5 mm to 2 mm. In another embodiment, the liner 1326 includes a thickness of 0.5 mm to 1 mm.

In some embodiments, the liner 1326 includes a thickness of 1 mm to 5 mm. In another embodiment, the liner 1326 includes a thickness of 1 mm to 5 mm. In another embodiment, the liner 1326 includes a thickness of 1 mm to 4 mm. In another embodiment, the liner 1326 includes a thickness of 1 mm to 3 mm. In another embodiment, the liner 1326 includes a thickness of 1 mm to 2 mm. In some embodiments, the liner 1326 includes a thickness of 2 mm to 5 mm. In another embodiment, the liner 1326 includes a thickness of 2 mm to 4 mm. In another embodiment, the liner 1326 includes a thickness of 2 mm to 3 mm. In some embodiments, the liner 1326 includes a thickness of 3 mm to 5 mm. In another embodiment, the liner 1326 includes a thickness of 3 mm to 4 mm. In another embodiment, the liner 1326 includes a thickness of 4 mm to 5 mm.

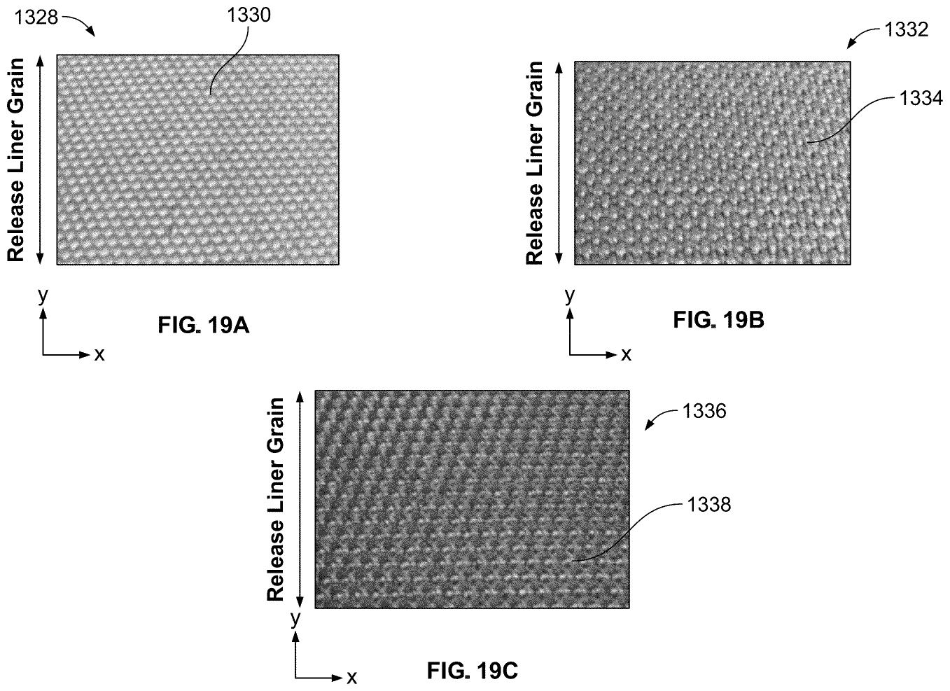

FIGS. 19A through 19C show embodiments of the liner 1326. In some embodiments, FIG. 19A shows a liner 1328 including a plurality of dimples (i.e., indentations) 1330 formed within a surface thereof. In some embodiments, each of the dimples 1330 includes a length of 0.95 mm to 1.1 mm. In some embodiments, a majority of the dimples 1330 have a length of 0.95 mm to 1.1 mm. In some embodiments, each of the dimples 1330 includes a length of 0.95 mm to 1.05 mm. In some embodiments, each of the dimples 1330 includes a length of 0.95 mm to 1 mm. In some embodiments, each of the dimples 1330 includes a length of 1 mm to 1.1 mm. In some embodiments, each of the dimples 1330 includes a length of 1 mm to 1.05 mm. In some embodiments, each of the dimples 1330 includes a length of 1.05 mm to 1.1 mm.

In some embodiments, each of the dimples 1330 includes a length of 0.95 mm. In some embodiments, each of the dimples 1330 includes a length of 0.96 mm. In some embodiments, each of the dimples 1330 includes a length of 0.97 mm. In some embodiments, each of the dimples 1330 includes a length of 0.98 mm. In some embodiments, each of the dimples 1330 includes a length of 0.99 mm. In some embodiments, each of the dimples 1330 includes a length of 1 mm. In some embodiments, each of the dimples 1330 includes a length of 1.01 mm. In some embodiments, each of the dimples 1330 includes a length of 1.02 mm. In some embodiments, each of the dimples 1330 includes a length of 1.03 mm. In some embodiments, each of the dimples 1330 includes a length of 1.04 mm. In some embodiments, each of the dimples 1330 includes a length of 1.05 mm. In some embodiments, each of the dimples 1330 includes a length of 1.06 mm. In some embodiments, each of the dimples 1330 includes a length of 1.07 mm. In some embodiments, each of the dimples 1330 includes a length of 1.08 mm. In some embodiments, each of the dimples 1330 includes a length of 1.09 mm. In some embodiments, each of the dimples 1330 includes a length of 1.1 mm.

In some embodiments, each of the dimples 1330 includes a width of 1.95 mm to 2.1 mm. In some embodiments, a majority of the dimples 1330 have a width of 1.95 mm to 2.1 mm. In some embodiments, each of the dimples 1330 includes a width of 1.95 mm to 2 mm. In some embodiments, each of the dimples 1330 includes a width of 2 mm to 2.1 mm. In some embodiments, each of the dimples 1330 includes a width of 1.95 mm. In some embodiments, each of the dimples 1330 includes a width of 1.96 mm. In some embodiments, each of the dimples 1330 includes a width of 1.97 mm. In some embodiments, each of the dimples 1330 includes a width of 1.98 mm. In some embodiments, each of the dimples 1330 includes a width of 1.99 mm. In some embodiments, each of the dimples 1330 includes a width of 2 mm. In some embodiments, each of the dimples 1330 includes a width of 2.01 mm. In some embodiments, each of the dimples 1330 includes a width of 2.02 mm. In some embodiments, each of the dimples 1330 includes a width of 2.03 mm. In some embodiments, each of the dimples 1330 includes a width of 2.04 mm. In some embodiments, each of the dimples 1330 includes a width of 2.05 mm. In some embodiments, each of the dimples 1330 includes a width of 2.06 mm. In some embodiments, each of the dimples 1330 includes a width of 2.07 mm. In some embodiments, each of the dimples 1330 includes a width of 2.08 mm. In some embodiments, each of the dimples 1330 includes a width of 2.09 mm. In some embodiments, each of the dimples 1330 includes a width of 2.1 mm.

In some embodiments, each of the dimples 1330 includes a depth of 0.12 mm to 0.2 mm. In some embodiments, a majority of the dimples 1330 have a depth of 0.12 mm to 0.2 mm. In some embodiments, each of the dimples 1330 includes a depth of 0.12 mm to 0.19 mm. In some embodiments, each of the dimples 1330 includes a depth of 0.12 mm to 0.18 mm. In some embodiments, each of the dimples 1330 includes a depth of 0.12 mm to 0.17 mm. In some embodiments, each of the dimples 1330 includes a depth of 0.12 mm to 0.16 mm. In some embodiments, each of the dimples 1330 includes a depth of 0.12 mm to 0.15 mm. In some embodiments, each of the dimples 1330 includes a depth of 0.12 mm to 0.14 mm. In some embodiments, each of the dimples 1330 includes a depth of 0.12 mm to 0.13 mm.

In some embodiments, each of the dimples 1330 includes a depth of 0.13 mm to 0.2 mm. In some embodiments, each of the dimples 1330 includes a depth of 0.13 mm to 0.19 mm. In some embodiments, each of the dimples 1330 includes a depth of 0.13 mm to 0.18 mm. In some embodiments, each of the dimples 1330 includes a depth of 0.13 mm to 0.17 mm. In some embodiments, each of the dimples 1330 includes a depth of 0.13 mm to 0.16 mm. In some embodiments, each of the dimples 1330 includes a depth of 0.13 mm to 0.15 mm. In some embodiments, each of the dimples 1330 includes a depth of 0.13 mm to 0.14 mm.

In some embodiments, each of the dimples 1330 includes a depth of 0.14 mm to 0.2 mm. In some embodiments, each of the dimples 1330 includes a depth of 0.14 mm to 0.19 mm. In some embodiments, each of the dimples 1330 includes a depth of 0.14 mm to 0.18 mm. In some embodiments, each of the dimples 1330 includes a depth of 0.14 mm to 0.17 mm. In some embodiments, each of the dimples 1330 includes a depth of 0.14 mm to 0.16 mm. In some embodiments, each of the dimples 1330 includes a depth of 0.14 mm to 0.15 mm. In some embodiments, each of the dimples 1330 includes a depth of 0.15 mm to 0.2 mm. In some embodiments, each of the dimples 1330 includes a depth of 0.15 mm to 0.19 mm. In some embodiments, each of the dimples 1330 includes a depth of 0.15 mm to 0.18 mm. In some embodiments, each of the dimples 1330 includes a depth of 0.15 mm to 0.17 mm. In some embodiments, each of the dimples 1330 includes a depth of 0.15 mm to 0.16 mm.

In some embodiments, each of the dimples 1330 includes a depth of 0.16 mm to 0.2 mm. In some embodiments, each of the dimples 1330 includes a depth of 0.16 mm to 0.19 mm. In some embodiments, each of the dimples 1330 includes a depth of 0.16 mm to 0.18 mm. In some embodiments, each of the dimples 1330 includes a depth of 0.16 mm to 0.17 mm. In some embodiments, each of the dimples 1330 includes a depth of 0.17 mm to 0.2 mm. In some embodiments, each of the dimples 1330 includes a depth of 0.17 mm to 0.19 mm. In some embodiments, each of the dimples 1330 includes a depth of 0.17 mm to 0.18 mm. In some embodiments, each of the dimples 1330 includes a depth of 0.18 mm to 0.2 mm. In some embodiments, each of the dimples 1330 includes a depth of 0.18 mm to 0.19 mm. In some embodiments, each of the dimples 1330 includes a depth of 0.19 mm to 0.2 mm.

In some embodiments, each of the dimples 1330 includes a depth of 0.12 mm. In some embodiments, each of the dimples 1330 includes a depth of 0.13 mm. In some embodiments, each of the dimples 1330 includes a depth of 0.14 mm. In some embodiments, each of the dimples 1330 includes a depth of 0.15 mm. In some embodiments, each of the dimples 1330 includes a depth of 0.155 mm. In some embodiments, each of the dimples 1330 includes a depth of 0.16 mm. In some embodiments, each of the dimples 1330 includes a depth of 0.17 mm. In some embodiments, each of the dimples 1330 includes a depth of 0.18 mm. In some embodiments, each of the dimples 1330 includes a depth of 0.19 mm.

In some embodiments, the liner 1328 includes polytetrafluoroethylene (PTFE). In some embodiments, the liner 1328 includes PTFE coated glass fabric. In some embodiments, the PTFE coated glass fabric is Steinbach AG PTFE fabric 345. In some embodiments, the liner 1328 is configured to form within the frontsheet 1316 a plurality of indentations having a size and shape corresponding to those of the plurality of dimples 1330.

In some embodiments, FIG. 19B shows a liner 1332 including a plurality of dimples 1334 formed within a surface thereof. In some embodiments, each of the dimples 1334 includes a length of 1.2 mm to 1.4 mm. In some embodiments, a majority of the dimples 1334 have a length of 1.2 mm to 1.4 mm. In some embodiments, each of the dimples 1334 includes a length of 1.2 mm to 1.3 mm. In some embodiments, each of the dimples 1334 includes a length of 1.3 mm to 1.4 mm. In some embodiments, each of the dimples 1334 includes a length of 1.2 mm. In some embodiments, each of the dimples 1334 includes a length of 1.3 mm. In some embodiments, each of the dimples 1334 includes a length of 1.31 mm. In some embodiments, each of the dimples 1334 includes a length of 1.4 mm.

In some embodiments, each of the dimples 1334 includes a width of 2.85 mm to 2.95 mm. In some embodiments, a majority of the dimples 1334 have a width of 2.85 mm to 2.95 mm. In some embodiments, each of the dimples 1334 includes a width of 2.85 mm to 2.9 mm. In some embodiments, each of the dimples 1334 includes a width of 2.9 mm to 2.95 mm. In some embodiments, each of the dimples 1334 includes a width of 2.85 mm. In some embodiments, each of the dimples 1334 includes a width of 2.9 mm. In some embodiments, each of the dimples 1334 includes a width of 2.95 mm.

In some embodiments, each of the dimples 1334 includes a depth of 0.17 mm to 0.28 mm. In some embodiments, a majority of the dimples 1334 have a depth of 0.17 mm to 0.28 mm. In some embodiments, each of the dimples 1334 includes a depth of 0.17 mm to 0.27 mm. In some embodiments, each of the dimples 1334 includes a depth of 0.17 mm to 0.26 mm. In some embodiments, each of the dimples 1334 includes a depth of 0.17 mm to 0.25 mm. In some embodiments, each of the dimples 1334 includes a depth of 0.17 mm to 0.24 mm. In some embodiments, each of the dimples 1334 includes a depth of 0.17 mm to 0.23 mm. In some embodiments, each of the dimples 1334 includes a depth of 0.17 mm to 0.22 mm. In some embodiments, each of the dimples 1334 includes a depth of 0.17 mm to 0.21 mm. In some embodiments, each of the dimples 1334 includes a depth of 0.17 mm to 0.2 mm. In some embodiments, each of the dimples 1334 includes a depth of 0.17 mm to 0.19 mm. In some embodiments, each of the dimples 1334 includes a depth of 0.17 mm to 0.18 mm.

In some embodiments, each of the dimples 1334 includes a depth of 0.18 mm to 0.28 mm. In some embodiments, each of the dimples 1334 includes a depth of 0.18 mm to 0.27 mm. In some embodiments, each of the dimples 1334 includes a depth of 0.18 mm to 0.26 mm. In some embodiments, each of the dimples 1334 includes a depth of 0.18 mm to 0.25 mm. In some embodiments, each of the dimples 1334 includes a depth of 0.18 mm to 0.24 mm. In some embodiments, each of the dimples 1334 includes a depth of 0.18 mm to 0.23 mm. In some embodiments, each of the dimples 1334 includes a depth of 0.18 mm to 0.22 mm. In some embodiments, each of the dimples 1334 includes a depth of 0.18 mm to 0.21 mm. In some embodiments, each of the dimples 1334 includes a depth of 0.18 mm to 0.2 mm. In some embodiments, each of the dimples 1334 includes a depth of 0.18 mm to 0.19 mm.

In some embodiments, each of the dimples 1334 includes a depth of 0.19 mm to 0.28 mm. In some embodiments, each of the dimples 1334 includes a depth of 0.19 mm to 0.27 mm. In some embodiments, each of the dimples 1334 includes a depth of 0.19 mm to 0.26 mm. In some embodiments, each of the dimples 1334 includes a depth of 0.19 mm to 0.25 mm. In some embodiments, each of the dimples 1334 includes a depth of 0.19 mm to 0.24 mm. In some embodiments, each of the dimples 1334 includes a depth of 0.19 mm to 0.23 mm. In some embodiments, each of the dimples 1334 includes a depth of 0.19 mm to 0.22 mm. In some embodiments, each of the dimples 1334 includes a depth of 0.19 mm to 0.21 mm. In some embodiments, each of the dimples 1334 includes a depth of 0.19 mm to 0.2 mm.

In some embodiments, each of the dimples 1334 includes a depth of 0.2 mm to 0.28 mm. In some embodiments, each of the dimples 1334 includes a depth of 0.2 mm to 0.27 mm. In some embodiments, each of the dimples 1334 includes a depth of 0.2 mm to 0.26 mm. In some embodiments, each of the dimples 1334 includes a depth of 0.2 mm to 0.25 mm. In some embodiments, each of the dimples 1334 includes a depth of 0.2 mm to 0.24 mm. In some embodiments, each of the dimples 1334 includes a depth of 0.2 mm to 0.23 mm. In some embodiments, each of the dimples 1334 includes a depth of 0.2 mm to 0.22 mm. In some embodiments, each of the dimples 1334 includes a depth of 0.2 mm to 0.21 mm.

In some embodiments, each of the dimples 1334 includes a depth of 0.21 mm to 0.28 mm. In some embodiments, each of the dimples 1334 includes a depth of 0.21 mm to 0.27 mm. In some embodiments, each of the dimples 1334 includes a depth of 0.21 mm to 0.26 mm. In some embodiments, each of the dimples 1334 includes a depth of 0.21 mm to 0.25 mm. In some embodiments, each of the dimples 1334 includes a depth of 0.21 mm to 0.24 mm. In some embodiments, each of the dimples 1334 includes a depth of 0.21 mm to 0.23 mm. In some embodiments, each of the dimples 1334 includes a depth of 0.21 mm to 0.22 mm.

In some embodiments, each of the dimples 1334 includes a depth of 0.22 mm to 0.28 mm. In some embodiments, each of the dimples 1334 includes a depth of 0.22 mm to 0.27 mm. In some embodiments, each of the dimples 1334 includes a depth of 0.22 mm to 0.26 mm. In some embodiments, each of the dimples 1334 includes a depth of 0.22 mm to 0.25 mm. In some embodiments, each of the dimples 1334 includes a depth of 0.22 mm to 0.24 mm. In some embodiments, each of the dimples 1334 includes a depth of 0.22 mm to 0.23 mm. In some embodiments, each of the dimples 1334 includes a depth of 0.23 mm to 0.28 mm. In some embodiments, each of the dimples 1334 includes a depth of 0.23 mm to 0.27 mm. In some embodiments, each of the dimples 1334 includes a depth of 0.23 mm to 0.26 mm. In some embodiments, each of the dimples 1334 includes a depth of 0.23 mm to 0.25 mm. In some embodiments, each of the dimples 1334 includes a depth of 0.23 mm to 0.24 mm.

In some embodiments, each of the dimples 1334 includes a depth of 0.24 mm to 0.28 mm. In some embodiments, each of the dimples 1334 includes a depth of 0.24 mm to 0.27 mm. In some embodiments, each of the dimples 1334 includes a depth of 0.24 mm to 0.26 mm. In some embodiments, each of the dimples 1334 includes a depth of 0.24 mm to 0.25 mm. In some embodiments, each of the dimples 1334 includes a depth of 0.25 mm to 0.28 mm. In some embodiments, each of the dimples 1334 includes a depth of 0.25 mm to 0.27 mm. In some embodiments, each of the dimples 1334 includes a depth of 0.25 mm to 0.26 mm. In some embodiments, each of the dimples 1334 includes a depth of 0.26 mm to 0.28 mm. In some embodiments, each of the dimples 1334 includes a depth of 0.26 mm to 0.27 mm. In some embodiments, each of the dimples 1334 includes a depth of 0.27 mm to 0.28 mm.

In some embodiments, each of the dimples 1334 includes a depth of 0.17 mm. In some embodiments, each of the dimples 1334 includes a depth of 0.18 mm. In some embodiments, each of the dimples 1334 includes a depth of 0.19 mm. In some embodiments, each of the dimples 1334 includes a depth of 0.2 mm. In some embodiments, each of the dimples 1334 includes a depth of 0.21 mm. In some embodiments, each of the dimples 1334 includes a depth of 0.22 mm. In some embodiments, each of the dimples 1334 includes a depth of 0.227 mm. In some embodiments, each of the dimples 1334 includes a depth of 0.23 mm. In some embodiments, each of the dimples 1334 includes a depth of 0.24 mm. In some embodiments, each of the dimples 1334 includes a depth of 0.25 mm. In some embodiments, each of the dimples 1334 includes a depth of 0.26 mm. In some embodiments, each of the dimples 1334 includes a depth of 0.27 mm. In some embodiments, each of the dimples 1334 includes a depth of 0.28 mm.

In some embodiments, the liner 1332 includes polytetrafluoroethylene (PTFE). In some embodiments, the liner 1332 includes PTFE transport and release sheet. In some embodiments, the PTFE transport and release sheet is Steinbach AG PTFE Type 5307. In some embodiments, the liner 1332 is configured to form within the frontsheet 1316 a plurality of indentations having a size and shape corresponding to those of the plurality of dimples 1334.

In some embodiments, FIG. 19C shows a liner 1336 including a plurality of dimples 1338 formed within a surface thereof. In some embodiments, each of the dimples 1338 includes a length of 1.44 mm to 1.52 mm. In some embodiments, a majority of the dimples 1338 have a length of 1.44 mm to 1.52 mm. In some embodiments, each of the dimples 1338 includes a length of 1.44 mm to 1.51 mm. In some embodiments, each of the dimples 1338 includes a length of 1.44 mm to 1.5 mm. In some embodiments, each of the dimples 1338 includes a length of 1.44 mm to 1.49 mm. In some embodiments, each of the dimples 1338 includes a length of 1.44 mm to 1.48 mm. In some embodiments, each of the dimples 1338 includes a length of 1.44 mm to 1.47 mm. In some embodiments, each of the dimples 1338 includes a length of 1.44 mm to 1.46 mm. In some embodiments, each of the dimples 1338 includes a length of 1.44 mm to 1.45 mm.

In some embodiments, each of the dimples 1338 includes a length of 1.45 mm to 1.52 mm. In some embodiments, each of the dimples 1338 includes a length of 1.45 mm to 1.51 mm. In some embodiments, each of the dimples 1338 includes a length of 1.45 mm to 1.5 mm. In some embodiments, each of the dimples 1338 includes a length of 1.45 mm to 1.49 mm. In some embodiments, each of the dimples 1338 includes a length of 1.45 mm to 1.48 mm. In some embodiments, each of the dimples 1338 includes a length of 1.45 mm to 1.47 mm. In some embodiments, each of the dimples 1338 includes a length of 1.45 mm to 1.46 mm.

In some embodiments, each of the dimples 1338 includes a length of 1.46 mm to 1.52 mm. In some embodiments, each of the dimples 1338 includes a length of 1.46 mm to 1.51 mm. In some embodiments, each of the dimples 1338 includes a length of 1.46 mm to 1.5 mm. In some embodiments, each of the dimples 1338 includes a length of 1.46 mm to 1.49 mm. In some embodiments, each of the dimples 1338 includes a length of 1.46 mm to 1.48 mm. In some embodiments, each of the dimples 1338 includes a length of 1.46 mm to 1.47 mm. In some embodiments, each of the dimples 1338 includes a length of 1.47 mm to 1.52 mm. In some embodiments, each of the dimples 1338 includes a length of 1.47 mm to 1.51 mm. In some embodiments, each of the dimples 1338 includes a length of 1.47 mm to 1.5 mm. In some embodiments, each of the dimples 1338 includes a length of 1.47 mm to 1.49 mm. In some embodiments, each of the dimples 1338 includes a length of 1.47 mm to 1.48 mm.

In some embodiments, each of the dimples 1338 includes a length of 1.48 mm to 1.52 mm. In some embodiments, each of the dimples 1338 includes a length of 1.48 mm to 1.51 mm. In some embodiments, each of the dimples 1338 includes a length of 1.48 mm to 1.5 mm. In some embodiments, each of the dimples 1338 includes a length of 1.48 mm to 1.49 mm. In some embodiments, each of the dimples 1338 includes a length of 1.49 mm to 1.52 mm. In some embodiments, each of the dimples 1338 includes a length of 1.49 mm to 1.51 mm. In some embodiments, each of the dimples 1338 includes a length of 1.49 mm to 1.5 mm. In some embodiments, each of the dimples 1338 includes a length of 1.5 mm to 1.52 mm. In some embodiments, each of the dimples 1338 includes a length of 1.5 mm to 1.51 mm. In some embodiments, each of the dimples 1338 includes a length of 1.51 mm to 1.52 mm.

In some embodiments, each of the dimples 1338 includes a length of 1.44 mm. In some embodiments, each of the dimples 1338 includes a length of 1.45 mm. In some embodiments, each of the dimples 1338 includes a length of 1.46 mm. In some embodiments, each of the dimples 1338 includes a length of 1.47 mm. In some embodiments, each of the dimples 1338 includes a length of 1.48 mm. In some embodiments, each of the dimples 1338 includes a length of 1.49 mm. In some embodiments, each of the dimples 1338 includes a length of 1.5 mm. In some embodiments, each of the dimples 1338 includes a length of 1.51 mm. In some embodiments, each of the dimples 1338 includes a length of 1.52 mm.

In some embodiments, each of the dimples 1338 includes a width of 3.19 mm to 3.24 mm. In some embodiments, a majority of the dimples 1338 have a width of 3.19 mm to 3.24 mm. In some embodiments, each of the dimples 1338 includes a width of 3.19 mm to 3.23 mm. In some embodiments, each of the dimples 1338 includes a width of 3.19 mm to 3.22 mm. In some embodiments, each of the dimples 1338 includes a width of 3.19 mm to 3.21 mm. In some embodiments, each of the dimples 1338 includes a width of 3.19 mm to 3.20 mm. In some embodiments, each of the dimples 1338 includes a width of 3.2 mm to 3.24 mm. In some embodiments, each of the dimples 1338 includes a width of 3.2 mm to 3.23 mm. In some embodiments, each of the dimples 1338 includes a width of 3.2 mm to 3.22 mm. In some embodiments, each of the dimples 1338 includes a width of 3.2 mm to 3.21 mm. In some embodiments, each of the dimples 1338 includes a width of 3.21 mm to 3.24 mm. In some embodiments, each of the dimples 1338 includes a width of 3.21 mm to 3.23 mm. In some embodiments, each of the dimples 1338 includes a width of 3.21 mm to 3.22 mm. In some embodiments, each of the dimples 1338 includes a width of 3.22 mm to 3.24 mm. In some embodiments, each of the dimples 1338 includes a width of 3.22 mm to 3.23 mm. In some embodiments, each of the dimples 1338 includes a width of 3.23 mm to 3.24 mm.

In some embodiments, each of the dimples 1338 includes a width of 3.19 mm. In some embodiments, each of the dimples 1338 includes a width of 3.2 mm. In some embodiments, each of the dimples 1338 includes a width of 3.21 mm. In some embodiments, each of the dimples 1338 includes a width of 3.22 mm. In some embodiments, each of the dimples 1338 includes a width of 3.23 mm. In some embodiments, each of the dimples 1338 includes a width of 3.24 mm.

In some embodiments, each of the dimples 1338 includes a depth of 0.19 mm to 0.32 mm. In some embodiments, a majority of the dimples 1338 have a depth of 0.19 mm to 0.32 mm. In some embodiments, each of the dimples 1338 includes a depth of 0.19 mm to 0.31 mm. In some embodiments, each of the dimples 1338 includes a depth of 0.19 mm to 0.3 mm. In some embodiments, each of the dimples 1338 includes a depth of 0.19 mm to 0.29 mm. In some embodiments, each of the dimples 1338 includes a depth of 0.19 mm to 0.28 mm. In some embodiments, each of the dimples 1338 includes a depth of 0.19 mm to 0.27 mm. In some embodiments, each of the dimples 1338 includes a depth of 0.19 mm to 0.26 mm. In some embodiments, each of the dimples 1338 includes a depth of 0.19 mm to 0.25 mm. In some embodiments, each of the dimples 1338 includes a depth of 0.19 mm to 0.24 mm. In some embodiments, each of the dimples 1338 includes a depth of 0.19 mm to 0.23 mm. In some embodiments, each of the dimples 1338 includes a depth of 0.19 mm to 0.22 mm. In some embodiments, each of the dimples 1338 includes a depth of 0.19 mm to 0.21 mm. In some embodiments, each of the dimples 1338 includes a depth of 0.19 mm to 0.2 mm.

In some embodiments, each of the dimples 1338 includes a depth of 0.2 mm to 0.32 mm. In some embodiments, each of the dimples 1338 includes a depth of 0.2 mm to 0.31 mm. In some embodiments, each of the dimples 1338 includes a depth of 0.2 mm to 0.3 mm. In some embodiments, each of the dimples 1338 includes a depth of 0.2 mm to 0.29 mm. In some embodiments, each of the dimples 1338 includes a depth of 0.2 mm to 0.28 mm. In some embodiments, each of the dimples 1338 includes a depth of 0.2 mm to 0.27 mm. In some embodiments, each of the dimples 1338 includes a depth of 0.2 mm to 0.26 mm. In some embodiments, each of the dimples 1338 includes a depth of 0.2 mm to 0.25 mm. In some embodiments, each of the dimples 1338 includes a depth of 0.2 mm to 0.24 mm. In some embodiments, each of the dimples 1338 includes a depth of 0.2 mm to 0.23 mm. In some embodiments, each of the dimples 1338 includes a depth of 0.2 mm to 0.22 mm. In some embodiments, each of the dimples 1338 includes a depth of 0.2 mm to 0.21 mm.

In some embodiments, each of the dimples 1338 includes a depth of 0.21 mm to 0.32 mm. In some embodiments, each of the dimples 1338 includes a depth of 0.21 mm to 0.31 mm. In some embodiments, each of the dimples 1338 includes a depth of 0.21 mm to 0.3 mm. In some embodiments, each of the dimples 1338 includes a depth of 0.21 mm to 0.29 mm. In some embodiments, each of the dimples 1338 includes a depth of 0.21 mm to 0.28 mm. In some embodiments, each of the dimples 1338 includes a depth of 0.21 mm to 0.27 mm. In some embodiments, each of the dimples 1338 includes a depth of 0.21 mm to 0.26 mm. In some embodiments, each of the dimples 1338 includes a depth of 0.21 mm to 0.25 mm. In some embodiments, each of the dimples 1338 includes a depth of 0.21 mm to 0.24 mm. In some embodiments, each of the dimples 1338 includes a depth of 0.21 mm to 0.23 mm. In some embodiments, each of the dimples 1338 includes a depth of 0.21 mm to 0.22 mm.

In some embodiments, each of the dimples 1338 includes a depth of 0.22 mm to 0.32 mm. In some embodiments, each of the dimples 1338 includes a depth of 0.22 mm to 0.31 mm. In some embodiments, each of the dimples 1338 includes a depth of 0.22 mm to 0.3 mm. In some embodiments, each of the dimples 1338 includes a depth of 0.22 mm to 0.29 mm. In some embodiments, each of the dimples 1338 includes a depth of 0.22 mm to 0.28 mm. In some embodiments, each of the dimples 1338 includes a depth of 0.22 mm to 0.27 mm. In some embodiments, each of the dimples 1338 includes a depth of 0.22 mm to 0.26 mm. In some embodiments, each of the dimples 1338 includes a depth of 0.22 mm to 0.25 mm. In some embodiments, each of the dimples 1338 includes a depth of 0.22 mm to 0.24 mm. In some embodiments, each of the dimples 1338 includes a depth of 0.22 mm to 0.23 mm.

In some embodiments, each of the dimples 1338 includes a depth of 0.23 mm to 0.32 mm. In some embodiments, each of the dimples 1338 includes a depth of 0.23 mm to 0.31 mm. In some embodiments, each of the dimples 1338 includes a depth of 0.23 mm to 0.3 mm. In some embodiments, each of the dimples 1338 includes a depth of 0.23 mm to 0.29 mm. In some embodiments, each of the dimples 1338 includes a depth of 0.23 mm to 0.28 mm. In some embodiments, each of the dimples 1338 includes a depth of 0.23 mm to 0.27 mm. In some embodiments, each of the dimples 1338 includes a depth of 0.23 mm to 0.26 mm. In some embodiments, each of the dimples 1338 includes a depth of 0.23 mm to 0.25 mm. In some embodiments, each of the dimples 1338 includes a depth of 0.23 mm to 0.24 mm.

In some embodiments, each of the dimples 1338 includes a depth of 0.24 mm to 0.32 mm. In some embodiments, each of the dimples 1338 includes a depth of 0.24 mm to 0.31 mm. In some embodiments, each of the dimples 1338 includes a depth of 0.24 mm to 0.3 mm. In some embodiments, each of the dimples 1338 includes a depth of 0.24 mm to 0.29 mm. In some embodiments, each of the dimples 1338 includes a depth of 0.24 mm to 0.28 mm. In some embodiments, each of the dimples 1338 includes a depth of 0.24 mm to 0.27 mm. In some embodiments, each of the dimples 1338 includes a depth of 0.24 mm to 0.26 mm. In some embodiments, each of the dimples 1338 includes a depth of 0.24 mm to 0.25 mm.

In some embodiments, each of the dimples 1338 includes a depth of 0.25 mm to 0.32 mm. In some embodiments, each of the dimples 1338 includes a depth of 0.25 mm to 0.31 mm. In some embodiments, each of the dimples 1338 includes a depth of 0.25 mm to 0.3 mm. In some embodiments, each of the dimples 1338 includes a depth of 0.25 mm to 0.29 mm. In some embodiments, each of the dimples 1338 includes a depth of 0.25 mm to 0.28 mm. In some embodiments, each of the dimples 1338 includes a depth of 0.25 mm to 0.27 mm. In some embodiments, each of the dimples 1338 includes a depth of 0.25 mm to 0.26 mm.

In some embodiments, each of the dimples 1338 includes a depth of 0.26 mm to 0.32 mm. In some embodiments, each of the dimples 1338 includes a depth of 0.26 mm to 0.31 mm. In some embodiments, each of the dimples 1338 includes a depth of 0.26 mm to 0.3 mm. In some embodiments, each of the dimples 1338 includes a depth of 0.26 mm to 0.29 mm. In some embodiments, each of the dimples 1338 includes a depth of 0.26 mm to 0.28 mm. In some embodiments, each of the dimples 1338 includes a depth of 0.26 mm to 0.27 mm.

In some embodiments, each of the dimples 1338 includes a depth of 0.27 mm to 0.32 mm. In some embodiments, each of the dimples 1338 includes a depth of 0.27 mm to 0.31 mm. In some embodiments, each of the dimples 1338 includes a depth of 0.27 mm to 0.3 mm. In some embodiments, each of the dimples 1338 includes a depth of 0.27 mm to 0.29 mm. In some embodiments, each of the dimples 1338 includes a depth of 0.27 mm to 0.28 mm. In some embodiments, each of the dimples 1338 includes a depth of 0.28 mm to 0.32 mm. In some embodiments, each of the dimples 1338 includes a depth of 0.28 mm to 0.31 mm. In some embodiments, each of the dimples 1338 includes a depth of 0.28 mm to 0.3 mm. In some embodiments, each of the dimples 1338 includes a depth of 0.28 mm to 0.29 mm.

In some embodiments, each of the dimples 1338 includes a depth of 0.29 mm to 0.32 mm. In some embodiments, each of the dimples 1338 includes a depth of 0.29 mm to 0.31 mm. In some embodiments, each of the dimples 1338 includes a depth of 0.29 mm to 0.3 mm. In some embodiments, each of the dimples 1338 includes a depth of 0.3 mm to 0.32 mm. In some embodiments, each of the dimples 1338 includes a depth of 0.3 mm to 0.31 mm. In some embodiments, each of the dimples 1338 includes a depth of 0.31 mm to 0.32 mm.

In some embodiments, each of the dimples 1338 includes a depth of 0.19 mm. In some embodiments, each of the dimples 1338 includes a depth of 0.2 mm. In some embodiments, each of the dimples 1338 includes a depth of 0.21 mm. In some embodiments, each of the dimples 1338 includes a depth of 0.22 mm. In some embodiments, each of the dimples 1338 includes a depth of 0.23 mm. In some embodiments, each of the dimples 1338 includes a depth of 0.24 mm. In some embodiments, each of the dimples 1338 includes a depth of 0.25 mm. In some embodiments, each of the dimples 1338 includes a depth of 0.252 mm. In some embodiments, each of the dimples 1338 includes a depth of 0.26 mm. In some embodiments, each of the dimples 1338 includes a depth of 0.27 mm. In some embodiments, each of the dimples 1338 includes a depth of 0.28 mm. In some embodiments, each of the dimples 1338 includes a depth of 0.29 mm. In some embodiments, each of the dimples 1338 includes a depth of 0.3 mm. In some embodiments, each of the dimples 1338 includes a depth of 0.31 mm. In some embodiments, each of the dimples 1338 includes a depth of 0.32 mm.

In some embodiments, the liner 1336 includes a polymer coated fiber reinforced membrane. In some embodiments, the liner 1336 is a polytetrafluoroethylene (PTFE) coated fiber reinforced membrane. In some embodiments, the liner 1336 is Xiya A membrane. In some embodiments, the liner 1336 is configured to form within the frontsheet 1316 a plurality of indentations having a size and shape corresponding to those of the plurality of dimples 1338.

In another embodiment, the indentations are created by embossing a portion of the frontsheet 1316. In another embodiment, the indentations are created by embossing the polymer layer 1320 of the frontsheet 1316.

Still referring to FIGS. 19A through 19C, in some embodiments, each of the dimples 1330 is oblong in shape. In some embodiments, a majority of the dimples 1330 is oblong in shape. In some embodiments, the dimples 1330 form a grain pattern. In some embodiments, the grain pattern extends in a direction Y. In some embodiments, each of the dimples 1334 is oblong in shape. In some embodiments, a majority of the dimples 1334 is oblong in shape. In some embodiments, the dimples 1334 form a grain pattern. In some embodiments, the grain pattern extends in a direction Y. In some embodiments, each of the dimples 1338 is oblong in shape. In some embodiments, a majority of the dimples 1338 is oblong in shape. In some embodiments, the dimples 1338 form a grain pattern. In some embodiments, the grain pattern extends in a direction Y.

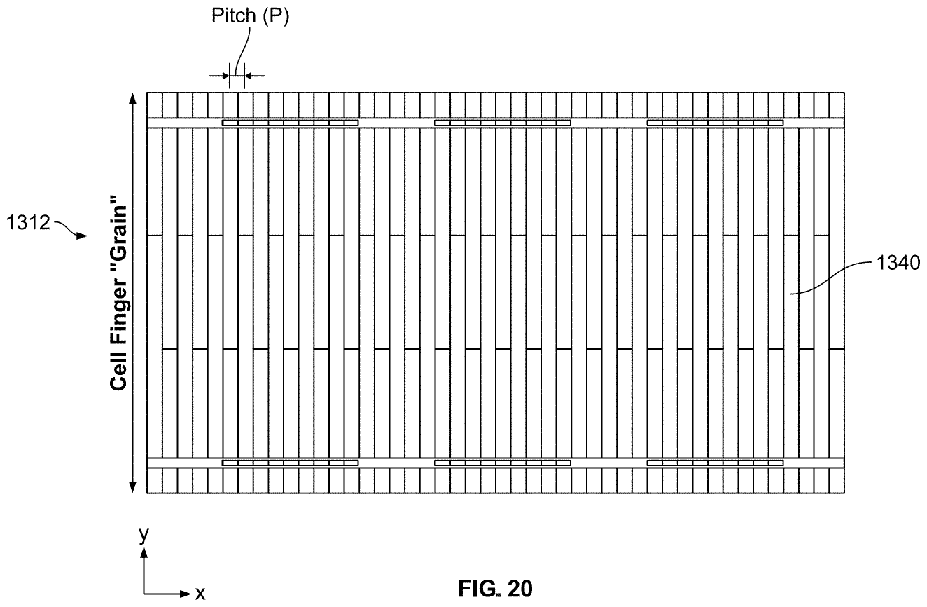

Referring to FIG. 20, the at least one solar cell 12 includes a plurality of cell fingers 1340. In some embodiments, the plurality of cell fingers 1340 from a grain pattern. In some embodiments, the grain pattern of the plurality of cell fingers 1340 extends in a direction Y. In some embodiments, the cell fingers 1340 include a pitch P (the distance from a center, longitudinal axis of one of the cell fingers 1340 to a center, longitudinal axis of another adjacent one of the cell fingers 1340).

In some embodiments, the cell fingers 1340 include a pitch of 1.0 mm to 1.5 mm. In another embodiment, the cell fingers 1340 include a pitch of 1.0 mm to 1.4 mm. In another embodiment, the cell fingers 1340 include a pitch of 1.0 mm to 1.3 mm. In another embodiment, the cell fingers 1340 include a pitch of 1.0 mm to 1.2 mm. In another embodiment, the cell fingers 1340 include a pitch of 1.0 mm to 1.1 mm. In some embodiments, the cell fingers 1340 include a pitch of 1.1 mm to 1.5 mm. In another embodiment, the cell fingers 1340 include a pitch of 1.1 mm to 1.4 mm. In another embodiment, the cell fingers 1340 include a pitch of 1.1 mm to 1.3 mm. In another embodiment, the cell fingers 1340 include a pitch of 1.1 mm to 1.2 mm. In some embodiments, the cell fingers 1340 include a pitch of 1.2 mm to 1.5 mm. In another embodiment, the cell fingers 1340 include a pitch of 1.2 mm to 1.4 mm. In another embodiment, the cell fingers 1340 include a pitch of 1.2 mm to 1.3 mm. In some embodiments, the cell fingers 1340 include a pitch of 1.3 mm to 1.5 mm. In another embodiment, the cell fingers 1340 include a pitch of 1.3 mm to 1.4 mm. In some embodiments, the cell fingers 1340 include a pitch of 1.4 mm to 1.5 mm.

In some embodiments, the photovoltaic module 1310 is configured to be installed on a roof deck. In some embodiments, a system includes a plurality of the photovoltaic module 1310. In some embodiments, when the photovoltaic module 1310 is installed on a roof deck of a structure, the photovoltaic module 1310 module is viewable from the vantage point located at a ground level of the structure.

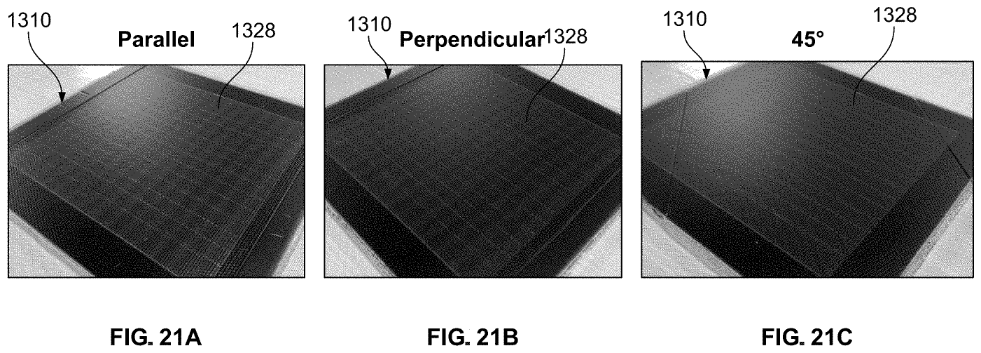

FIGS. 21A through 21C show embodiments of the photovoltaic module 1310 including the liner 1328. Referring to FIG. 21A, in some embodiments, the grain pattern of the liner 1328 is positioned parallel to (zero (0) degrees relative to) the grain pattern of the cell fingers 1340 of the at least one solar cell 1312 when the liner 1328 overlays the polymer layer 1320 to form a plurality of indentations within the frontsheet 1316. In some embodiments, an interference fringe pattern between the plurality of indentations and cell fingers 1340 is viewable.

Referring to FIG. 21B, in some embodiments, the grain pattern of the liner 1328 is positioned perpendicular to (90 degrees relative to) the grain pattern of the cell fingers 1340 of the at least one solar cell 1312 when the liner 1328 overlays the polymer layer 1320 to form a plurality of indentations within the frontsheet 1316. In some embodiments, an interference fringe pattern between the plurality of indentations and the cell fingers 1340 is viewable.

Referring to FIG. 21C, in some embodiments, the grain pattern of the liner 1328 is positioned 45 degrees relative to the grain pattern of the cell fingers 1340 of the at least one solar cell 1312 when the liner 1328 overlays the polymer layer 1320 to form a plurality of indentations within the frontsheet 1316. In some embodiments, an interference fringe pattern between the plurality of indentations and cell fingers 1340 is faint and slightly viewable.

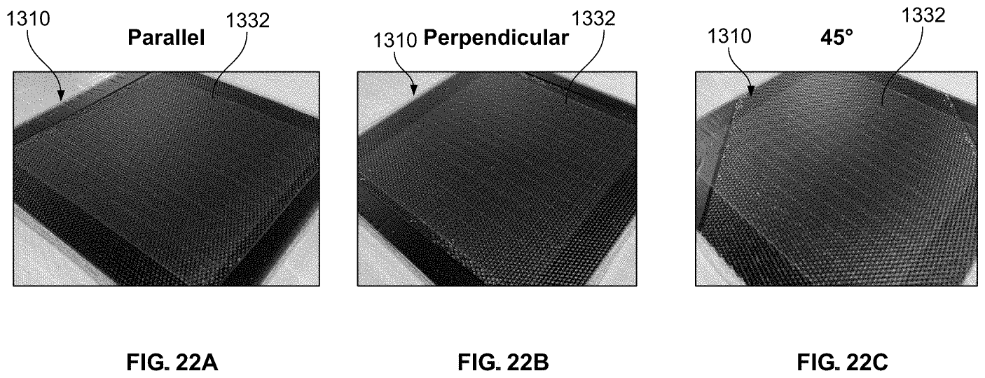

FIGS. 22A through 22C show embodiments of the photovoltaic module 1310 including the liner 1332. Referring to FIG. 22A, in some embodiments, the grain pattern of the liner 1332 is positioned parallel to (zero (0) degrees relative to) the grain pattern of the cell fingers 1340 of the at least one solar cell 1312 when the liner 1332 overlays the polymer layer 1320 to form a plurality of indentations within the frontsheet 1316. In some embodiments, there is no viewable interference fringe pattern between the plurality of indentations and the cell fingers 1340.

Referring to FIG. 22B, in some embodiments, the grain pattern of the liner 1332 is positioned perpendicular to (90 degrees relative to) the grain pattern of the cell fingers 1340 of the at least one solar cell 1312 when the liner 1332 overlays the polymer layer 1320 to form a plurality of indentations within the frontsheet 1316. In some embodiments, there is no viewable interference fringe pattern between the plurality of indentations and the cell fingers 1340.

Referring to FIG. 22C, in some embodiments, the grain pattern of the liner 1332 is positioned 45 degrees relative to the grain pattern of the cell fingers 1340 of the at least one solar cell 1312 when the liner 1332 overlays the polymer layer 1320 to form a plurality of indentations within the frontsheet 1316. In some embodiments, there is no viewable interference fringe pattern between the plurality of indentations and the cell fingers 1340.

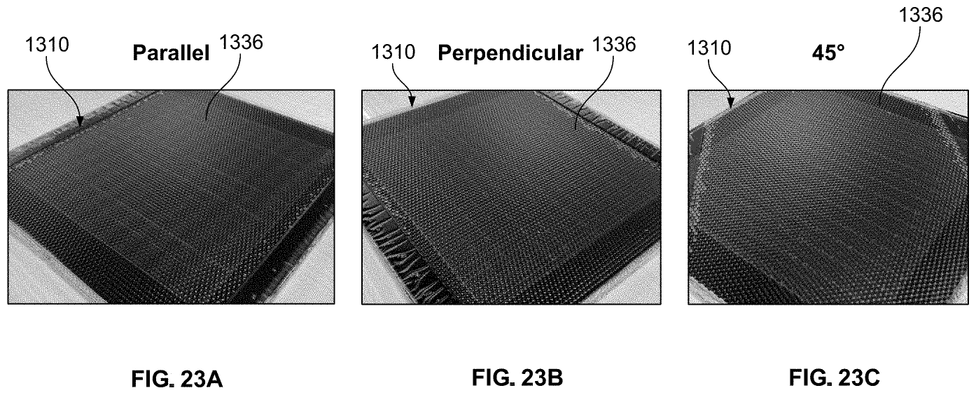

FIGS. 23A through 23C show embodiments of the photovoltaic module 1310 including the liner 1336. Referring to FIG. 23A, in some embodiments, the grain pattern of the liner 1336 is positioned parallel to (zero (0) degrees relative to) the grain pattern of the cell fingers 1340 of the at least one solar cell 1312 when the liner 1336 overlays the polymer layer 1320 to form a plurality of indentations within the frontsheet 1316. In some embodiments, an interference fringe pattern between the plurality of indentations and the cell fingers 1340 is viewable.

Referring to FIG. 23B, in some embodiments, the grain pattern of the liner 1336 is positioned perpendicular to (90 degrees relative to) the grain pattern of the cell fingers 1340 of the at least one solar cell 1312 when the liner 1336 overlays the polymer layer 1320 to form the plurality of indentations within the frontsheet 1316. In some embodiments, there is no viewable interference fringe pattern between the plurality of indentations and the cell fingers 1340.

Referring to FIG. 23C, in some embodiments, the grain pattern of the liner 1336 is positioned 45 degrees relative to the grain pattern of the cell fingers 1340 of the at least one solar cell 1312 when the liner 1336 overlays the polymer layer 1320 to form the plurality of indentations within the frontsheet 1316. In some embodiments, there is no viewable interference fringe pattern between the plurality of indentations and the cell fingers 1340.

In some embodiments, the liner 1326 is configured to form a plurality of indentations within the any of the frontsheets 116, 216, 316, 416, 516, 616, 716, 916, 1016, 1116 of the roofing modules 110, 210, 310, 410, 510, 610, 710, 1010 and the photovoltaic module 1110, respectively. In some embodiments, the liner 1326 is configured to form the plurality of indentations within any of the frontsheets 116, 216, 316, 416, 516, 616, 716, 916, 1016, 1116 of the roofing modules 110, 210, 310, 410, 510, 610, 710, 1010 and the photovoltaic module 1110, respectively. In some embodiments, the liner 1326 is removed after formation of the plurality of indentations. In some embodiments, the liner 1326 includes a structure similar to the liner 1328 including the dimples 1330. In another embodiment, the liner 1326 includes a structure similar to the liner 1332 including the dimples 1334. In another embodiment, the liner 1326 includes a structure similar to the liner 1336 including the dimples 1338. In certain embodiments, the liners 1328, 1332, 1336 may be arranged and positioned relative to the depiction of the cell fingers similar to any of those described above and shown in FIGS. 21A through 23C.

In certain embodiments, the liner 1326 is configured to form the indentations 804 of the roofing module 810. In some embodiments, the liner 1326 includes a structure similar to the liner 1328 including the dimples 1330. In another embodiment, the liner 1326 includes a structure similar to the liner 1332 including the dimples 1334. In another embodiment, the liner 1326 includes a structure similar to the liner 1336 including the dimples 1338.

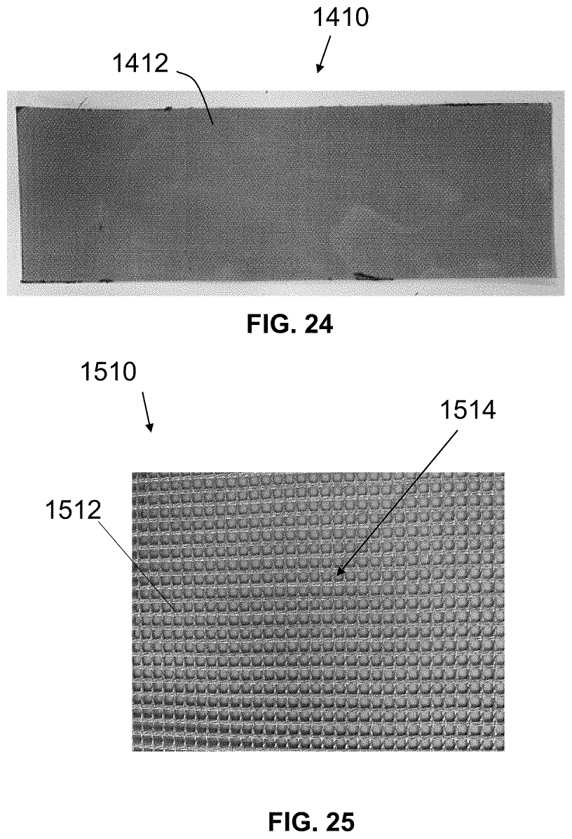

Referring to FIG. 24, in some embodiments, a liner 1410 includes a first surface 1412. In some embodiments, the first surface 1412 is smooth. In some embodiments, the first surface 1412 has no texture. In some embodiments, the liner 1410 is configured to form a smooth outer surface on any of the frontsheets 116, 216, 316, 416, 516, 616, 716, 916, 1016, 1116 of the roofing modules 110, 210, 310, 410, 510, 610, 710, 1010 and the photovoltaic module 1110, respectively.

Referring to FIG. 25, in some embodiments, a scrim 1510 includes a mesh 1512 having a plurality of openings 1514. In some embodiments, each of the openings 1514 is 5 mm×5 mm. In some embodiments, each of the openings 1514 is 4 mm×4 mm. In some embodiments, each of the openings 1514 is 3 mm×3 mm. In some embodiments, each of the openings 1514 is 2 mm×2 mm. In some embodiments, each of the openings 1514 is 1 mm×1 mm. In some embodiments, the mesh 1512 has a thickness of 1 mm. In some embodiments, the mesh 1512 has a thickness of 2 mm. In some embodiments, the mesh 1512 has a thickness of 0.5 mm. In some embodiments, the scrim 1510 is composed of fiberglass. In some embodiments, the scrim 1510 is composed of metal. In some embodiments, the scrim 1510 is composed of plastic. In some embodiments, the scrim 1510 is configured to form a plurality of indentations within the any of the frontsheets 116, 216, 316, 416, 516, 616, 716, 916, 1016, 1116 of the roofing modules 110, 210, 310, 410, 510, 610, 710, 1010 and the photovoltaic module 1110, respectively.

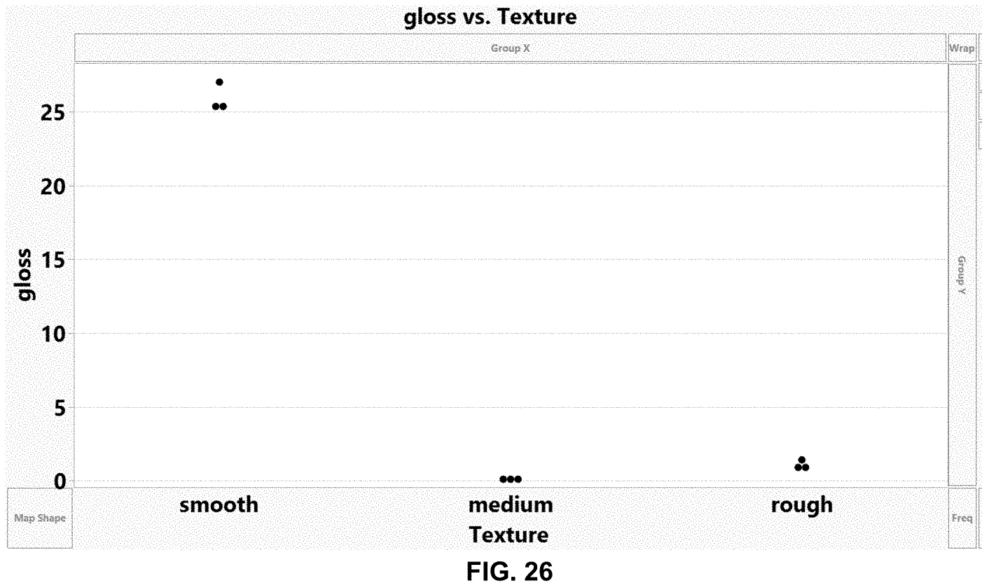

FIG. 26 is graph of gloss versus texture of textured roofing shingles formed by the liner 1410 (labeled as “smooth”), the liner 1332 (labeled as “medium”), and the liner 1336 (labeled as “rough”). In some embodiments, each of the roofing shingles is composed of thermoplastic polyolefin (TPO). In some embodiments, each of the roofing shingles is composed of carbon black TPO. Table I below sets forth embodiments of the textures formed by the liners 1410, 1332, and 1336, the viewing angles, and the measured gloss. In some embodiments, the angle of 85 degrees is approximately a viewing angle of from an observer on a street level of a structure comprising a roof deck that includes the textures roofing modules:

TABLE I

| Texture | Angle | Gloss |
|---|---|---|
| Smooth | 20° | 2.9 |
| Smooth | 20° | 2.8 |
| Smooth | 20° | 0.7 |
| Smooth | 60° | 15.3 |
| Smooth | 60° | 16.7 |
| Smooth | 60° | 10.4 |
| Smooth | 85° | 27.0 |
| Smooth | 85° | 25.5 |
| Smooth | 85° | 25.2 |
| Medium | 20° | 0.2 |
| Medium | 20° | 0.2 |
| Medium | 20° | 0.2 |
| Medium | 60° | 1.3 |
| Medium | 60° | 1.0 |
| Medium | 60° | 1.1 |
| Medium | 85° | 0.1 |
| Medium | 85° | 0.1 |
| Medium | 85° | 0.1 |
| Rough | 20° | 0.2 |
| Rough | 20° | 0.2 |
| Rough | 20° | 0.1 |
| Rough | 60° | 1.2 |
| Rough | 60° | 1.3 |
| Rough | 60° | 1.0 |
| Rough | 85° | 1.1 |
| Rough | 85° | 0.9 |
| Rough | 85° | 0.9 |

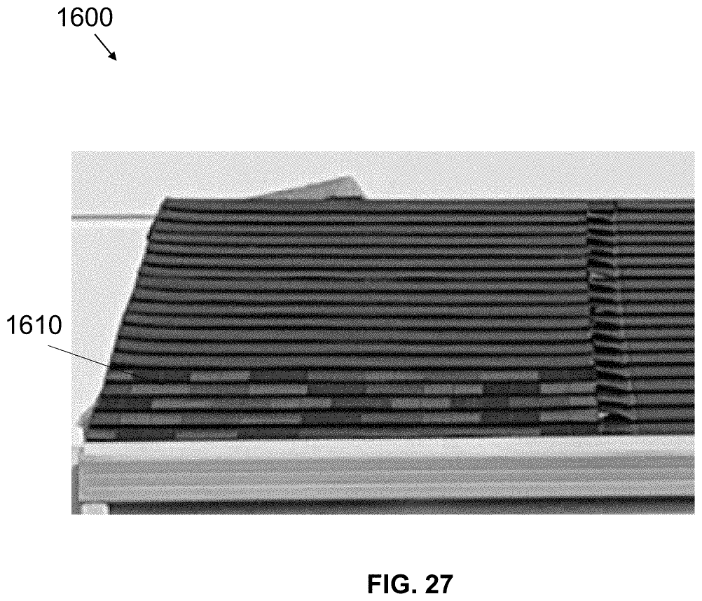

FIG. 27 illustrates some embodiments of a roofing system 1600 including a plurality of roofing shingles 1610. In some embodiments, some of the roofing shingles 1610 are textured by the liner 1410. In some embodiments, some of the roofing shingles 1610 are textured by the liner 1332. In some embodiments, some of the roofing shingles 1610 are textured by the liner 1336. In some embodiments, the different textures diffract various light wavelengths in different directions. In some embodiment, the different textures result in different colors. In some embodiments, the different textures result in different colors at eye level. In some embodiments, the colors will change throughout a day depending upon the sun's ray incident position relative the roofing system.

What is claimed is:

1. A system, comprising:
a plurality of roofing modules, each of the roofing modules includes
a first layer
wherein the first layer includes
a first surface, and
a second surface opposite the first surface,
wherein the first surface is textured, and
a second layer,
wherein the second layer is juxtaposed with the second surface of the first layer,
wherein each of the roofing modules does not include a solar cell; and
a plurality of photovoltaic modules, each of the plurality of photovoltaic modules includes
at least one solar cell,
an encapsulant encapsulating the at least one solar cell, wherein the encapsulant of the photovoltaic module includes a first surface and a second surface opposite the first surface of the encapsulant of the photovoltaic module,
a frontsheet,
wherein the frontsheet includes
a first surface, and
a second surface opposite the first surface of the frontsheet,
wherein the second surface of the frontsheet is juxtaposed with the first surface of the encapsulant,
wherein the first surface of the frontsheet is textured, and
a backsheet juxtaposed with the second surface of the encapsulant of the photovoltaic module,
wherein the photovoltaic modules are configured to be installed on a roof deck of a structure,
wherein the roofing modules are configured to be installed on the roof deck proximate to the photovoltaic modules, and
wherein an appearance of the roofing modules aesthetically matches an appearance of the photovoltaic modules when viewed from a vantage point located at a ground level of the structure.

2. The system of claim 1, wherein the first layer is composed of a polymer.

3. The system of claim 2, wherein the first layer is composed of thermoplastic polyolefin (TPO).

4. The system of claim 1, wherein the second layer is composed of a polymer.

5. The system of claim 4, wherein the second layer is composed of thermoplastic polyolefin (TPO).

6. The system of claim 4, wherein the second layer includes fiberglass.

7. The system of claim 1, wherein the first layer has a thickness of 25 mils to 100 mils.

8. The system of claim 4, wherein the second layer has a thickness of 25 mils to 200 mils.

9. The system of claim 1, wherein the first layer includes a pattern printed on the first surface of the first layer.

10. The system of claim 9, wherein the pattern is a depiction of solar cells.

11. The system of claim 1, wherein the first layer is colored.

12. The system of claim 11, wherein the first layer is black colored.

13. The system of claim 1, wherein the second layer is colored.

14. The system of claim 13, wherein the second layer is black colored.

15. A method, comprising the steps of:
obtaining a plurality of roofing modules, each of the roofing modules includes
a first layer
wherein the first layer includes
a first surface, and
a second surface opposite the first surface,
wherein the first surface is textured, and
a second layer,
wherein the second layer is juxtaposed with the second surface of the first layer,
wherein each of the roofing modules does not include a solar cell;
obtaining a plurality of photovoltaic modules, each of the plurality of photovoltaic modules includes
at least one solar cell,
an encapsulant encapsulating the at least one solar cell, wherein the encapsulant of the photovoltaic module includes a first surface and a second surface opposite the first surface of the encapsulant of the photovoltaic module,
a frontsheet,
wherein the frontsheet includes
a first surface, and
a second surface opposite the first surface of the frontsheet,
wherein the second surface of the frontsheet is juxtaposed with the first surface of the encapsulant,
wherein the first surface of the frontsheet is textured, and
a backsheet juxtaposed with the second surface of the encapsulant of the photovoltaic module;
installing the plurality of photovoltaic modules on a roof deck of a structure;
cutting at least one of the plurality of roofing modules to a size and shape; and
installing the plurality of roofing modules on the roof deck proximate to the plurality of photovoltaic modules,
wherein the at least one solar cell of at least one of the plurality of photovoltaic modules is electrically active, and
wherein an appearance of the roofing modules aesthetically matches an appearance of the photovoltaic modules when viewed from a vantage point located at a ground level of the structure.

16. The method of claim 15, wherein each of the first layer and the second layer is composed of a polymer.

17. The method of claim 16, wherein each of the first layer and the second layer is composed of thermoplastic polyolefin (TPO).

18. The method of claim 16, wherein the first layer has a thickness of 25 mils to 100 mils, and wherein the second layer has a thickness of 25 mils to 200 mils.

19. The method of claim 16, wherein the first layer includes a pattern printed on the first surface of the first layer.

20. The method of claim 19, wherein the pattern is a depiction of solar cells.
